(19) United States
(12) Patent Application Publication
(10) Pub. No.: US 2006/0068301 A1
(43) Pub. Date: Mar. 30, 2006

(54) Pattern decision method and system, mask manufacturing method, image-forming performance adjusting method, exposure method and apparatus, program, and information recording medium

(75) Inventor: Shigeru Hirukawa, Tokyo (JP)

Correspondence Address: OLIFF & BERRIDGE, PLC, P.O. BOX 19928, ALEXANDRIA, VA, 22320, US

(73) Assignee: Nikon Corporation, Tokyo (JP)

(21) Appl. No.: 11/250,533

(22) Filed: Oct. 17, 2005

Related U.S. Application Data
(63) Continuation of application No. PCT/JP04/05481, filed on Apr. 16, 2004.

(30) Foreign Application Priority Data
Apr. 16, 2003 (JP) 2003-111072

(51) Int. Cl. G03C 5/00; G06F 17/50; G03F 1/00

(52) U.S. Cl. 430/5; 716/19; 430/30

(57) ABSTRACT

Based on adjustment information on the adjustment unit under predetermined exposure conditions and information on the corresponding image-forming performance of the projection optical system, pattern correction information, information on a permissible range of the image-forming performance, and the like, a calculation step (steps 114 to 118) and a setting step (steps 120, 124, and 126) are repeatedly performed in the case an image-forming performance in at least one exposure apparatus is outside the permissible range under the target exposure conditions until the image-forming performance in all the exposure apparatus is within the permissible range. In the calculation step, an appropriate adjustment amount under target exposure conditions whose pattern is corrected is calculated for each exposure apparatus, and in the setting step, the correction information is set according to a predetermined criterion based on the image forming performance outside the permissible range, and when the image-forming performance in all the exposure apparatus is within the permissible range, the correction information that has been set is decided as the pattern correction information (step 138).

### CROSS-REFERENCE TO RELATED APPLICATIONS

This is a continuation of International Application PCT/JP2004/005481, with an international filing date of Apr. 16, 2004, the entire content of which being hereby incorporated herein by reference, which was not published in English.

### BACKGOUND OF THE INVENTION

1. Field of the Invention

The present invention relates to pattern decision methods and systems, mask manufacturing methods, image-forming performance adjusting methods, exposure methods and apparatus, programs, and information recording mediums, and more particularly to a pattern decision method and a pattern decision system where information of a pattern that is to be formed on a mask is decided, a mask manufacturing method that uses the pattern decision method, an image-forming performance adjusting method of a projection optical system which projects the pattern formed on the mask onto an object, an exposure method that uses the image-forming performance adjusting method and an exposure apparatus suitable for performing the exposure method, a program that makes a computer execute a predetermined processing to design the mask, and an information recording medium in which the program is recorded.

2. Description of the Related Art

Conventionally, in a lithographic process to produce electronic devices such as a semiconductor, a liquid crystal display device, a thin-film magnetic head, or the like, projection exposure apparatus are used that transfer a pattern of a mask or a reticle (hereinafter generally referred to as a ‘reticle’) via a projection optical system onto an object (hereinafter generally referred to as a ‘wafer’) such as a wafer or a glass plate whose surface is coated with a photosensitive agent such as a photoresist or the like. For example, a reduction projection exposure apparatus by a step-and-repeat method (the so-called stepper), and a scanning projection exposure apparatus by a step-and-scan method (the so-called scanning stepper) have been used.

In the case of manufacturing semiconductors or the like, because many layers of different circuit patterns have to be formed on the wafer, it is important to accurately overlay the reticle on which the circuit pattern is formed onto the patterns that are already formed on each shot area of the wafer. In order to perform the overlay with good precision, it is essential for the image-forming performance of the projection optical system to be adjusted to a desirable state (for example, the magnification error of the transferred image of the reticle pattern to the shot area (pattern) on the wafer is to be corrected). Even in the case of transferring the reticle pattern of the first layer onto each shot area of the wafer, it is desirable to adjust the image-forming performance of the projection optical system so that the reticle pattern from the second layer onward can be transferred with good precision onto each shot area.

In addition, because circuit patterns are becoming finer with higher integration in recent semiconductor devices or the like, correcting only Seidel's five aberrations (low order aberration) is no longer sufficient enough in recent exposure apparatus. Therefore, conventionally, in order to correct line width variation in the transferred image of the reticle pattern that occurs due to aberration of the projection optical system, optical proximity effect, or the like of the exposure apparatus, there were cases (for example, refer to Japanese Patent Publication No. 3343919, and the corresponding U.S. Pat. No. 5,546,225) where a pattern was formed on the reticle with a part of its line width varying from the designed value.

In addition, when adjusting the image-forming performance or the image-forming state of the pattern by the projection optical system, for example, an image-forming performance adjustment mechanism or the like is used that adjusts the position and the inclination or the like of optical elements such as lens elements constituting the projection optical system. However, the image-forming performance changes according to exposure conditions, such as the illumination condition (illumination σ or the like), N.A. (numerical aperture) of the projection optical system, the pattern to be used, and the like. Accordingly, the adjusted position of each optical element by the image-forming performance adjustment mechanism that is optimal under a certain exposure condition may not be the optimal adjusted position under other exposure conditions.

Considering such points, recently, a proposal has been made (for example, refer to International Publication No. 02/054036 Pamphlet and its corresponding U.S. patent application No. 2004/0059444) of an invention related to an adjusting method of an adjustment mechanism that optimizes the image-forming characteristics (image-forming performance) and the image-forming state by the projection optical system according to exposure conditions which are decided according to the illumination condition (illumination σ or the like), N.A. (numerical aperture) of the projection optical system, the pattern to be used, or the like, an image-forming characteristics adjusting method, and its program.

However, in the case of applying the invention described in the Japanese Patent Publication No. 3343919 referred to above to a plurality of exposure apparatus, because the pattern correction (optimization) of the reticle used in each exposure apparatus is performed individually in the plurality of exposure apparatus while using the invention described in the Patent Publication, a case may occur where the reticle optimized with respect to a certain exposure apparatus cannot be used in another exposure apparatus. That is, it may be difficult to use a common reticle among the plurality of exposure apparatus. This is because the aberration state of the projection optical system of the exposure apparatus differs depending on the exposure apparatus (apparatus number), and the difference (discrepancy) in aberration among the exposure apparatus causes positional shift and line width difference of the image of the pattern, which makes it virtually difficult to use a common reticle among the exposure apparatus.

Meanwhile, in the case of optimizing the image-forming characteristics (image-forming performance) of the projection optical system of a plurality of exposure apparatus with respect to a pattern using the invention described in International Publication No. 02/054036 pamphlet referred to above, when the permissible range of the required image-forming performance is relatively large, the image-forming performance of the projection optical system can be optimized in each exposure apparatus with respect to the same pattern, as long as the image-forming performance is within the adjustable range of the adjustment mechanism that each exposure apparatus has. However, in the invention described in the pamphlet above, because the image-forming characteristics (image-forming performance and aberration) of the projection optical system of the exposure apparatus were optimized with a given reticle pattern, the adjustment of the adjustment mechanism referred to above could easily reach its limit, and especially in the case of using the same common reticle between many apparatus or apparatus that have different performances, the probability increases of a situation occurring where adjusting the image-forming performance of the exposure apparatus becomes difficult in some of the apparatus. Such a situation can occur, especially more easily when the permissible range becomes smaller for errors of the required image-forming performance.

Meanwhile, in the same semiconductor factory, if the same reticle can be shared among a larger number of exposure apparatus, consequently, from a practical point of view, there are advantages of being able to lower the manufacturing cost of electronic devices such as semiconductors, as well as increase the degree of freedom (flexibility) of operation of the exposure apparatus (apparatus number).

### SUMMARY OF THE INVENTION

The present invention was made under such circumstances, and has as its first object to provide a pattern decision method and a pattern decision system that can make manufacturing (fabricating) a mask commonly used in a plurality of exposure apparatus easier.

The second object of the present invention is to provide a mask manufacturing method that allows easy manufacture of a mask commonly used in a plurality of exposure apparatus.

The third object of the present invention is to provide an image-forming performance adjusting method that can substantially increase the adjusting capacity of the image-forming performance of a projection optical system with respect to a pattern on a mask.

The fourth object of the present invention is to provide an exposure method and exposure apparatus that allow a pattern on a mask to be transferred with good precision onto an object.

And, the fifth object of the present invention is to provide a program that can make designing a mask used in a plurality of exposure apparatus easy using a computer, and an information recording medium.

According to the first aspect of the present invention, there is provided a first pattern decision method in which information on a pattern that is to be formed on a mask is decided, the mask being a mask used in a plurality of exposure apparatus that form a projected image of the pattern formed on the mask onto an object via a projection optical system, the method comprising: an optimization processing step in which a first step and a second step are repeatedly performed until an image-forming performance of the projection optical system in all the exposure apparatus is judged to be within a permissible range, according to a judgment made in the second step, wherein in the first step, an appropriate adjustment amount of an adjustment unit so as to adjust a forming state of the projected image of the pattern on the object is calculated for each exposure apparatus under target exposure conditions, which take into consideration correction information on the pattern, based on a plurality of types of information that includes the adjustment information of the adjustment unit including the pattern information and information related to the image-forming performance of the projection optical system corresponding to the adjustment information under predetermined exposure conditions, correction information on the pattern, and information on the permissible range of the image-forming performance, and in the second step, the judgment is made whether or not the predetermined image-forming performance of the projection optical system in at least one exposure apparatus is outside the permissible range under the target exposure conditions after the adjustment unit has been adjusted according to the appropriate adjustment amount for each exposure apparatus calculated in the first step, and by the judgment, based on the image-forming performance resulting to be outside the permissible range, the correction information is set according to a predetermined criterion; and a decision making step in which when the image-forming performance of the projection optical system in all the exposure apparatus falls within the permissible range, the correction information set in the optimization processing step is decided as correction information on the pattern.

In the description, the correction information on the pattern can include the case when the correction value is zero. In addition, ‘exposure condition’ refers to conditions related to exposure, which are decided depending on the combination of illumination conditions (such as, illumination a (coherence factor), annular ratio, and the light quantity distribution on the pupil plane of the illumination optical system), the numerical aperture (N.A.) of the projection optical system, and the type of the subject pattern (such as, whether it is an extracted pattern or a residual pattern, a dense pattern or an isolated pattern, the pitch in the case it is a line-and-space pattern, line width, duty ratio, in the case of isolated lines its line width, in the case of contact holes its longitudinal length, its lateral length, and the distance between the hole patterns (such as its pitch), whether it is a phase shift pattern or not, and whether the projection optical system has a pupil filter or not). In addition, the appropriate adjustment amount refers to the adjustment amount of the adjustment unit, which generates substantially the best image-forming performance within the adjustable range of the projection optical system when projecting the pattern subject to projection.

According to this method, first of all, in the optimization processing step, the optimization processing described below is performed.

In the processing step, the first step and the second step are repeatedly performed until the image-forming performance of the projection optical system in all the exposure apparatus is judged to be within the permissible range, according to the judgment made in the second step. In the first step, an appropriate adjustment amount of the adjustment unit so as to adjust the forming state of the projected image of the pattern on the object is calculated for each exposure apparatus under target exposure conditions, which take into consideration correction information on the pattern (under target exposure conditions where the pattern is replaced with a corrected pattern that has been corrected with the correction information), based on a plurality of types of information that includes the adjustment information of the adjustment unit including the pattern information and information related to the image-forming performance of the projection optical system corresponding to the adjustment information under predetermined exposure conditions, correction information on the pattern, and information on the permissible range of the image-forming performance. And then, in the second step, the judgment is made whether or not the predetermined image-forming performance of the projection optical system in at least one exposure apparatus is outside the permissible range under the target exposure conditions after the adjustment unit has been adjusted according to the appropriate adjustment amount for each exposure apparatus calculated in the first step, and by the judgment, based on the image-forming performance resulting to be outside the permissible range, the correction information is set according to a predetermined criterion.

And, in the above optimization processing step, when the image-forming performance of the projection optical system for all the exposure apparatus falls within the permissible range, that is, when there is no longer any image-forming performance outside the permissible range by the correction information setting, or when the image-forming performance of the projection optical system for all the exposure apparatus is within the permissible range from the very beginning, the correction information set in the above optimization processing step is decided (decision making step) as the correction information on the pattern.

Accordingly, by using the correction information on the pattern decided by the first pattern decision method of the present invention or the information on the pattern that has been corrected using the correction information when manufacturing the mask, manufacturing (fabricating) a mask that can be commonly used in a plurality of exposure apparatus can be easily achieved.

In this case, the second step can comprise: a first judgment step in which a predetermined image-forming performance of a projection optical system in at least one exposure apparatus is judged whether it is outside the permissible range under the target exposure conditions or not after the adjustment unit has been adjusted according to the appropriate adjustment amount, based on the appropriate adjustment amount for each exposure apparatus calculated in the first step, and the adjustment information of the adjustment unit under the predetermined exposure conditions and information related to an image-forming performance of the projection optical system corresponding to the adjustment information; and a setting step in which the correction information is set according to a predetermined criterion based on a predetermined image-forming performance resulting to be outside the permissible range, in the case the predetermined image-forming performance of a projection optical system in at least one exposure apparatus is outside the permissible range according to the results of the judgment in the first judgment step.

In this case, the second step can further comprise a second judgment step in which a predetermined image-forming performance of a projection optical system in at least one exposure apparatus is judged whether it is outside the permissible range under the target exposure conditions after the adjustment unit has been adjusted according to the appropriate adjustment amount, based on the appropriate adjustment amount for each exposure apparatus calculated in the first step, the correction information set in the setting step, the adjustment information of the adjustment unit under the predetermined exposure conditions and information related to the image-forming performance of the projection optical system corresponding to the adjustment information, and information on the permissible range of the image-forming performance.

In such a case, after the correction information is set in the setting step, in the second judgment step, the judgment is made whether or not a predetermined image-forming performance of a projection optical system in at least one exposure apparatus is outside the permissible range under the target exposure conditions (under target exposure conditions where the pattern is replaced with a corrected pattern that has been corrected with the correction information) after the adjustment unit has been adjusted according to the appropriate adjustment amount, which is calculated prior to the setting of the correction information in the first step, based on the correction information that has been set and other information (appropriate adjustment amount for each exposure apparatus calculated in the first step, the adjustment information of the adjustment unit and information related to the image-forming performance of the projection optical system corresponding to the adjustment information under the predetermined exposure conditions, and information on the permissible range of the image-forming performance). Therefore, in the case the image-forming performance of the projection optical system in all the exposure apparatus is within the permissible range in the second judgment step, the procedure moves to the decision making step where the correction information set at this point is decided as the correction information on the pattern, without returning to the first step. Accordingly, the correction information on the pattern can be decided within a shorter period of time than the case when it is decided by the image-forming performance of the projection optical system in all the exposure apparatus being confirmed to be within the permissible range, after the procedure returns to the first step and re-calculates the appropriate adjustment amount.

In the first pattern decision method of the present invention, the predetermined criterion to decide the correction information can be a criterion based on an image-forming performance resulting outside the permissible range, and also can be a criterion when performing pattern correction to make the image-forming performance fall within the permissible range. Accordingly, for example, a value that is half (½) the value of the image-forming performance outside the permissible range can be used as the correction information (correction value).

In the first pattern decision method of the present invention, the correction information can be set based on an average value of residual errors of a predetermined image-forming performance in the plurality of exposure apparatus.

According to the first pattern decision method of the present invention, since the information related to the image-forming performance only has to be information that is a base for calculating the optimal adjustment amount of the adjustment unit under the target exposure conditions, along with the adjustment information of the adjustment unit, various information can be included. For example, the information related to the image-forming performance can include information on wavefront aberration of the projection optical system after adjustment under the predetermined exposure conditions, or the information related to the image-forming performance can include information on wavefront aberration only of the projection optical system and information on an image-forming performance of the projection optical system under the predetermined exposure conditions. In the latter case, the deviation between the wavefront aberration (stand-alone wavefront aberration) only of the projection optical system (for example, before incorporating the projection optical system into the exposure apparatus) and the wavefront aberration of the projection optical system on body (that is, after the projection optical system is incorporated into the exposure apparatus) after the adjustment under the reference exposure conditions can be assumed to be corresponding to the deviation of the adjustment amount of the adjustment unit, and the correction amount of the adjustment amount can be obtained by calculation based on the deviation of the image-forming performance from an ideal state, and correction amount of the wavefront aberration can be obtained from the correction amount. Then, based on the wavefront aberration correction amount, the stand-alone wavefront aberration, and information on the wavefront aberration conversion value at the positional reference of the adjustment unit under the reference exposure conditions, the wavefront aberration of the projection optical system after adjustment under the reference exposure conditions can be obtained.

According to the first pattern decision method of the present invention, in the case the information related to the image-forming performance is information on a difference between an image-forming performance of the projection optical system under the predetermined exposure conditions and a predetermined target value of the image-forming performance, and the adjustment information of the adjustment unit is information on adjustment amounts of the adjustment unit, in the first step, the appropriate adjustment amount can be calculated for each exposure apparatus, using a relational expression between the difference, a Zernike Sensitivity chart under the target exposure conditions, which denotes a relation between an image-forming performance of the projection optical system and the coefficient of each term in the Zernike polynomial under the target exposure conditions, a wavefront aberration variation table consisting of a group of parameters, which denotes a relation between adjustment of the adjustment unit and wavefront aberration change of the projection optical system, and the adjustment amounts.

In this case, a predetermined target value of the image-forming performance includes the case when the target value of the image-forming performance is zero.

In this case, the relational expression can be an expression that includes a weighting function for performing weighting on any of the terms of each term of the Zernike polynomial.

In this case, the weight can be set so that among the image-forming performance of the projection optical system under the target exposure conditions, weight in sections outside the permissible range is high.

In the first pattern decision method of the present invention, in the second step, the judgment of whether or not the predetermined image-forming performance of the projection optical system in at least one exposure apparatus is outside the permissible range can be made, based on a difference between: an image-forming performance of the projection optical system under the target exposure conditions calculated for each exposure apparatus, based on information on wavefront aberration after adjustment and the Zernike Sensitivity chart under the target exposure conditions, the information on wavefront aberration after adjustment being obtained based on adjustment information of the adjustment unit under the predetermined exposure conditions and information on wavefront aberration of the projection optical system corresponding to the adjustment information, and an appropriate adjustment amount calculated in the first step; and the target value of the image-forming performance.

In the first pattern decision method of the present invention, as the Zernike Sensitivity chart under the target exposure conditions, a Zernike Sensitivity chart under the target exposure conditions that takes into consideration the correction information made by calculation after setting the correction information in the second step can be used.

In the first pattern decision method of the present invention, the predetermined target value can be a target value of the image-forming performance in a least one evaluation point of the projection optical system.

In this case, the target value of the image-forming performance can be a target value of an image-forming performance at a representative point that is selected.

In the first pattern decision method of the present invention, in the optimization processing step, the appropriate adjustment amount can be calculated, further taking into consideration restraint conditions, which are decided by adjustment amount limits due to the adjustment unit.

In the first pattern decision method of the present invention, in the optimization processing step, the appropriate adjustment amount can be calculated with at least a part of the field of the projection optical system serving as an optimization field range.

In the first pattern decision method of the present invention, the method can further comprise: a repetition number limitation step in which a judgment is made whether or not the first step and the second step have been repeated a predetermined number of times, and when a judgment is made that the first step and the second step have been repeated a predetermined number of times before the image-forming performance of the projection optical system in all the exposure apparatus falls within the permissible range, processing is terminated. For example, in the case when the permissible range of the image-forming performance is extremely small, or in the case when the correction value of the pattern should not be largely increased, a case may occur when the appropriate adjustment amount cannot be calculated for all the exposure apparatus in a state where all the conditions are satisfied, no matter how many times the setting of the correction information (correction value) is performed in the optimization processing step previously described. In such a case, the processing is terminated at the point where the first step and the second step are repeatedly performed a predetermined number of times, therefore, it becomes possible to prevent time from being wasted.

According to the second aspect of the present invention, there is provided a first mask manufacturing method, the method comprising: a pattern decision step in which information on a pattern that is to be formed on a mask is decided according to the first pattern decision method of the present invention; and a pattern forming step in which a pattern is formed on a mask blank using the information on the pattern that has been decided.

According to the method, in the pattern decision step, as the information of the pattern to be formed on the mask, information on a pattern whose image-forming performance is within the permissible range in any of the exposure apparatus when forming the projected image by the projection optical system in a plurality of exposure apparatus is decided by the first pattern decision method of the present invention. Then, in the pattern forming step, a pattern is formed on a mask blank using the pattern information that has been decided. Accordingly, a mask that can be commonly used in a plurality of exposure apparatus can be manufactured easily.

According to the third aspect of the present invention, there is provided a first exposure method, the method comprising: a loading step in which a mask manufactured by a manufacturing method according to the first mask manufacturing method of the present invention is loaded into an exposure apparatus among the plurality of exposure apparatus; and an exposure step in which an object is exposed via the mask and a projection optical system, in a state where an image-forming performance of the projection optical system equipped in the exposure apparatus is adjusted according to a pattern of the mask.

According to the method, a mask manufactured by the first mask manufacturing method of the present invention is loaded into an exposure apparatus of the plurality of exposure apparatus, and exposure of the object is performed via the mask and the projection optical system in a state where the image-forming performance of the projection optical system equipped in the exposure apparatus is adjusted to the pattern of the mask. In this case, because the pattern formed on the mask is the pattern whose information is decided in the pattern decision stage so that the image-forming performance of the projection optical system is within the permissible range in any of the plurality of the exposure apparatus, by adjusting the image-forming performance of the projection optical system to the pattern of the mask, the image-forming performance of the projection optical system is adjusted for certain within the permissible range. The adjustment of the image-forming performance in this case may be performed by storing the adjustment parameters (for example, the adjustment amounts of the adjustment mechanism) of the image-forming performance obtained during the pattern decision stage and using the values for adjustment, or the appropriate values of the adjustment parameters of the image-forming performance may be obtained again. In any case, by the exposure above, the pattern is transferred onto the object with good precision.

According to the fourth aspect of the present invention, there is provided a second pattern decision method in which information on a pattern that is to be formed on a mask is decided, the mask being a mask used in a plurality of exposure apparatus that form a projected image of the pattern formed on the mask onto an object via a projection optical system wherein the information on the pattern is decided so as to make a predetermined image-forming performance when the projected image of the pattern is formed by the projection optical system in the plurality of exposure apparatus fall within a permissible range.

According to the method, when the information of the pattern to be formed on the mask is decided, the pattern information is decided so that the predetermined image-forming performance is within the permissible range when the projection optical systems in the plurality of exposure apparatus form the projected image of the pattern. Accordingly, by using the pattern information decided by the second pattern decision method of the present invention when manufacturing a mask, a mask that can be commonly used in a plurality of exposure apparatus can be manufactured easily.

According to the fifth aspect of the present invention, there is provided a second mask manufacturing method, the method comprising: a pattern decision step in which information on a pattern that is to be formed on a mask is decided by a pattern decision method according to the second pattern decision method of the present invention; and a pattern forming step in which a pattern is formed on a mask blank using the information on the pattern that has been decided.

According to the method, in the pattern decision step, as the information of the pattern to be formed on the mask, information on a pattern whose image-forming performance is within the permissible range in any of the exposure apparatus when forming the projected image by the projection optical system in a plurality of exposure apparatus is decided by the second pattern decision method of the present invention. Then, in the pattern forming step, a pattern is formed on a mask blank using the pattern information that has been decided. Accordingly, a mask that can be commonly used in a plurality of exposure apparatus can be manufactured easily.

According to the sixth aspect of the present invention, there is provided a second exposure method, the method comprising: a loading step in which a mask manufactured by a manufacturing method according to the second mask manufacturing method of the present invention is loaded into an exposure apparatus of the plurality of exposure apparatus; and an exposure step in which an object is exposed via the mask and the projection optical system, in a state where an image-forming performance of a projection optical system equipped in the exposure apparatus is adjusted according to a pattern of the mask.

According to the method, for the same reasons as the first exposure method, the pattern is transferred onto the object with good precision.

According to the seventh aspect of the present invention, there is provided an image-forming performance adjusting method of a projection optical system in which an image-forming performance of the projection optical system projecting a pattern formed on a mask onto an object is adjusted, the method comprising: a calculating step in which an appropriate adjustment amount of an adjustment unit so as to adjust a forming state of the projected image of the pattern on the object is calculated for each exposure apparatus under target exposure conditions, which take into consideration correction information on the pattern, using adjustment information of the adjustment unit and information related to the image-forming performance of the projection optical system under predetermined exposure conditions, and correction information on the pattern in a mask manufacturing stage; and an adjusting step in which the adjustment unit is adjusted according to the appropriate adjustment amount.

According to the method, the appropriate adjustment amount of the adjustment unit under the target exposure conditions (projection conditions), which take into consideration the correction information on the pattern, is calculated using the correction information on the pattern at the mask manufacturing stage, along with the adjustment information of the adjustment unit and information related to the image-forming performance of the projection optical system under predetermined exposure conditions (projection conditions). Therefore, this allows calculation of the adjustment amount that makes the image-forming performance of the projection optical system more favorable than when the adjustment amount is calculated without taking into consideration the correction information on the pattern. In addition, even in the case when calculating the adjustment amount that makes the image-forming performance of the projection optical system fall within the permissible range decided in advance under target exposure conditions, which does not take into consideration the correction information on the pattern, is difficult, by calculating the adjustments amount of the adjustment units under the target exposure conditions taking into consideration the correction information on the pattern, there may be cases when it becomes possible to calculate the adjustment amount that makes the image-forming performance of the projection optical system fall within the permissible range.

In this case, the correction information on the pattern at the mask manufacturing stage can be obtained, as an example, by using the pattern decision method previously described.

Then, by the adjustment unit being adjustment according to the calculated appropriate adjustment amount, the image-forming performance of the projection optical system is adjusted more favorably than in the case when the correction information on the pattern is not taken into consideration. Accordingly, it becomes possible to substantially improve the adjustment capability of the image-forming performance of the projection optical system to the pattern on the mask.

In this case, the information related to the image-forming performance can include information on wavefront aberration of the projection optical system after adjustment under the predetermined exposure conditions, or the information related to the image-forming performance can include information on wavefront aberration only of the projection optical system and information on an image forming performance of the projection optical system under the predetermined exposure conditions.

In the image-forming performance adjusting method of the present invention, in the case the information related to the image-forming performance is information on a difference between an image-forming performance of the projection optical system under the predetermined exposure conditions and a predetermined target value of the image-forming performance, and the adjustment information of the adjustment unit is information on adjustment amounts of the adjustment unit, in the calculating step, the appropriate adjustment amount can be calculated, using a relational expression between the difference, a Zernike Sensitivity chart under the target exposure conditions, which denotes a relation between an image-forming performance of the projection optical system and the coefficient of each term in the Zernike polynomial under the target exposure conditions, a wavefront aberration variation table consisting of a group of parameters, which denotes a relation between adjustment of the adjustment unit and wavefront aberration change of the projection optical system, and the adjustment amounts.

In this case, the relational expression can be an expression that includes a weighting function for performing weighting on any of the terms of each term of the Zernike polynomial.

According to the eighth aspect of the present invention, there is provided a third exposure method in which a pattern formed on a mask is transferred onto an object using a projection optical system, the method comprising: an adjusting step in which an image-forming performance of the projection optical system under the target exposure conditions is adjusted by an image-forming performance adjusting method of the present invention; and a transferring step in which the pattern is transferred onto the object, using a projection optical system whose image-forming performance has been adjusted.

According to the method, by using the image-forming performance adjusting method of the present invention, the image-forming performance of the projection optical system is favorably adjusted, and the pattern is transferred onto the object under the target exposure conditions using the projection optical system whose image-forming performance is favorably adjusted. Accordingly, it becomes possible to transfer the pattern onto the object with good precision.

According to the ninth aspect of the present invention, there is provided a pattern decision system in which information on a pattern that is to be formed on a mask is decided, the mask being a mask used in a plurality of exposure apparatus that form a projected image of the pattern formed on the mask onto an object via a projection optical system, the system comprising: a plurality of exposure apparatus that each have a projection optical system and an adjustment unit used to adjust an image-forming state of a projected image of the pattern on the object; and a computer connecting to the plurality of exposure apparatus via a communication channel, wherein for exposure apparatus subject to optimization selected from the plurality of exposure apparatus, the computer executes an optimization processing step in which a first step and a second step are repeatedly performed until an image-forming performance of the projection optical system in all the exposure apparatus subject to optimization is judged to be within a permissible range, according to a judgment made in the second step, wherein in the first step, an appropriate adjustment amount of an adjustment unit so as to adjust a forming state of the projected image of the pattern on the object is calculated for each exposure apparatus under target exposure conditions, which take into consideration correction information on the pattern, based on a plurality of types of information that includes the adjustment information of the adjustment unit including the pattern information and information related to the image-forming performance of the projection optical system corresponding to the adjustment information under predetermined exposure conditions, correction information on the pattern, and information on the permissible range of the image-forming performance, and in the second step, the judgment is made whether or not the predetermined image-forming performance of the projection optical system in at least one exposure apparatus subject to optimization is outside the permissible range under the target exposure conditions after the adjustment unit has been adjusted according to the appropriate adjustment amount for each exposure apparatus calculated in the first step, and by the judgment, based on the image-forming performance resulting to be outside the permissible range, the correction information is set according to a predetermined criterion; and a decision making step in which when the image-forming performance of the projection optical system in all the exposure apparatus subject to optimization falls within the permissible range, the correction information set in the optimization processing step is decided as correction information on the pattern.

According to the method, the computer executes the following optimization processing for the exposure apparatus subject to optimization, which are selected from a plurality of exposure apparatus connecting via a communication channel.

More specifically, in the processing step, the first step and the second step are repeatedly performed until the image-forming performance of the projection optical system in all the exposure apparatus is judged to be within the permissible range, according to the judgment made in the second step. In the first step, an appropriate adjustment amount of the adjustment unit so as to adjust the forming state of the projected image of the pattern on the object is calculated for each exposure apparatus under target exposure conditions, which take into consideration correction information on the pattern (under target exposure conditions where the pattern is replaced with a corrected pattern that has been corrected with the correction information), based on a plurality of types of information that includes the adjustment information of the adjustment unit including the pattern information and information related to the image-forming performance of the projection optical system corresponding to the adjustment information under predetermined exposure conditions, correction information on the pattern, and information on the permissible range of the image-forming performance. And then, in the second step, the judgment is made whether or not the predetermined image-forming performance of the projection optical system in at least one exposure apparatus is outside the permissible range under the target exposure conditions after the adjustment unit has been adjusted according to the appropriate adjustment amount for each exposure apparatus calculated in the first step, and by the judgment, based on the image-forming performance resulting to be outside the permissible range, the correction information is set according to a predetermined criterion.

And, in the above optimization processing step, when the image-forming performance of the projection optical system for all the exposure apparatus falls within the permissible range, that is, when there is no longer any image-forming performance outside the permissible range by the correction information setting, or when the image-forming performance of the projection optical system for all the exposure apparatus is within the permissible range from the very beginning, the correction information set in the above optimization processing step is decided as the correction information on the pattern.

Accordingly, by using the correction information on the pattern decided by the pattern decision system of the present invention or the information on the pattern that has been corrected using the correction information when manufacturing the mask, manufacturing (fabricating) a mask that can be commonly used in a plurality of exposure apparatus can be easily achieved.

In this case, the computer can execute in the second step, a first judgment step in which a judgment of whether or not the predetermined image-forming performance of the projection optical system in at least one exposure apparatus subject to optimization is outside the permissible range under the target exposure conditions after the adjustment unit has been adjusted according to the appropriate adjustment amount is made, based on the appropriate adjustment amount for each exposure apparatus calculated in the first step, and the adjustment information of the adjustment unit under predetermined exposure conditions and information related to an image-forming performance of the projection optical system corresponding to the adjustment information, and a setting step in which the correction information is set according to a predetermined criterion based on a predetermined image-forming performance resulting to be outside the permissible range, in the case the predetermined image-forming performance of the projection optical system in at least one exposure apparatus subject to optimization is outside the permissible range according to the results of the judgment in the first judgment step.

In this case, the computer can further execute in the second step, a second judgment step in which a judgment of whether or not a predetermined image-forming performance of a projection optical system in at least one exposure apparatus subject to optimization is outside the permissible range under the target exposure conditions after the adjustment unit has been adjusted according to the appropriate adjustment amount is made, based on the appropriate adjustment amount for each exposure apparatus calculated in the first step, the correction information set in the setting step, the adjustment information of the adjustment unit under the predetermined exposure conditions and information related to the image-forming performance of the projection optical system corresponding to the adjustment information, and information on the permissible range of the image-forming performance.

In the pattern decision system of the present invention, the predetermined reference can be a criterion based on an image-forming performance resulting outside the permissible range, and also can be a criterion when performing pattern correction to make the image-forming performance fall within the permissible range.

In the pattern decision system of the present invention, the computer can set the correction information in the optimization processing step, based on an average value of residual errors of an image-forming performance in the plurality of exposure apparatus subject to optimization.

In the pattern decision system of the present invention, in the case the information related to the image-forming performance is information on a difference between an image-forming performance of the projection optical system under the predetermined exposure conditions and a predetermined target value of the image-forming performance, and the adjustment information of the adjustment unit is information on adjustment amounts of the adjustment unit, in the first step, the computer can calculate the appropriate adjustment amount for each exposure apparatus, using a relational expression between the difference, a Zernike Sensitivity chart under said target exposure conditions, which denotes a relation between an image-forming performance of the projection optical system under the target exposure conditions and the coefficient of each term in the Zernike polynomial under said target exposure conditions, a wavefront aberration variation table consisting of a group of parameters, which denotes a relation between adjustment of the adjustment unit and wavefront aberration change of the projection optical system, and the adjustment amounts.

In this case, the predetermined target value can be a target value of an image-forming performance in a least one evaluation point of the projection optical system, which is externally input.

In this case, the target value of the image forming performance can be a target value of an image-forming performance at a representative point that is selected, or the target value of the image forming performance can be a target value of an image-forming performance converted from a target value of a coefficient set based on a decomposition coefficient to improve faulty elements, after the image-forming performance of the projection optical system has been decomposed into elements by an aberration decomposition method.

In the pattern decision system of the present invention, the relational expression can be an expression that includes a weighting function for performing weighting on any of the terms of each term of the Zernike polynomial.

In this case, the computer can further execute a procedure of displaying the image-forming performance of the projection optical system within and outside a permissible range under the predetermined exposure conditions using different colors, and also displaying a weight setting screen.

In the pattern decision system of the present invention, the weight can be set so that among the image-forming performance of the projection optical system under the target exposure conditions, weight in sections outside the permissible range is high.

In the pattern decision system of the present invention, in the second step, the computer can execute a judgment operation of whether or not the predetermined image-forming performance of the projection optical system in the at least one exposure apparatus is outside the permissible range, based on a difference between: an image-forming performance of the projection optical system under the target exposure conditions calculated for each exposure apparatus, based on information on wavefront aberration after adjustment and the Zernike Sensitivity chart under the target exposure conditions denoting a relation between an image-forming performance of the projection optical system under the target exposure conditions and coefficients of each term of the Zernike polynomial, the information on wavefront aberration after adjustment being obtained based on adjustment information of the adjustment unit under the predetermined exposure conditions and information on wavefront aberration of the projection optical system corresponding to the adjustment information, and an appropriate adjustment amount calculated in the first step; and the target value of the image-forming performance.

In the pattern decision system of the present invention, in the second step, the computer can execute making of a Zernike Sensitivity chart by calculation under target exposure conditions, which take into consideration the correction information, after setting the correction information, and then can use the Zernike Sensitivity chart as the Zernike Sensitivity chart under the target exposure conditions.

In the pattern decision system of the present invention, the predetermined target value can be a target value of an image-forming performance in a least one evaluation point of the projection optical system, which is externally input.

In this case, the target value of the image forming performance can be a target value of an image-forming performance at a representative point that is selected.

In the pattern decision system of the present invention, in the optimization processing step, the computer can calculate the appropriate adjustment amount, further taking into consideration restraint conditions, which are decided by adjustment amount limits due to the adjustment unit.

In the pattern decision system of the present invention, the computer can externally set at least a part of the field of the projection optical system as an optimization field range.

In the pattern decision system of the present invention, the computer can decide whether or not the first step and the second step have been repeated a predetermined number of times, and when the computer decides that the first step and the second step have been repeated a predetermined number of times before the image-forming performance of the projection optical system in all the exposure apparatus subject to optimization falls within the permissible range, can terminate the processing.

In the pattern decision system of the present invention, the computer can be a process computer that controls each section of any one of the plurality of exposure apparatus.

According to the tenth aspect of the present invention, there is provided an exposure apparatus that transfers a pattern formed on a mask onto an object via a projection optical system, the apparatus comprising: an adjustment unit that adjusts a forming state of a projected image of the pattern on an object by the projection optical system; and a processing unit connecting to the adjustment unit via a communication channel, the processing unit controlling the adjustment unit based on an appropriate adjustment amount of the adjustment unit under target exposure conditions, which take into consideration correction information on the pattern, the appropriate adjustment amount calculated using adjustment information under predetermined exposure conditions, information related to an image-forming performance of the projection optical system, and correction information on the pattern in a mask manufacturing stage.

According to the method, the processing unit calculates the appropriate adjustment amount of the adjustment unit under the target exposure conditions, which take into consideration correction information on the pattern, using the adjustment information and information related to the image-forming performance of the projection optical system under predetermined exposure conditions, and the correction information on the pattern in the mask manufacturing stage, and based on the calculated adjustment amount, the adjustment unit is controlled.

In this case, the correction information on the pattern in the manufacturing stage can be obtained, for example, by using the pattern decision method previously described. In this case, the processing unit will be able to calculate n adjustment amount that makes the image-forming performance of the projection optical system more favorable than when the correction information on the pattern is not taken into consideration. In addition, even in the case where it is difficult to calculate the adjustment amounts that make the image-forming performance of the projection optical system fall within the permissible range decided in advance under the target exposure conditions when the pattern correction information is not taken into consideration, the processing unit can calculate the adjustment amounts of the adjustment unit under the target exposure conditions taking into consideration the pattern correction information, which might make it possible to calculate the adjustment amounts that make the image-forming performance of the projection optical system fall within the permissible range decided in advance. And, when the processing unit controls the adjustment unit according to the calculated adjustment amount, the image-forming performance of the projection optical system can be adjusted more favorably than when the correction information on the pattern is not considered. Accordingly, by transferring the pattern of the mask onto the object via the projection optical system after adjustment, it becomes possible to transfer the pattern onto the object with good precision.

According to the eleventh aspect of the present invention, there is provided a program that makes a computer execute a predetermined processing in order to design a mask used in a plurality of exposure apparatus that form a projected image of the pattern formed on the mask onto an object via a projection optical system, the program making the computer execute: an optimization processing procedure in which a first procedure and a second procedure are repeatedly performed until an image-forming performance of the projection optical system in all the exposure apparatus is judged to be within a permissible range, according to a judgment made in the second step, wherein in the first procedure, an appropriate adjustment amount of an adjustment unit so as to adjust a forming state of the projected image of the pattern on the object is calculated for each exposure apparatus under target exposure conditions, which take into consideration correction information on the pattern, based on a plurality of types of information that include the adjustment information of the adjustment unit including the pattern information, and information related to the image-forming performance of the projection optical system corresponding to the adjustment information under predetermined exposure conditions, correction information on the pattern, and information on the permissible range of the image-forming performance, and in the second procedure, the judgment is made whether or not the predetermined image-forming performance of the projection optical system in at least one exposure apparatus is outside the permissible range under the target exposure conditions after the adjustment unit has been adjusted according to the appropriate adjustment amount for each exposure apparatus calculated in the first step, and by the judgment, based on the image-forming performance resulting to be outside the permissible range, the correction information is set according to a predetermined criterion; and a decision making procedure in which when the image-forming performance of the projection optical system in all the exposure apparatus falls within the permissible range, the correction information set in the optimization processing procedure is decided as correction information on the pattern.

When the plurality of information including the adjustment information of the adjustment unit under the predetermined exposure conditions for each exposure apparatus and the information related to the image-forming performance of the projection optical system corresponding to the adjustment information, the correction information on the pattern, and the information on the permissible range of the image-forming performance is input into the computer where the program is installed, the computer executes the following optimization processing in response to the input.

More specifically, in the processing procedure, the first procedure and the second procedure are repeatedly performed until the image-forming performance of the projection optical system in all the exposure apparatus is judged to be within the permissible range, according to the judgment made in the second procedure. In the first procedure, an appropriate adjustment amount of the adjustment unit so as to adjust the forming state of the projected image of the pattern on the object is calculated for each exposure apparatus under target exposure conditions, which take into consideration correction information on the pattern (under target exposure conditions where the pattern is replaced with a corrected pattern that has been corrected with the correction information), based on a plurality of types of information that includes the adjustment information of the adjustment unit including the pattern information and information related to the image-forming performance of the projection optical system corresponding to the adjustment information under predetermined exposure conditions, correction information on the pattern, and information on the permissible range of the image-forming performance. And then, in the second procedure, the judgment is made whether or not the predetermined image-forming performance of the projection optical system in at least one exposure apparatus is outside the permissible range under the target exposure conditions after the adjustment unit has been adjusted according to the appropriate adjustment amount for each exposure apparatus calculated in the first procedure, and by the judgment, based on the image-forming performance resulting to be outside the permissible range, the correction information is set according to a predetermined criterion.

And, in the above optimization processing procedure, when the image-forming performance of the projection optical system for all the exposure apparatus falls within the permissible range, that is, when there is no longer any image-forming performance outside the permissible range by the correction information setting, or when the image-forming performance of the projection optical system for all the exposure apparatus is within the permissible range from the very beginning, the correction information set in the above optimization processing procedure is decided as the correction information on the pattern (decision making procedure).

Accordingly, by using the correction information on the pattern decided by the first pattern decision method of the present invention or the information on the pattern that has been corrected using the correction information when manufacturing the mask, manufacturing (fabricating) a mask that can be commonly used in a plurality of exposure apparatus can be easily achieved, as is previously described. That is, according to the program of the present invention, a mask that can be used in a plurality of exposure apparatus can be designed easily, using the computer.

In this case, as the second procedure, the program can make the computer execute a first judgment procedure in which a judgment of whether or not a predetermined image-forming performance of a projection optical system in at least one exposure apparatus is outside the permissible range under the target exposure conditions after the adjustment unit has been adjusted according to the appropriate adjustment amount is made, based on the appropriate adjustment amount for each exposure apparatus calculated in the first procedure, and the adjustment information of the adjustment unit under predetermined exposure conditions and information related to an image-forming performance of the projection optical system corresponding to the adjustment information, and a setting procedure in which the correction information is set according to a predetermined criterion based on an image-forming performance resulting to be outside the permissible range, in the case a predetermined image-forming performance of a projection optical system in at least one exposure apparatus is outside the permissible range according to the results of the judgment in the first judgment procedure.

In this case, the program can further make the computer execute as the second procedure: a second judgment procedure in which a judgment of whether or not the predetermined image-forming performance of the projection optical system in at least one exposure apparatus is outside the permissible range under the target exposure conditions after the adjustment unit has been adjusted according to the appropriate adjustment amount is made, based on the appropriate adjustment amount for each exposure apparatus calculated in the first procedure, the correction information set in the setting procedure, the adjustment information of the adjustment unit under the predetermined exposure conditions and information related to the image-forming performance of the projection optical system corresponding to the adjustment information, and information on the permissible range of the image-forming performance.

In the program of the present invention, the predetermined criterion can be a criterion based on an image-forming performance resulting outside the permissible range, and can also be a criterion when performing pattern correction to make the image-forming performance fall within the permissible range, or the predetermined criterion can be a criterion for setting the correction information based on an average value of residual errors of the image-forming performance of the plurality of exposure apparatus.

In the program of the present invention, the information related to the image-forming performance can include information on wavefront aberration of the projection optical system after adjustment under the predetermined exposure conditions, or the information related to the image-forming performance can include information on wavefront aberration only of the projection optical system and information on an image forming performance of the projection optical system under the predetermined exposure conditions.

In the program of the present invention, in the case the information related to the image-forming performance is information on a difference between an image-forming performance of the projection optical system under the predetermined exposure conditions and a predetermined target value of the image-forming performance, and the adjustment information of the adjustment unit is information on adjustment amounts of the adjustment unit, the program can make the computer execute a calculating procedure of the appropriate adjustment amount for each exposure apparatus, using a relational expression between the difference, a Zernike Sensitivity chart under the target exposure conditions, which denotes a relation between an image-forming performance of the projection optical system and the coefficient of each term in the Zernike polynomial under the target exposure conditions, a wavefront aberration variation table consisting of a group of parameters, which denotes a relation between adjustment of the adjustment unit and wavefront aberration change of the projection optical system, and the adjustment amounts as the first procedure.

In this case, the program can further make the computer execute: a display procedure in which a setting screen of the target values at each evaluation point within the field of the projection optical system is shown, or the program can further make the computer execute: a display procedure in which an image-forming performance of the projection optical system is decomposed into elements by an aberration decomposition method, and the setting screen of the target values is shown along with a decomposition coefficient obtained after decomposition; and a conversion procedure in which a target value of a coefficient set according to the display of the setting screen is converted to a target value of the image-forming performance.

In the program of the present invention, the relational expression can be an expression that includes a weighting function for performing weighting on any of the terms of each term of the Zernike polynomial.

In this case, the program can further make the computer execute: a procedure of displaying the image-forming performance of the projection optical system within and outside a permissible range under the target exposure conditions using different colors, and also displaying a setting screen for the weighting.

In the program of the present invention, in the second procedure, the program can make the computer execute a judgment operation of whether or not the predetermined image-forming performance of the projection optical system in the at least one exposure apparatus is outside the permissible range, based on a difference between: an image-forming performance of the projection optical system under the target exposure conditions calculated for each exposure apparatus, based on information on wavefront aberration after adjustment and the Zernike Sensitivity chart under the target exposure conditions denoting a relation between an image-forming performance of the projection optical system under the target exposure conditions and coefficients of each term of the Zernike polynomial, the information on wavefront aberration after adjustment being obtained based on adjustment information of the adjustment unit under the predetermined exposure conditions and information on wavefront aberration of the projection optical system corresponding to the adjustment information, and an appropriate adjustment amount calculated in the first step; and the target value of the image-forming performance.

In the program of the present invention, in the second procedure, the program can make the computer execute a procedure of making a Zernike Sensitivity chart by calculation under target exposure conditions, which take into consideration the correction information, after setting the correction information, and then using the Zernike Sensitivity chart as the Zernike Sensitivity chart under the target exposure conditions.

In the program of the present invention, in the optimization processing procedure, the program can make the computer calculate the appropriate adjustment amount, further taking into consideration restraint conditions, which are decided by adjustment amount limits due to the adjustment unit.

In the program of the present invention, in the optimization processing procedure, the program can make the computer calculate the appropriate adjustment amount, with at least a part of the field of the projection optical system as an optimization field range, according to specification from the outside.

In the program of the present invention, the program can further make the computer execute: a procedure of deciding whether or not the first procedure and the second procedure have been repeated a predetermined number of times, and when the computer decides that the first procedure and the second procedure have been repeated a predetermined number of times before the image-forming performance of the projection optical system in all the exposure apparatus subject to optimization falls within the permissible range, the program makes the computer terminate the processing.

According to the twelfth aspect of the present invention, there is provided an information storage medium that can be read by a computer in which a program of the present invention is recorded.

In addition, in the lithography process, by transferring a device pattern onto a photosensitive object using any one of the first to third exposure methods, the device pattern can be formed onto the photosensitive object with good accuracy, which allows highly integrated microdevices to be manufactured with good yield. Accordingly, further from another aspect of the present invention, it can be said that the present invention is a device manufacturing method that includes a transferring step in which a device pattern is transferred onto a photosensitive object, using the first to third exposure methods of the present invention.

### BRIEF DESCRIPTON OF THE DRAWINGS

In the accompanying drawings;

FIG. 1 is a view showing a-configuration of a device manufacturing system related to an embodiment of the present invention;

FIG. 2 is a schematic view showing a configuration of a first exposure apparatus 922₁ in FIG. 1;

FIG. 3 is a sectional view of an example of a wavefront aberration measuring instrument;

FIG. 4A is a view showing beams emitted from a microlens array in the case when there is no aberration in an optical system, and FIG. 4B is a view showing beams emitted from a microlens array in the case when aberration exists in an optical system;

FIG. 5 is a flow chart showing an example of a processing algorithm executed by a CPU within a second computer;

FIG. 6 is a flow chart (No. 1) showing a processing in step 114 in FIG. 5;

FIG. 7 is a flow chart (No. 2) showing a processing in step 114 in FIG. 5;

FIG. 8 is a flow chart (No. 3) showing a processing in step 114 in FIG. 5;

FIG. 9 is a flow chart (No. 4) showing a processing in step 114 in FIG. 5;

FIG. 10 is a flow chart (No. 5) showing a processing in step 114 in FIG. 5;

FIG. 11 is a diagram showing a processing when restraint conditions are violated;

FIG. 12 is a planar view showing an example of an object working reticle used in aberration optimization of a plurality of equipment (equipments A and B) and in an experiment on pattern correction;

FIG. 13A is a view showing an example of the results of aberration optimization of equipment A and equipment B in the case when the working reticle in FIG. 12 is used without performing pattern correction, FIG. 13B is a view showing an example of the results in the case pattern correction is performed in the same optimization state as in equipment A and equipment B in FIG. 13A, and FIG. 13C is a view showing an example of the results in the case the same pattern correction as in FIG. 13B is performed, and then aberration of equipment A and equipment B is optimized with respect to the pattern after correction;

FIG. 14 is a flow chart (No. 1) showing an example of an operation performed when manufacturing a working reticle using a reticle design system and reticle manufacturing system;

FIG. 15 is a flow chart (No. 2) showing an example of an operation performed when manufacturing a working reticle using a reticle design system and reticle manufacturing system;

FIG. 16 is a flow chart (No. 3) showing an example of an operation performed when manufacturing a working reticle using a reticle design system and reticle manufacturing system;

FIG. 17 is a planar view showing an example of an existing master reticle used when manufacturing the working reticle in FIG. 12;

FIG. 18 is a schematic view showing a process of seamless exposure using the master reticle in FIG. 17 and two types of newly manufactured master reticles;

FIG. 19 is a flow chart showing another example of a processing algorithm executed by the CPU in the second computer; and

FIG. 20 is a view showing a configuration of a computer system related to a modified example.

### DESCRIPTION OF THE EMBODIMENTS

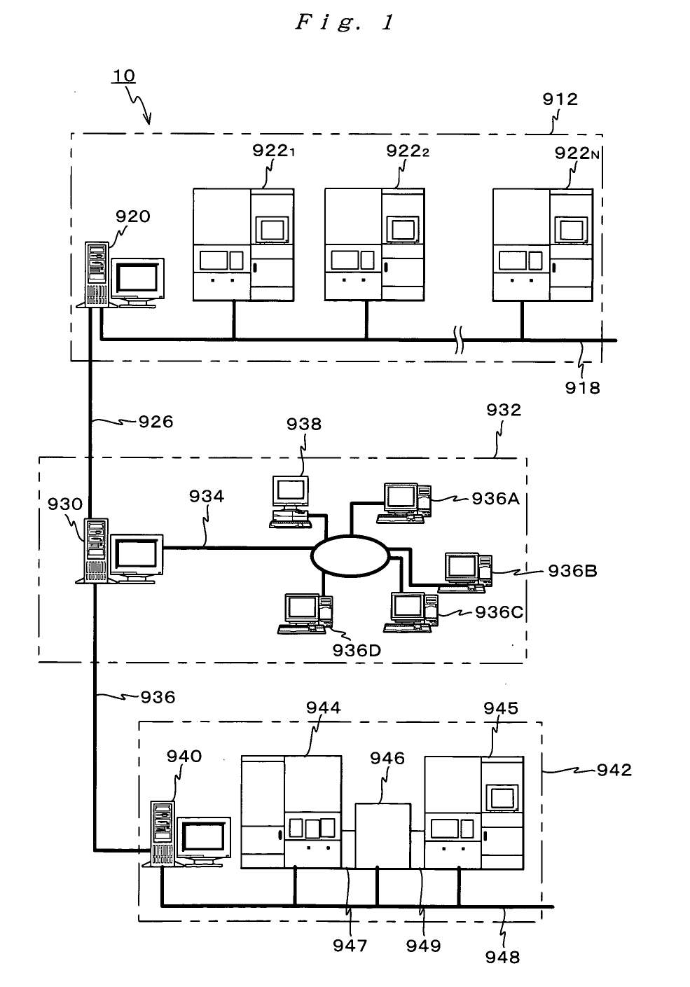

An embodiment of the present invention is described below, referring to FIGS. 1 to 18.

FIG. 1 shows an entire configuration of a device manufacturing system 10, which serves as a pattern decision system related to the embodiment, with a part of the configuration omitted.

Device manufacturing system 10 shown in FIG. 1 is a corporate LAN system built within a semiconductor factory of a device manufacturer (hereinafter referred to as ‘manufacturer A’ as appropriate) that is a user of device manufacturing units such as an exposure apparatus. Computer system 10 incorporates: a lithography system 912, which includes a first computer 920 and is arranged in a clean room; a reticle design system 932, which includes a second computer 930 that connects to the first computer 920 constituting lithography system 912 via a local area network (LAN) 926 serving as a communication channel; and a reticle manufacturing system 942, which includes a computer 940 used for production control that connects to the second computer 930 via a LAN 936 and is arranged in a different clean room.

Lithography system 912 is configured, including the first computer 920 composed of a mid-sized computer, a first exposure apparatus 922₁, a second exposure apparatus 922₂, up to an N^{th} exposure apparatus 922_{N} (hereinafter generally referred to as ‘exposure apparatus 922’ as appropriate), which are connected with one another via a LAN 918.

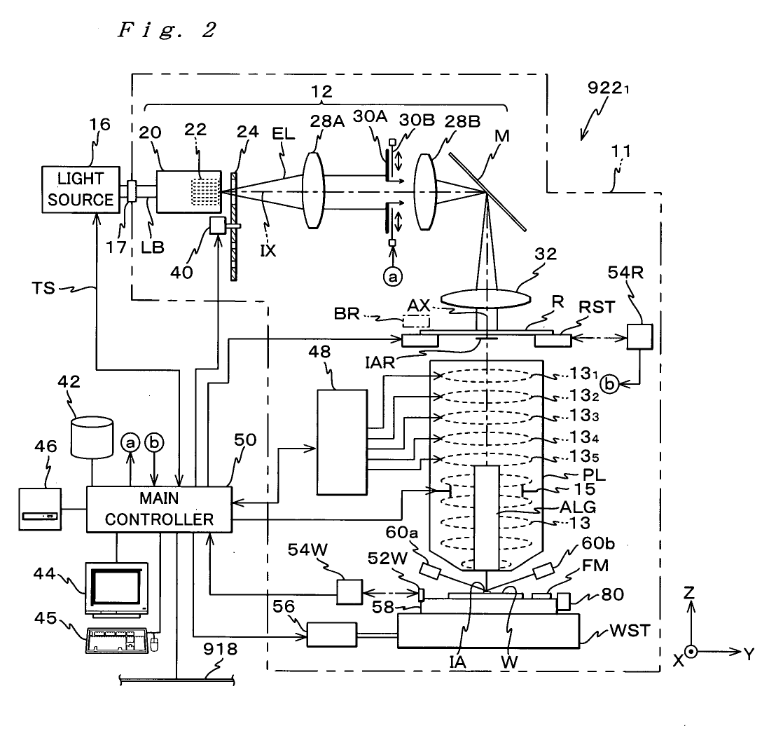

FIG. 2 shows a schematic configuration of the first exposure apparatus 922₁. Exposure apparatus 922₁ is a scanning projection exposure apparatus by a step-and-scan method, which uses a pulsed laser light source as the exposure light source (hereinafter referred to as ‘light source’), or in other words, a so-called scanning stepper (scanner).

Exposure apparatus 922₁ is equipped with: an illumination system composed of a light source 16 and an illumination optical system 12; a reticle stage RST serving as a mask stage that holds a reticle R, which is illuminated by an exposure illumination light EL serving as an energy beam from the illumination system; a projection optical system PL that projects exposure illumination light EL emitted from reticle R on a wafer W (on the image plane) serving as an object; a wafer stage WST, which has a Z-tilt stage 58 that holds wafer W; a control system for the above parts; and the like.

As light source 16, a pulsed ultraviolet light source that outputs a pulsed light in the vacuum ultraviolet region such as an F₂ laser (output wavelength: 157 nm) or an ArF excimer laser (output wavelength: 193 nm) is used. As light source 16, a light source that outputs pulsed light in the far ultraviolet region such as a KrF excimer laser (output wavelength: 248 nm), or outputs pulsed light in the ultraviolet region, may also be used.

In actual, light source 16 is set separately in a service room where the degree of cleanliness is lower than that of the clean room where a chamber 11, which houses the main body of the exposure apparatus composed of component parts of illumination optical system 12, reticle stage RST, projection optical system PL, wafer stage WST, and the like, is arranged. And, light source 16 connects to chamber 11 via a light transmitting optical system (not shown), which includes at least an optical axis adjusting optical system called a beam-matching unit as a part of its system. In light source 16, an internal controller of the apparatus controls the on/off operation of the output of laser beam LB, the energy of laser beam LB per pulse, the oscillation frequency (repetition frequency), the center wavelength and the spectral line half width (wavelength width), and the like, according to control information TS from a main controller 50.

Illumination optical system 12 is equipped with: a beam-shaping illuminance uniformity optical system 20 which includes parts such as a cylinder lens, a beam expander (none are shown), an optical integrator (homogenizer) 22, and the like; an illumination system aperture stop plate 24; a first relay lens 28A; a second relay lens 28B; a fixed reticle blind 30A; a movable reticle blind 30B; a mirror M for deflecting the optical path; a condenser lens 32, and the like. As the optical integrator a fly-eye lens, a rod integrator (internal reflection type integrator) or a diffracting optical element can be used. In the embodiment, because a fly-eye lens is used as optical integrator 22, optical integrator 22 will also be referred to as fly-eye lens 22 hereinafter.

Beam-shaping illuminance uniformity optical system 20 connects to the light transmitting optical system (not shown), via a light transmitting window 17 arranged in chamber 11. Beam-shaping illuminance uniformity optical system 20 shapes the cross section of laser beam LB pulsed and emitted from light source 16, which has entered beam-shaping illuminance uniformity optical system 20 via light transmitting window 17, using parts such as the cylinder lens and beam expander. Then, when the laser beam LB whose sectional shape has been shaped enters fly-eye lens 22 disposed on the exit side of beam-shaping illuminance uniformity optical system 20, in order to illuminate reticle R with uniform illuminance distribution, fly-eye lens 22 forms a surface light source (a secondary light source) consisting of a large number of point light sources on the outgoing side focal plane, which is arranged so that the focal plane substantially coincides with the pupil plane of illumination optical system 12. The laser beam emitted from the secondary light source is hereinafter referred to as “illumination light EL”.

In the vicinity of the focal plane on the exit side of fly-eye lens 22, illumination system aperture stop plate 24 constituted by a disk-like member is disposed. And, on illumination system aperture stop plate 24, for example, an aperture stop (conventional stop) constituted by a typical circular opening, an aperture stop (a small σ stop) for making coherence factor a small which is constituted by a small, circular opening, a ring-like aperture stop (annular stop) for forming a ring of illumination light, and a modified aperture stop for modified illumination composed of a plurality of openings disposed in an eccentric arrangement are arranged at a substantially equal angle (only two types of aperture stops are shown in FIG. 1). Illumination system aperture stop plate 24 is constructed and arranged to be rotated by a driving unit 40, for example a motor, controlled by main controller 50, and one of the aperture stops is selectively set to be on the optical path of illumination light EL, so that the shape of the illuminant surface in Koehler illumination described later is limited to a ring, a small circle, a large circle, four eyes or the like.

Instead of, or in combination with aperture stop plate 24, for example, an optical unit comprising at least one of a plurality of diffracting optical elements arranged switchable within the illumination optical system for distributing the illumination light to different areas on the pupil plane of the illumination optical system, a plurality of prisms that has at least one prism which moves along optical axis IX of the illumination optical system, or in other words, a plurality of prisms (conical prism, polyhedron prism, etc.) which can move along the optical axis of the illumination optical system, and a zoom optical system can be arranged in between light source 16 and optical integrator 22. And by changing the intensity distribution of the illumination light on the incident surface when the optical integrator 22 is a fly-eye lens, or the range of incident angle of the illumination light to the incident surface when the optical integrator 22 is an internal surface reflection type integrator, light amount distribution (the size and shape of the secondary illuminant) of the illumination light on the pupil plane of the illumination optical system, or in other words, the loss of light due to the change of conditions for illuminating reticle R, is preferably suppressed. Incidentally, in the embodiment, a plurality of light source images (virtual images) formed by the internal surface reflection type integrator is also referred to as the secondary light source. In addition, a variable aperture stop (iris diaphragm) used for flare extinction instead of for setting the light amount distribution on the pupil plane of the illumination optical system may be used, with the beam-shaping optical system.

On the optical path of illumination light EL emitted from illumination system aperture stop plate 24, a relay optical system is arranged that is made up of the first relay lens 28A and the second relay lens 28B, with fixed reticle blind 30A and movable reticle blind 30B disposed in between.

Fixed reticle blind 30A is disposed on a plane slightly defocused from a plane conjugate to the pattern surface of reticle R, and forms a rectangular opening to set a rectangular illumination area IAR on reticle R. In addition, in the vicinity of fixed reticle blind 30A, movable reticle blind 30B is disposed that has an opening whose position and width are variable in the scanning direction, and at the beginning and the end of scanning exposure, by limiting illumination area IAR further via movable reticle blind 30B, exposure of unnecessary areas can be prevented. Furthermore, the width of the opening of movable reticle blind 30B is also variable in the non-scanning direction, which is orthogonal to the scanning direction, which allows the width of illumination area IAR in the non-scanning direction to be adjusted according to the pattern of reticle R that is to be transferred onto the wafer. In the embodiment, by defocusing fixed reticle blind 30A, the intensity distribution of illumination light IL on reticle R in the scanning direction is made substantially into a trapezoidal shape. However, other configurations may be employed to make the intensity distribution of illumination light IL into a trapezoidal shape, as in, for example, disposing inside the illumination optical system a density filter whose attenuation ratio gradually increases toward the edges or a diffracting optical element that partially diffracts the illumination light. In addition, in the embodiment, both fixed reticle blind 30A and movable reticle blind 30B are arranged, however, the movable reticle blind can be arranged without the fixed reticle blind. Furthermore, by using the internal reflection type integrator whose rectangular exit surface is disposed slightly away from the plane conjugate to the pattern surface of the reticle as optical integrator 22, the fixed reticle blind may not be required. In this case, the movable reticle blind (masking blade) is to be disposed close to the exit surface of the internal reflection type integrator, for example, so that the movable reticle blind substantially coincides with the plane conjugate to the pattern surface of the reticle.

On the optical path of illumination light EL after the second relay lens 28B making up the relay optical system, deflecting mirror M is disposed for reflecting illumination light EL having passed through the second relay lens 28B toward reticle R. And, on the optical path of illumination light EL after mirror M, condenser lens 32 is disposed.

In the configuration described above, the incident surface of fly-eye lens 22, the plane on which movable reticle blind 30B is disposed, and the pattern surface (the object plane of projection optical system PL) of reticle R are set optically conjugate to one another, whereas the light source surface formed on the focal plane on the exit side of fly-eye lens 22 (the pupil plane of the illumination optical system) and the Fourier transform plane of projection optical system PL (the exit pupil plane) are set optically conjugate to each other, so as to form a Koehler illumination system.

The operation of the illumination optical system that has the configuration described above will be briefly described below. Laser beam LB emitted in pulse from light source 16 enters beam-shaping illuminance uniformity optical system 20, which shapes the cross section of the beam. The beam then enters fly-eye lens 22, and the secondary light source is formed on the focal plane on the exit side of fly-eye lens 22.

When illumination light EL emitted from the secondary light source passes through one of the aperture stops on illumination system aperture stop plate 24, it then passes through the apertures of fixed reticle blind 30A and movable reticle blind 30B via the first relay lens 28A, and then passes through the second relay lens 28B and is deflected vertically downward by mirror M. Then, after passing through condenser lens 32, illumination light EL illuminates the rectangular or rectangular slit-shaped illumination area IAR on reticle R held on reticle stage RST with uniform illuminance. Illumination area IAR narrowly extends in the X-axis direction and its center is to substantially coincide with optical axis AX of projection optical system PL.

On reticle stage RST, reticle R is mounted and held by electrostatic chucking (or by vacuum chucking) or the like (not shown). Reticle stage RST is structured so that it can be finely driven on a horizontal plane (an XY plane) by a reticle stage drive system (not shown) that includes linear motors or the like. In addition, reticle stage RST can be moved in the scanning direction (in this case, the Y-axis direction, which is the lateral direction of the page surface of FIG. 1) within a predetermined stroke range. The position of reticle stage RST within the XY plane is measured by a reticle laser interferometer 54R arranged on reticle stage RST or via a reflection surface formed in the stage, at a predetermined resolution (e.g., a resolution around 0.5 to 1 nm), and the measurement results are supplied to main controller 50.

Material used for reticle R should be different depending on the light source used. More particularly, when an ArF excimer laser or KrF excimer laser is used as the light source, synthetic quartz, fluoride crystal such as fluorite, fluorine-doped quartz or the like can be used, whereas, when an F₂ laser is used as the light source, the material used for reticle R needs to be fluoride crystal such as fluorite, fluorine-doped quartz or the like.

Projection optical system PL is, for example, a both-side telecentric reduction system, and the projection magnification of projection optical system PL is, e.g., ¼, ⅕, or ⅙. Therefore, when illumination area IAR on reticle R is illuminated with illumination light EL in the manner described above, the image of the pattern formed on reticle R is reduced by the above projection magnification via projection optical system PL, and then is projected and transferred onto a slit shaped exposure area (an area conjugate with illumination area IAR) on wafer W coated with a resist (photosensitive material).

As projection optical system PL, as is shown in FIG. 2, a dioptric system is used composed only of a plurality of refracting optical elements (lenses) 13, such as around 10 to 20. Of the plurality of lenses 13 making up projection optical system PL, a plurality of lenses 13₁, 13₂, 13₃, 13₄, 13₅ (in this case, for the sake of simplicity, five lens elements are used) in the object-plane side (reticle R side) are movable lenses, which can be driven externally by an image-forming characteristics correction controller 48. The barrel holds lenses 13₁, 13₂, 13₃, 13₄, 13₅, via double-structured lens holders (not shown), respectively. Interior lens holders hold lenses 13₁, 13₂, 13₃, 13₄, 13₅, respectively, and these lens holders are supported with respect to exterior lens holders in the gravitational direction at three points by driving devices such as piezo elements (not shown). And, by independently adjusting the applied voltage to the driving devices, lenses 13₁, 13₂, 13₃, 13₄, 13₅ can be shifted in a Z-axis direction, which is the optical-axis direction of projection optical system PL, and can be driven (tilted) in a direction of inclination relative to the XY plane (that is, a rotational direction around the X-axis and a rotational direction around the Y-axis).

Other lenses 13 are held by the barrel, via typical lens holders. Projection optical system PL may also be formed so that not only lenses 13₁, 13₂, 13₃, 13₄, 13₅, but also lenses disposed near the pupil plane or the image plane of projection optical system PL, or an aberration correcting plate (optical plate) for correcting the aberration of projection optical system PL, especially the non-rotational symmetric component, can be driven. Furthermore, the degree of freedom (the number of movable directions) of such movable optical elements is not limited to three, but may be one, two or four and over. In addition, the barrel structure of projection optical system PL or the drive mechanism of the lens elements is not limited to the arrangements described above, and the arrangement can be arbitrary.

In addition, near the pupil plane of projection optical system PL, an aperture stop 15 is arranged whose numerical aperture (N.A.) is continuously variable within a predetermined range. For example, a so-called iris aperture stop is used as such aperture stop 15, and aperture stop 15 operates under the control of main controller 50.

When an ArF excimer laser or KrF excimer laser is used as illumination light EL, the material for each of the lens elements used in projection optical system PL can be synthetic quartz besides fluoride crystal such as fluorite, or fluorine-doped quartz referred to earlier. However, when an F₂ laser is used, the material of the lenses used in projection optical system PL all has to be fluoride crystal such as fluorite, or fluorine-doped quartz.

Wafer stage WST is structured freely drivable on the XY two-dimensional plane by a wafer stage drive section 56. And wafer W is held on a Z-tilt stage 58 mounted on wafer stage WST by electrostatic chucking (or vacuum chucking) or the like, via a wafer holder (not shown).

In addition, Z-tilt stage 58 is constituted so that it moves in the Z-axis direction and can also be driven (tilted) in a direction of inclination relative to the XY plane (that is, the rotational direction around the X-axis (θx) and the rotational direction around the Y-axis (θy)) on wafer stage WST by a drive system (not shown). This structure allows the surface position (the position in the Z-axis direction and the inclination relative to the XY plane) of wafer W held on Z-tilt stage 58 to be set to a desired state.

Furthermore, a movable mirror 52W is fixed on Z-tilt stage 58, and with a wafer laser interferometer 54W externally disposed, the position of Z-tilt stage 58 is measured in the X-axis direction, the Y-axis direction, and θz direction (rotational direction around the Z-axis), and the positional information measured by interferometer 54W is supplied to main controller 50. Main controller 50 controls wafer stage WST (and Z-tilt stage 58) via wafer stage drive section 56 (including the drive systems of both wafer stage WST and Z-tilt stage 58), based on the measurement values of interferometer 54W. Instead of movable mirror 52W, for example, a reflection surface formed by mirror polishing the edge surface (side surface) of Z-tilt stage 58 may be used.

In addition, on Z-tilt stage 58, a fiducial mark plate FM is fixed on which fiducial marks such as fiducial marks for the so called base-line measurement of alignment system ALG (to be described later) are formed, with the surface of fiducial mark plate FM at substantially the same height as the surface of wafer W.

In addition, on the side surface in the +Y side (the right side of the page surface in FIG. 2) of Z-tilt stage 58, a wavefront aberration measuring instrument 80 is attached, which serves as a portable wavefront measuring unit that is freely detachable to Z-tilt stage 58.

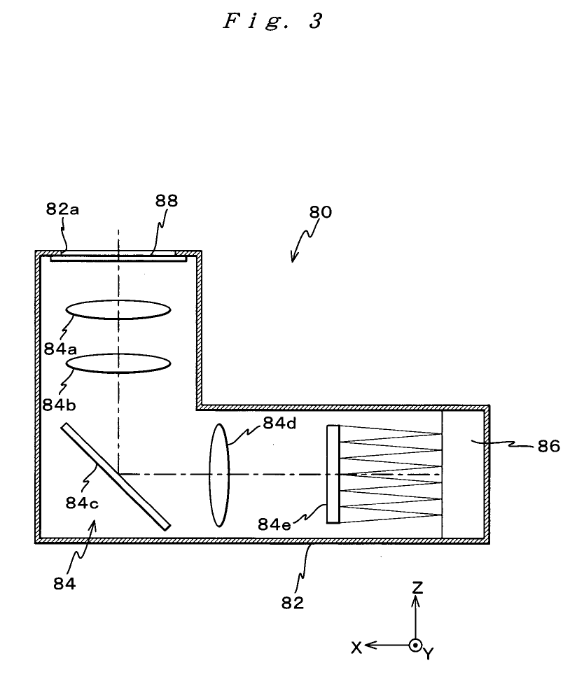

As is shown in FIG. 3, wavefront aberration measuring instrument 80 is equipped with a hollow housing 82, a light-receiving optical system 84 consisting of a plurality of optical elements disposed inside housing 82 in a predetermined positional relation, and a light-receiving section 86 disposed on the −X end inside housing 82

Housing 82 consists of a member that has the shape of a letter L in the XZ section and forms a space therein. At the topmost section of housing 82 (the end in the +Z direction), an opening 82a that has a circular shape when in a planar view is formed so that the light from above housing 82 will be guided into the inner space of housing 82. In addition, a cover glass 88 is arranged so as to cover opening 82a from the inside of housing 82. On the upper surface of cover glass 88, a light shielding membrane that has a circular opening in the center is formed by vapor deposition of metal such as chrome, which shields unnecessary light from entering light-receiving optical system 84 when the wavefront aberration of projection optical system PL is measured.

Light-receiving optical system 84 is made up of an objective lens 84a, a relay lens 84b, and a deflecting mirror 84c, which are sequentially arranged from under cover glass 88 inside housing 82 in a downward direction, and a collimator lens 84d and a microlens array 84e, which are sequentially arranged on the −X side of deflecting mirror 84c. Deflecting mirror 84c is arranged having an inclination of 45°, and by deflecting mirror 84c, the optical path of the light entering the objective lens 84a from above in a downward vertical direction is deflected toward collimator lens 84d. Each of the optical members constituting light-receiving optical system 84 is fixed to the wall of housing 82 on the inner side, via holding members (not shown), respectively. Microlens array 84e is constituted with a plurality of small convex lenses (lens elements) arranged in an array shape on a plane perpendicular to the optical path.

Light-receiving section 86 is composed of parts like a light-receiving element such as a two-dimensional CCD, and an electric circuit such as a charge transport controlling circuit. The light-receiving element has an area large enough to receive all the beams that have entered objective lens 84a and are outgoing microlens array 84e. The measurement data of light-receiving section 86 is output to main controller 50 via a signal line (not shown) or by wireless transmission.

By using the above wavefront aberration measuring instrument 80, the wavefront aberration of projection optical system PL can be measured on body. The measurement method of the wavefront aberration of projection optical system PL using wavefront aberration measuring instrument 80 will be described later in the description.

Referring back to FIG. 2, in exposure apparatus 922₁ of the embodiment, a multiple focal point position detection system (hereinafter simply referred to as a ‘focal point position detection system’) of an oblique incident method is arranged, consisting of an irradiation system 60a and a light-receiving system 60b. Irradiation system 60a has a light source whose on/off is controlled by main controller 50, and the system irradiates image-forming beams toward the image-forming plane of projection optical system PL for making multiple pinhole or slit images from an oblique direction with respect to optical axis AX, while light-receiving system 60b receives the reflection beams of such image-forming beams at the surface of wafer W. As such a focal point position detection system (60a, 60b), a system that has a configuration similar to the one disclosed in, for example, Kokai (Japanese Unexamined Patent Application Publication) No. 6-283403, and the corresponding U.S. Pat. No. 5,448,332. As long as the national laws in designated states (or elected states), to which this international application is applied, permit, the above disclosures of the publication and the U.S. Patent are incorporated herein by reference.

In the focal point position detection system disclosed in the above publication and the U.S. Patent, the measurement points where the image-forming beams are irradiated are set not only within exposure area IA but also on the outside, however, it is also acceptable to set a plurality of measurement points substantially only within exposure area IA. In addition, the shape of the irradiation area of the image-forming beam at each measurement point is not limited to a pinhole or a slit, and other shapes may be employed, such as for example, a parallelogram or a rhombus.

On scanning exposure and the like, main controller 50 performs auto-focusing (automatic focusing) and auto-leveling by controlling the Z-position and the inclination with respect to the XY plane of wafer W so as to eliminate defocus via wafer stage drive section 56, based on defocus signals from light-receiving system 60b, such as S-curve signals. In addition, on the wavefront aberration measurement described later, main controller 50 measures and aligns the Z-position of wavefront aberration measuring instrument 80, using the focal point position detection system (60a, 60b). The inclination of wavefront aberration measuring instrument 80 may also be measured in the measurement, if necessary.

Furthermore, exposure apparatus 922₁ is equipped with an alignment system ALG by an off-axis method, which is used for positional measurement and the like of alignment marks on wafer W held on wafer stage WST and reference marks formed on a fiducial mark plate FM. As alignment system ALG, for example, a sensor of an FIA (Field Image Alignment) system based on an image-processing method is used. This sensor irradiates a broadband detection beam that does not expose the resist on the wafer on a target mark, picks up an image of the target mark formed on the photodetection surface by the reflection light from the target mark and an index image with a pick-up device (such as a CCD), and outputs the imaging signals. The sensor, however, is not limited to the FIA system sensor, and it is a matter of course that an alignment sensor that irradiates a coherent detection light on a target mark and detects the scattered light or diffracted light generated from the target mark, or a sensor that detects two diffracted lights (for example, the same order) generated from a target mark that are made to interfere can be used independently, or appropriately combined.

Furthermore, in exposure apparatus 922₁ in the embodiment, although it is omitted in the drawings, a pair of reticle alignment microscopes is arranged above reticle R, each constituted by a TTR (Through The Reticle) alignment optical system. With this system, the light of the exposure wavelength is used to observe a reticle mark on reticle R (or a reference mark on reticle stage RST) and its corresponding fiducial mark on the fiducial mark plate at the same time, via projection optical system PL. In the embodiment, as alignment system ALG and the reticle alignment system, systems that have a structure similar to the ones disclosed in, for example, Kokai (Japanese Unexamined Patent Application Publication) No. 7-176468 and the corresponding U.S. Pat. No. 5,646,413, are used. As long as the national laws in designated states (or elected states), to which this international application is applied, permit, the above disclosures of the publication and the U.S. Patent are incorporated herein by reference.

The control system in FIG. 2 is mainly composed of main controller 50. Main controller 50 is constituted by a so-called workstation (or microcomputer) made up of a CPU (Central Processing Unit), ROM (Read Only Memory), RAM (Random Access Memory), and the like, and besides the various control operations described above, main controller 50 controls the overall operation of the entire apparatus.

In addition, main controller 50 is externally connected to, for example, a storage unit 42 made up of hard disks, an input unit 45 configured including a pointing-device such as a key board and a mouse, a display unit 44 such as a CRT display or liquid-crystal display, and a drive unit 46 which is an information recording medium such as CD (compact disc), DVD (digital versatile disc), MO (magneto-optical disc), or FD (flexible disc). Furthermore, main controller 50 also connects to LAN918 described earlier.

In storage unit 42, measurement data of wavefront aberration only of projection optical system PL (hereinafter referred to as ‘stand-alone wavefront aberration’) is stored, which is measured before projection optical system PL is incorporated into the main body of the exposure apparatus in the making stage of the exposure apparatus by, for example, a wavefront aberration measuring instrument called PMI (Phase Measurement Interferometer).

In addition, in storage unit 42, for example, wavefront aberration data or wavefront aberration correction amount (the difference between wavefront aberration and stand-alone wavefront aberration previously described) data, which is measured by wavefront aberration measuring instrument 80 in a state where the position of each of the movable lenses 13, to 13₅ in directions of three degrees of freedom, the Z position and inclination of wafer W (Z-tilt stage 58), and wavelength λ of the illumination light are adjusted so as to set a correct (e.g., the aberration being zero or under a permissible value) forming state of the projected image projected on wafer W by projection optical system PL under a plurality of reference exposure conditions (to be described later), and information on the adjustment amount at this point, that is, the positional information of movable lenses 13₁ to 13₅ in directions of three degrees of freedom, the positional information of wafer W in directions of three degrees of freedom, and the information on wavelength λ of the illumination light, is stored. In this case, because the reference exposure conditions refereed to above are each controlled by an ID, serving as identification information, hereinafter, each reference exposure condition will be referred to as a reference ID. That is, in storage device 42, information on the adjustment amount under a plurality of reference IDs, and data on wavefront aberration or wavefront aberration correction amount is stored.

In the information storage medium (hereinafter will be described as a CD-ROM for the sake of convenience) set in drive unit 46, a conversion program is stored for converting positional deviations measured using wavefront aberration measuring instrument 80 (to be described later) into coefficients of each term of the Zernike polynomial.

The remaining exposure apparatus 922₂, 922₃, . . . up to 922_{N} have a configuration similar to exposure apparatus 922₁ described above.

Referring back to FIG. 1, reticle design system 932 is a system for designing (a pattern of) a reticle serving as a mask. Reticle design system 932 is equipped with the second computer 930 composed of a mid-size computer (or a large-size computer), design terminals 936A to 936D consisting of small-size computers connecting to the second computer 930 via a LAN934, and a computer 938 used for optical simulation. In design terminals 936A to 936D, partial design of the reticle pattern corresponding to the circuit pattern (chip pattern) on each of the layers of the semiconductor devices or the like is performed. The second computer 930, in the embodiment, also serves as a-circuit design central control unit, and the second computer 930 controls the allocation or the like of the design area in each of the terminals 936A to 936D.

The reticle pattern designed in each of the terminals 936A to 936D has sections that require tight line width accuracy, as well as sections that require relatively loose line width accuracy, and in each of the terminals 936A to 936D, identification information for identifying a position (e.g., a section requiring relatively loose line width accuracy) where the circuit can be divided is generated, and the identification information is sent to the second computer 930 along with the design data of the partial reticle pattern. The second computer 930 then transmits the design data information of the reticle pattern used in each layer and the identification information that indicates the position where the circuit can be divided to computer 940 used for production control in reticle manufacturing system 942, via LAN 936.

Reticle manufacturing system 942 is a system for manufacturing a working reticle on which a transfer pattern designed by reticle design system 932 is formed. Reticle manufacturing system 942 is equipped with computer 940 used for production control composed of a mid-size computer, an EB (Electron Beam) exposure apparatus 944 connecting with computer 940 via a LAN 948, a coater developer (hereinafter shortened to ‘C/D’) 946, an optical exposure apparatus 945, and the like. EB exposure apparatus 944 and C/D 946 connects via an interface section 947, and C/D 946 and optical exposure apparatus 945 connects via an interface section 949.

EB exposure apparatus 944 draws a predetermined pattern on a reticle blank composed of quartz (SiO₂) such as synthetic quartz (SiO₂), fluorine (F) containing quartz, or fluorite (CaF₂), or the like where a predetermined electron beam resist is coated, using an electron beam.

C/D 946 coats a resist on a substrate (a reticle blank) that will be a master reticle or a working reticle, and also performs development after the exposure of the substrate.

As optical exposure apparatus 945, a scanning stepper similar to exposure apparatus 922₁ previously described is used. However, in optical exposure apparatus 945, instead of a wafer holder, a substrate holder that holds a reticle blank serving as a substrate is arranged.

Inside interface section 947, a substrate transport system is arranged that delivers a substrate (the reticle blank for a master reticle) between a vacuum atmosphere within EB exposure apparatus 944 and C/D 946 arranged in a predetermined gas atmosphere almost the same as the atmospheric pressure. In addition, inside interface section 949, a substrate transport system is arranged that delivers a substrate (a reticle blank for a master reticle or a working reticle) between the C/D and optical exposure apparatus 945 that are both arranged in a predetermined gas atmosphere almost the same as the atmospheric pressure.

Besides the parts described above, although, it is now shown, reticle manufacturing system 942 is equipped with a blank housing section for housing a plurality of reticle blanks (substrates) used for master reticles or working reticles, and a reticle housing section for housing a plurality of master reticles that are manufactured (made) in advance. In the embodiment, as the master reticle, besides the master reticle manufactured by reticle manufacturing system 942 in the manner described below, a reticle that has an existing pattern formed on a predetermined substrate by chrome deposition or the like is used.

In reticle manufacturing system 942 that has the configuration described above, based on the design data information on the reticle pattern and the identification information that shows the positions where the reticle pattern can be divided from the second computer to computer 940, computer 940 divides an original plate pattern containing the reticle pattern enlarged by a predetermined magnification a (a is, for example, 4 times, or 5 times) to a plurality of original plate patterns at the dividing positions decided by the identification information referred to above. And of the divided original plate patterns, computer 940 makes the data of the patterns different (including patterns that have not been made yet) from the master reticle housed in the reticle housing section previously described.

Next, based on the data of the new original plate patterns that have been made, computer 940 draws each of the new original plate patterns on the different reticle blanks for master reticles on which the predetermined electron beam resist is coated by C/D 946, using EB exposure apparatus 944.

In this manner, a plurality of reticle blanks on which each of the new original plate patterns are formed is developed by C/D 946, and in the case the electron beam resist is a positive type resist, for example, the resist pattern on the area where the energy beam is not irradiated is preserved as the original plate pattern. In the embodiment, as the electron beam resist, a resist that contains a pigment that absorbs (or reflects) the exposure light used in optical exposure apparatus 942 is used. Therefore, after the development of the resist, the reticle blanks on which the resist patterns are formed can be used as, for example, master reticles (hereinafter will also be appropriately referred to as ‘parent reticles’), without having to perform deposition of chromium film serving as a metal film on the reticle blanks where the resist patterns are formed.

Then, according to the instructions of computer 940, optical exposure apparatus 945 uses the plurality of master reticles (the new master reticles made in the manner described above and the master reticles that have been prepared in advance) to perform exposure while performing a screen connecting operation (perform seamless exposure), and the images of the pattern on the plurality of master reticles reduced by 1/α are transferred on predetermined substrates, more specifically, on the reticle blanks for working reticles that have a photoresist coated on the surface. The working reticles that are used when making the circuit pattern of each layer in semiconductors or the like are manufactured in the manner described above. The manufacturing of such working reticles will be described further, later in the description.

Next, a wavefront aberration measuring method in the first to N^{th} exposure apparatus 922₁ to 922_{N} is described, which is performed during maintenance operation or in a state where adjustment of projection optical system PL has been performed so as to make a proper forming state of the image projected on wafer W by projection optical system PL. In the description below, for the sake of simplicity, the aberration of light-receiving optical system 84 within wavefront aberration measuring instrument 80 is to be small enough to be ignored.

As a premise, the conversion program in the CD-ROM set in drive unit 46 is to be installed into storage unit 42.

On normal exposure, wavefront aberration measuring instrument 80 is detached from Z-tilt stage 58, therefore, on wavefront measurement, first of all, an operator or a service engineer or the like (hereinafter referred to as an ‘operator’ as appropriate) performs an operation of attaching wavefront aberration measuring instrument 80 onto the side surface of Z-tilt stage 58. On the attachment operation, wavefront aberration measuring instrument 80 is fixed to a predetermined surface (in this case, a surface on the +Y side) via a bolt, a magnet, or the like so that wavefront aberration measuring instrument 80 fits within the movement strokes of wafer stage WST (Z-tilt stage 58)

After the attachment operation described above, in response to the command input to start the measurement by the operator or the like, main controller 50 moves wafer stage WST via wafer stage drive section 56, so that wavefront aberration measuring instrument 80 is positioned below alignment system ALG. Then, main controller 50 detects the alignment marks (not shown) arranged in wavefront aberration measuring instrument 80 with alignment system ALG, and based on the detection results and the measurement values of laser interferometer 54W at the point of detection, main controller calculates the position coordinates of the alignment marks and obtains the accurate position of wavefront aberration measuring instrument 80. Then, after measuring the position of wavefront aberration measuring instrument 80, main controller 50 performs wavefront aberration measurement in the manner described below.

First of all, main controller 50 loads a measurement reticle (not shown, hereinafter referred to as a ‘pinhole reticle’) on which pinhole patterns are formed onto reticle stage RST with a reticle loader (not shown). The pinhole reticle is a reticle on which pinholes (pinholes that become ideal point light sources and generate spherical waves) are formed at a plurality of points on the pattern surface within the area corresponding to illumination area IAR previously described.

In the pinhole reticle used in this case, the wavefront aberration is to be measured on the entire surface of the pupil plane of projection optical system PL by arranging a diffusion plate on its upper surface or the like and distributing the light from the pinhole patterns on substantially the entire surface of the pupil plane of projection optical system PL. In the embodiment, aperture stop 15 is arranged in the vicinity of the pupil plane of projection optical system PL; therefore, wavefront aberration will substantially be measured on the pupil plane set by aperture stop 15.

After the pinhole reticle is loaded, main controller 50 detects reticle alignment marks formed on the pinhole reticle using the reticle alignment system described earlier, and based on the detection results, aligns the pinhole reticle at a predetermined position. With this operation, the center of the pinhole reticle is substantially made to coincide with the optical axis of projection optical system PL.

Then, main controller 50 gives control information TS to light source 16 so as to make it start emitting the laser beam. With this operation, illumination light EL from illumination optical system 12 is irradiated on the pinhole reticle. Then, the beams outgoing from the plurality of pinholes on the pinhole reticle are condensed on the image plane via projection optical system PL, and the images of the pinholes are formed on the image plane.

Next, main controller 50 moves wafer stage WST via wafer stage drive section 56 so that the substantial center of opening 82a of wavefront aberration measuring instrument 80 coincides with an image-forming point where an image of a pinhole on the pinhole reticle (hereinafter referred to as focused pinhole) is formed, while monitoring the measurement values of wafer laser interferometer 54W. On such operation, based on the detection results of the focal point position detection system (60a, 60b), main controller 50 finely moves Z-tilt stage in the Z-axis direction via wafer stage drive section 56 so that-the upper surface of cover glass 88 of wavefront aberration measuring instrument 80 coincides with the image plane on which the pinhole images are formed. When Z-tilt stage is being finely moved, the angle of inclination of wafer stage WST is also adjusted if necessary. In this manner, the imaging beam of the focused pinhole enters light-receiving optical system 84 via the opening in the center of cover glass 88, and is received by the photodetection elements making up light-receiving section 86.

More particularly, from the focused pinhole on the pinhole reticle, a spherical wave is generated which becomes parallel beams via projection optical system PL and objective lens 84a, relay lens 84b, mirror 84c, and collimator lens 84d that make up the light-receiving optical system 84 and irradiate microlens array 84e. With this operation, the pupil plane of projection optical system PL is relayed to microlens array 84e, and then divided thereby. And then, by each lens element of microlens array 84e, the respective beams (divided beams) are condensed on the light-receiving surface of the photodetection element, and the images of the pinholes are respectively formed on the light-receiving surface.

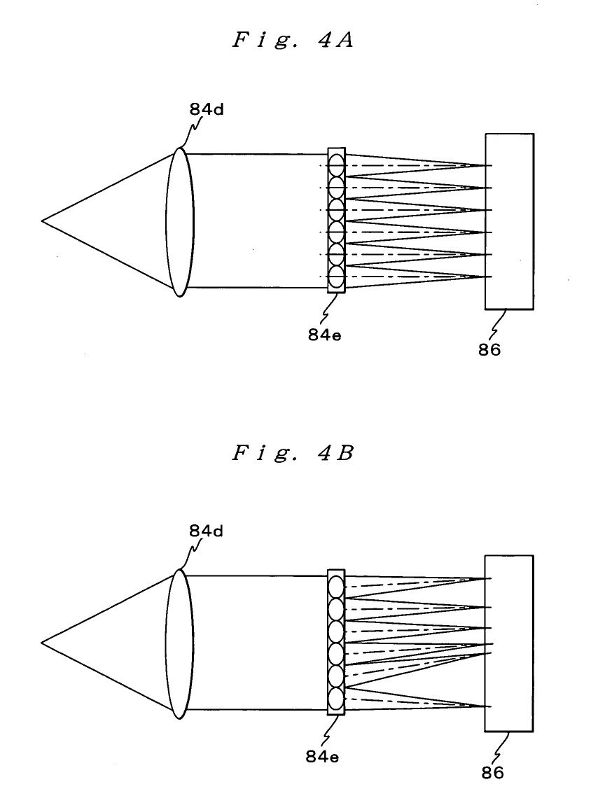

In this case, when projection optical system PL is an ideal optical system that does not have any wavefront aberration, the wavefront in the pupil plane of projection optical system PL becomes an ideal shape (in this case, a planar surface), and as a consequence, the parallel beams incident on microlens array 84e is supposed to be a plane wave that has an ideal wavefront. In this case, as is shown in FIG. 4A, a spot image (hereinafter also referred to as a ‘spot’) is formed at a position on the optical axis of each lens element that make up microlens array 84e.

However, in projection optical system PL, because there normally is wavefront aberration, the wavefront of the parallel beams incident on microlens array 84e shifts from the ideal wavefront, and corresponding to the shift, that is, the inclination of the wavefront with respect to the ideal wavefront, the image-forming position of each spot shifts from the position on the optical axis of each lens element of microlens array 84e, as is shown in FIG. 4B. In this case, the positional deviation of each spot from its reference point (the position of each lens element on the optical axis) corresponds to the inclination of the wavefront.

Then, the light incident on each condensing point on the photodetection element constituting light-receiving section 86 (beams of the spot images) is photoelectrically converted at the photodetection elements, and the photoelectric conversion signals are sent to main controller 50 via the electric circuit. Based on the photodetection conversion signals, main controller 50 calculates the image-forming position of each spot, and furthermore, calculates the positional deviations (Δξ, Δη) using the calculation results and the positional data of the known reference points and stores it in the RAM. On such operation, the measurement values (Xᵢ, Yᵢ) of laser interferometer 54W at that point are being sent to main controller 50.

When measurement of positional deviations of the spot images by wavefront aberration measuring instrument 80 at the image-forming point of the focused pinhole image is completed, main controller 50 moves wafer stage WST so that the substantial center of opening 82a of wavefront aberration measuring instrument 80 coincides with the image-forming point of the next pinhole image. When this movement is completed, main controller 50 makes light source 16 generate the laser beam as is described above, and similarly calculates the image-forming position of each spot. Hereinafter, a similar measurement is sequentially performed at the image-forming point of other pinhole images.

When all the necessary measurement has been completed in the manner described above, in the RAM of main controller 50, data on positional deviations (Δξ, Δη) of each pinhole image at the image-forming point previously described and the coordinate data of each image-forming point (the measurement values of laser interferometer 54W (Xᵢ, Yᵢ) when performing measurement at the image-forming point of each pinhole image) are stored. On the measurement above, the position and size of the illumination area on the reticle may be changed per each pinhole, for example, using movable reticle blind 30B, so that only the focused pinhole on the reticle or a partial area that includes at least the focused pinhole is illuminated by illumination light EL.

Next, main controller 50 loads the conversion program into the main memory, and then, based on positional deviation data (Δξ, Δη) of each pinhole image at the image-forming point stored in the RAM and the coordinate data of each image-forming point, the wavefront (wavefront aberration) corresponding to the image-forming points of the pinhole images, or in other words, the wavefront corresponding to the first measurement point through the n^{th} measurement point within the field of projection optical system PL, which in this case are the coefficients of each of the terms in the Zernike polynomial in equation (3) below, such as the coefficient Z₁ of the 1^{st} term through the coefficient Z₃₇ of the 37^{th} term, are calculated according to the conversion program, based on the principle described below.

In the embodiment, the wavefront of projection optical system PL is obtained by calculation according to the conversion program, based on the above positional deviations (Δξ, Δη). That is, positional deviations (Δξ, Δη) are values directly reflecting the gradient of the wavefront to an ideal wavefront, therefore, conversely, the wavefront can be reproduced based on positional deviations (Δξ, Δη). As is obvious from the physical relation between positional deviations (Δξ, Δη) and the wavefront above, the principle of this embodiment for calculating the wavefront is the known Shack-Hartmann wavefront calculation principle.

Next, the method of calculating the wavefront based on the above positional deviations will be described briefly.

As is described above, positional deviations (Δξ, Δη) correspond to values of the gradient of the wavefront, and by integrating the positional deviations the shape of the wavefront (or to be more precise, deviations from the reference plane (the ideal plane)) is obtained. When the wavefront (deviations from the reference plane) is expressed as W(x, y) and the proportional coefficient is expressed as k, then the relation in the following equations (1) and (2) exist.

$$\begin{matrix}Δξ = k \frac{\partial W}{\partial x} & ( 1 ) \\ Δη = k \frac{\partial W}{\partial y} & ( 2 )\end{matrix}$$

Because it is not easy to integrate the gradient of the wavefront given only as positional deviations, the surface shape is expanded in series so that it fits the wavefront. In this case, an orthogonal system is chosen for the series. The Zernike polynomial is a series suitable to expand a surface symmetrical with respect to an axis in, whose component in the circumferential direction is a trigonometric series. That is, when wavefront W is expressed using a polar coordinate system (ρ, θ), it can be expanded as equation (3) below.

$$W ( ρ , θ ) = {\sum }_{i} {Z}_{i} \cdot {f}_{i} ( ρθ ) \qquad ( 3 )$$

Because the terms are an orthogonal system, coefficient Zᵢ of each of the terms can be determined independently. Cutting i at an appropriate value corresponds to a sort of filtering. An example of f₁ of the 1^{st} term through the 37^{th} term is shown in Table 1 below, along with Zᵢ. The 37^{th} term in Table 1 corresponds to the 49^{th} term in the actual Zernike polynomial, however, in the description, it will be addressed as the term i=37 (the 37^{th} term). That is, in the present invention, the number of terms in the Zernike polynomial is not limited in particular.

TABLE 1

| Zi | fi |
|---|---|
| Z1 | 1 |
| Z2 | ρ cos θ |
| Z3 | ρ sin θ |
| Z4 | 2ρ² − 1 |
| Z5 | ρ² cos 2θ |
| Z6 | ρ² sin 2θ |
| Z7 | (3ρ³ − 2ρ) cos θ |
| Z8 | (3ρ³ − 2ρ) sin θ |
| Z9 | 6ρ⁴ − 6ρ² + 1 |
| Z10 | ρ³ cos 3θ |
| Z11 | ρ³ sin 3θ |
| Z12 | (4ρ⁴ − 3ρ²) cos 2θ |
| Z13 | (4ρ⁴ − 3ρ²) sin 2θ |
| Z14 | (10ρ⁵ − 12ρ³ + 3ρ) cos θ |
| Z15 | (10ρ⁵ − 12ρ³ + 3ρ) sin θ |
| Z16 | 20ρ⁶ − 30ρ⁴ + 12ρ² − 1 |
| Z17 | ρ⁴ cos 4θ |
| Z18 | ρ⁴ sin 4θ |
| Z19 | (5ρ⁵ − 4ρ³) cos 3θ |
| Z20 | (5ρ⁵ − 4ρ³) sin 3θ |
| Z21 | (15ρ⁶ − 20ρ⁴ + 6ρ²) cos 2θ |
| Z22 | (15ρ⁶ − 20ρ⁴ + 6ρ²) sin 2θ |
| Z23 | (35ρ⁷ − 60ρ⁵ + 30ρ³ − 4ρ) cos θ |
| Z24 | (35ρ⁷ − 60ρ⁵ + 30ρ³ − 4ρ) sin θ |
| Z25 | 70ρ⁸ − 140ρ⁶ + 90ρ⁴ − 20ρ² + 1 |
| Z26 | ρ⁵ cos 5θ |
| Z27 | ρ⁵ sin 5θ |
| Z28 | (6ρ⁶ − 5ρ⁴) cos 4θ |
| Z29 | (6ρ⁶ − 5ρ⁴) sin 4θ |
| Z30 | (21ρ⁷ − 30ρ⁵ + 10ρ³) cos 3θ |
| Z31 | (21ρ⁷ − 30ρ⁵ + 10ρ³) sin 3θ |
| Z32 | (56ρ⁸ − 105ρ⁶ + 60ρ⁴ − 10ρ²) cos 2θ |
| Z33 | (56ρ⁸ − 105ρ⁶ + 60ρ⁴ − 10ρ²) sin 2θ |
| Z34 | (126ρ⁹ − 280ρ⁷ + 210ρ⁵ − 60ρ³ + 5ρ) cos θ |
| Z35 | (126ρ⁹ − 280ρ⁷ + 210ρ⁵ − 60ρ³ + 5ρ) sin θ |
| Z36 | 252ρ¹⁰ − 630ρ⁸ + 560ρ⁶ − 210ρ⁴ + 30ρ² − 1 |
| Z37 | 924ρ¹² − 2772ρ¹⁰ + 3150ρ⁸ − 1680ρ⁶ + 420ρ⁴ − 42ρ² + 1 |

Because the differentials are detected as the above positional deviations in actual, the fitting needs to be performed on the differential coefficients. In the polar coordinate system (x=ρcosθ, y=ρsinθ), the partial differentials are represented by equations (4), (5) below.

$$\begin{matrix}\frac{\partial W}{\partial x} = \frac{\partial W}{\partial ρ} cos θ - \frac{1}{ρ} \frac{\partial W}{\partial θ} sin θ & ( 4 ) \\ \frac{\partial W}{\partial y} = \frac{\partial W}{\partial ρ} sin θ + \frac{1}{ρ} \frac{\partial W}{\partial θ} cos θ & ( 5 )\end{matrix}$$

Because the differentials of Zernike polynomials are not orthogonal, the fitting needs to be performed in the least-squares method. Because the information (amount of positional deviation) on the image-forming point is given in the X and Y directions for each spot image, when the number of pinholes (in the embodiment, n is, e.g., 33) is expressed as n, then the number of observation equations derived from the above equations (1) through (5) is 2n (=66).

Each term of the Zernike polynomial corresponds to an optical aberration. Furthermore, lower-order terms substantially correspond to Seidel's aberrations. Therefore, by using the Zernike polynomial, the wavefront aberration of projection optical system PL can be obtained.

The computation procedure of the conversion program is determined according to the above principle, and by the calculation process according to the conversion program, the wavefront (wavefront aberration) for the first up to the n^{th} measurement point within the field of projection optical system PL, or in this case, the coefficients of terms of the Zernike polynomial, such as the coefficient Z₁ of the 1^{st} term up to the coefficient Z₃₇ of the 37^{th} term, can be obtained.

Referring back to FIG. 1, in the hard disk or the like equipped in the first computer 920, target information that the first to third exposure apparatus 922₁ to 922₃ should achieve, such as resolution (resolving power), practical minimum line width (device rule), wavelength of illumination light EL (center wavelength and width of the wavelength range), information on the pattern subject to transfer, or any other information related to the projection optical system that decides the performance of exposure apparatus 922₁ to 922₃ that can be a target value, is stored. In addition, in the hard disk or the like equipped in the first computer 920, target information of the exposure apparatus that will be installed in the future, such as, information on patterns that are going to be used, is also stored as target information.

Meanwhile, in the memory unit of the hard disk or the like equipped in the second computer 930, a reticle pattern design program is installed that makes a proper forming state of a projected image of a predetermined pattern on the wafer surface (image plane) under the target exposure conditions corresponding to the pattern in any of the exposure apparatus 922₁ to 922₃, and a first database and a second database stored that comes with the design program is also stored. More specifically, the first database and the second database that comes with the design program is stored in an information storage medium such as a CD-ROM, which is inserted into a drive unit such as a CD-ROM drive equipped in the second computer 930, and then the design program is installed into a storage unit such as a hard disk from the drive unit, and the first database and the second database are copied.

The first database is a database of a wavefront aberration variation table for each type of the projection optical system (projection lens) equipped in the exposure apparatus, such as in exposure apparatus 922₁ to 922_{N}. In this case, the wavefront aberration variation table is a variation table consisting of a group of data, arranged in a predetermined order. The group of data is obtained by simulation, which uses a model substantially equivalent to projection optical system PL, and as the simulation results, adjustment parameter variations by a unit adjustment quantity are obtained as the data, which can be used to optimize the image-forming state of the projected image of the pattern on the wafer, as well as the image-forming performance corresponding to a plurality of measurement points within the field of projection optical system PL, or more specifically, wavefront data, for example, data on how the coefficients of the 1^{st} term through the 37^{th} term of the Zernike polynomial change.

In the embodiment, as the above adjustment parameters, a total of 19 parameters are used, which are the drive amount of movable lenses 13₁, 13₂, 13₃, 13₄, and 13₅ in directions of each degree of freedom (movable directions), that is, drive amount z₁, θx₁, θy1, z₂, θx₂, θy₂, z₃, θx₃, θy₃, z₄, θx₄, θy₄, z₅, θx₅, and θy₅, the drive amount of the surface of wafer W (Z-tilt stage 58) in directions of three degrees of freedom, that is, drive amount Wz, Wθx, and Wθy, and the shift amount of the wavelength of illumination light EL, that is, shift amount Δλ.

Next, the procedure of generating the first database will be briefly described. First of all, design values of projection optical system PL (numerical aperture N.A., coherence factor σ, wavelength λ of the illumination light, data of each lenses or the like) are input into a computer used for the simulation where specific optical software is installed. Then, data on a first measurement point, which is an arbitrary position within the field of projection optical system PL, are input in the simulation computer.

Next, data on unit quantity of the movable lenses in directions of each degree of freedom (movable directions), the surface of wafer W in the above directions of each degree of freedom, and on the shift amount of the wavelength of the exposure light is input. For example, when instructions to drive movable lens 13₁ in the + direction of the Z-direction shift by the unit quantity is input, the simulation computer calculates the amount of deviation of a first wavefront from an ideal wavefront at a first measurement point set in advance within the field of projection optical system PL; for example, variation of the coefficients of each term (e.g., the 1^{st} term through the 37^{th} term) of the Zernike polynomial. The data of the variation is shown on the display of the simulation computer, while also being stored in memory as parameter PARA1P1.

Next, when instructions to drive movable lens 13₁ in the + direction of the Y-direction tilt (rotation θx around the x-axis) by the unit quantity is input, the simulation computer calculates the amount of deviation of a second wavefront from the ideal wavefront at the first measurement point, for example, variation of the coefficients of the above terms of the Zernike polynomial, and data on the variation are shown on the display, while also being stored in memory as parameter PARA2P1.

Next, when instructions to shift movable lens 13₁ in the + direction of the X-direction tilt (rotation θy around the y-axis) by the unit quantity is input, the simulation computer calculates the deviation of a third wavefront from the ideal wavefront at the first measurement point, for example, variation of the coefficients of the above terms of the Zernike polynomial, and data on the variation are shown on the display, while also being stored in memory as parameter PARA3P1.

Then, input for each measurement point from the second measurement point to the n^{th} measurement point is performed in the same procedure as is described above, and each time instructions are input for the Z-direction shift, the Y-direction tilt, and the X-direction tilt of movable lens 13₁, the simulation computer calculates the data of the first, second, and third wavefront in each measurement point, such as variation of the coefficients of the above terms of the Zernike polynomial, and data on each variation are shown on the display, while also being stored in memory as parameters PARA1P2, PARA2P2, PARA3P2, through PARA1Pn, PARA2Pn, PARA3Pn.

Also for the other movable lenses 13₂, 13₃, 13₄, and 13₅, in the same procedure as is described above, input for each measurement point is performed and instructions are input for driving movable lenses 13₂, 13₃, 13₄,and 13₅ in the + direction only by the unit quantity in directions of each degree of freedom. And in response, the simulation computer calculates the wavefront data for each of the first through n^{th} measurement points when movable lenses 13₂, 13₃, 13₄, and 13₅ are driven only by the unit quantity in directions of each degree of freedom, such as variation of the coefficients of the above terms of the Zernike polynomial, and parameter (PARA4P1, PARA5P1, PARA6P1, . . . PARA15P1), parameter (PARA4P2, PARA5P2, PARA6P2, . . . PARA15P2), . . . up to parameter (PARA4Pn, PARA5Pn, PARA6Pn, . . . PARA15Pn) are stored in memory.

In addition, also for wafer W, in the same procedure as is described above, input for each measurement point is performed and instructions are input for driving wafer W in the + direction only by the unit quantity in directions of each degree of freedom. And in response, the simulation computer calculates the wavefront data for each of the first through n^{th} measurement points when wafer W is driven only by the unit quantity in directions of each degree of freedom, such as variation of the coefficients of the above terms of the Zernike polynomial, and parameter (PARA16P1, PARA17P1, PARA18P1), parameter (PARA16P2, PARA17P2, PARA18P2), . . . up to parameter (PARA16Pn, PARA17Pn, PARA18Pn) are stored in memory.

Furthermore, also for the wavelength shift, in the same procedure as is described above, input for each measurement point is performed and instructions are input for shifting the wavelength in the + direction only by the unit quantity. And in response, the simulation computer calculates the wavefront data for each of the first through n^{th} measurement points when the wavelength is driven in the + direction only by the unit quantity, such as variation of the coefficients of the above terms of the Zernike polynomial, and PARA19P1, PARA19P2, . . . up to PARA19Pn are stored in memory.

The above parameters PARAiPj (i=1 to 19, j=1 to n) are each a row matrix (vector) of 1 row and 37 columns. That is, when n=33, adjustment parameter PARA1 is expressed as in equation (6) below.

$$\begin{matrix}PARA1P1 = [ {Z}_{1 , 1} {Z}_{1 , 2} {⋯⋯Z}_{1 , 37} ] \\ PARA1P2 = [ {Z}_{2 , 1} {Z}_{2 , 2} {⋯⋯Z}_{2 , 37} ] \\ ⋮ \\ PARA1Pn = [ {Z}_{33 , 1} {Z}_{33 , 2} {⋯⋯Z}_{33 , 37} ]\end{matrix} \} \qquad ( 6 )$$

In addition, adjustment parameter PARA2 is expressed as in equation (7) below.

$$\begin{matrix}PARA2P1 = [ {Z}_{1 , 1} {Z}_{1 , 2} ⋯ {Z}_{1 , 37} ] \\ PARA2P2 = [ {Z}_{2 , 1} {Z}_{2 , 2} ⋯ {Z}_{2 , 37} ] \\ ⋮ \\ PARA2Pn = [ {Z}_{33 , 1} {Z}_{33 , 2} ⋯ {Z}_{33 , 37} ]\end{matrix} \} \qquad ( 7 )$$

Similarly, for the other parameters PARA3 to PARA19, they can be expressed as in equation (8) below.

$$\begin{matrix}PARA3P1 = [ {Z}_{1 , 1} {Z}_{1 , 2} ⋯ {Z}_{1 , 37} ] \\ PARA3P2 = [ {Z}_{2 , 1} {Z}_{2 , 2} ⋯ {Z}_{2 , 37} \\ ⋮ \\ PARA3Pn = [ {Z}_{33 , 1} {Z}_{33 , 2} ⋯ {Z}_{33 , 37} ] \\ ⋮ \\ PARA19P1 = [ {Z}_{1 , 1} {Z}_{1 , 2} ⋯ {Z}_{1 , 37} ] \\ PARA19P2 = [ {Z}_{2 , 1} {Z}_{2 , 2} ⋯ {Z}_{2 , 37} ] \\ ⋮ \\ PARA19Pn = [ {Z}_{33 , 1} {Z}_{33 , 2} ⋯ {Z}_{33 , 37} ]\end{matrix} \} \qquad ( 8 )$$

Then, PARA1P1 to PARA19Pn, consisting of variation of the coefficients of each term of the Zernike polynomial stored in memory in the manner described above, are grouped by each adjustment parameter, and then the data is sorted as a wavefront aberration variation table for each of the 19 adjustment parameters. More specifically, a wavefront aberration variation table is made for each adjustment parameter, as is representatively shown for adjustment parameter PARA1 in equation (9) below, and the tables are stored in memory.

$$[ \begin{matrix}PARA1P1 \\ PARA1P2 \\ ⋮ \\ PARA1Pn\end{matrix} ] = [ \begin{matrix}{Z}_{1 , 1} & {Z}_{1 , 2} & ⋯ & {Z}_{1 , 36} & {Z}_{1 , 37} \\ {Z}_{2 , 1} & & & & {Z}_{2 , 37} \\ ⋮ & & ⋰ & & ⋮ \\ {Z}_{32 , 1} & & & & {Z}_{32 , 37} \\ {Z}_{33 , 1} & {Z}_{33 , 2} & ⋯ & {Z}_{33 , 36} & {Z}_{33 , 37}\end{matrix} ] \qquad ( 9 )$$

Then, the database made in the manner described above, consisting of the wavefront aberration variation table for each type of the projection optical system, is stored in the hard disk or the like equipped in the second computer 930 as the first database. In the embodiment, one wavefront aberration variation table is made for the same type (having the same design data) of projection optical system. However, the wavefront aberration variation table can be made for each projection optical system (that is, by exposure apparatus unit), regardless of the type.

Next, the second database will be described.

The second database is a database that includes different exposure conditions, that is, optical conditions and evaluation items, and a calculation chart consisting of a variation of the coefficients of each term of the Zernike polynomial, e.g., variation amount by 1 λ from the 1^{st} term to the 37^{th} term, that is, the Zernike Sensitivity chart, for calculating the image-forming performance such as aberrations (or its index values) of the projection optical system, obtained under the plurality of exposure conditions decided by the combination of the above optical conditions and evaluation items. The optical conditions are exposure wavelength, numerical aperture N.A. of the projection optical system (maximum N.A, N.A. set on exposure, and the like), and illumination conditions (illumination N.A (numerical aperture N.A. of the illumination optical system) or illumination a (coherence factor), and the aperture shape of illumination system aperture stop plate 24 (the light amount distribution of the illumination light on the pupil plane of the illumination optical system, that is, the shape of the secondary light source)) and the like, and the evaluation items are the type of mask, line width, evaluation amount, and pattern information, and the like.

In the description below, the Zernike Sensitivity chart will also be referred to as Zernike Sensitivity, or ZS. In addition, the file consisting of the Zernike Sensitivity obtained under a plurality of exposure conditions will also hereinafter be appropriately referred to as a ‘ZS file’. Further, the variation of the coefficients of each term of the Zernike polynomial is not limited to 1 λ, and other values (such as 0.5 λ) may also be used.

In the embodiment, each Zernike Sensitivity chart contains the following 12 aberrations as the image-forming performance: that is, distortions Disₓ and Dis_{y} in the X-axis and Y-axis directions, four types of line width abnormal values CM_{V}, CM_{H}, CM_{R}, and CM_{L} that serve as index values for coma, four types of curvature of field CF_{V}, CF_{H}, CF_{R}, and CF_{L}, and two types of spherical aberration SA_{V} and SA_{H}.

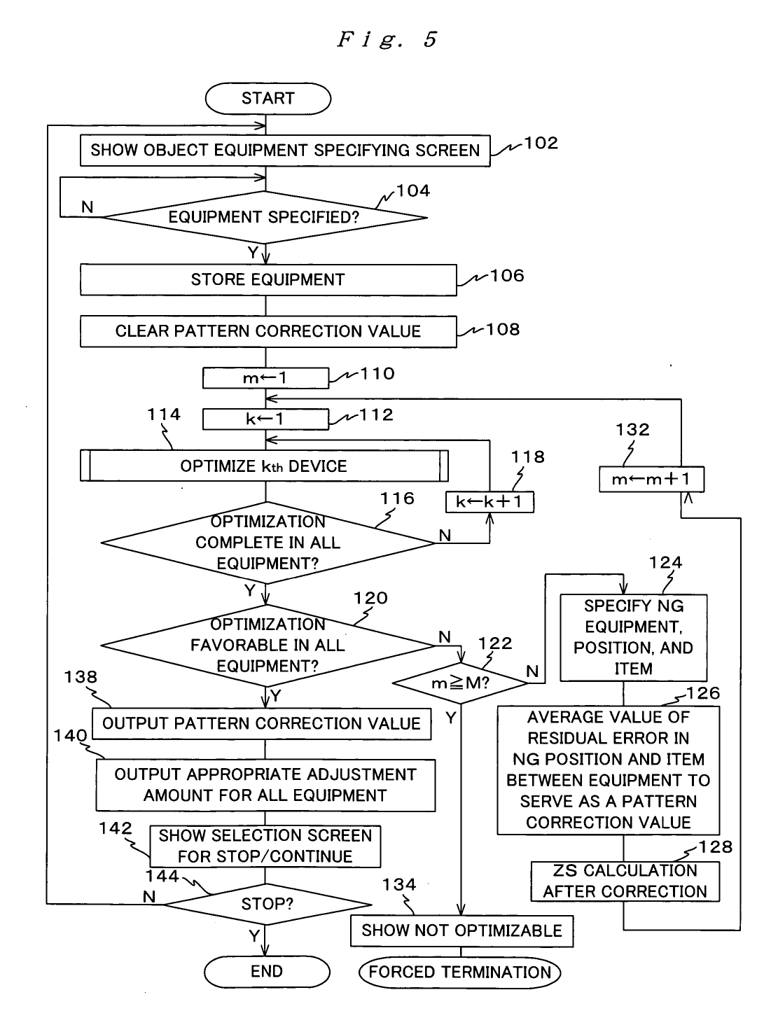

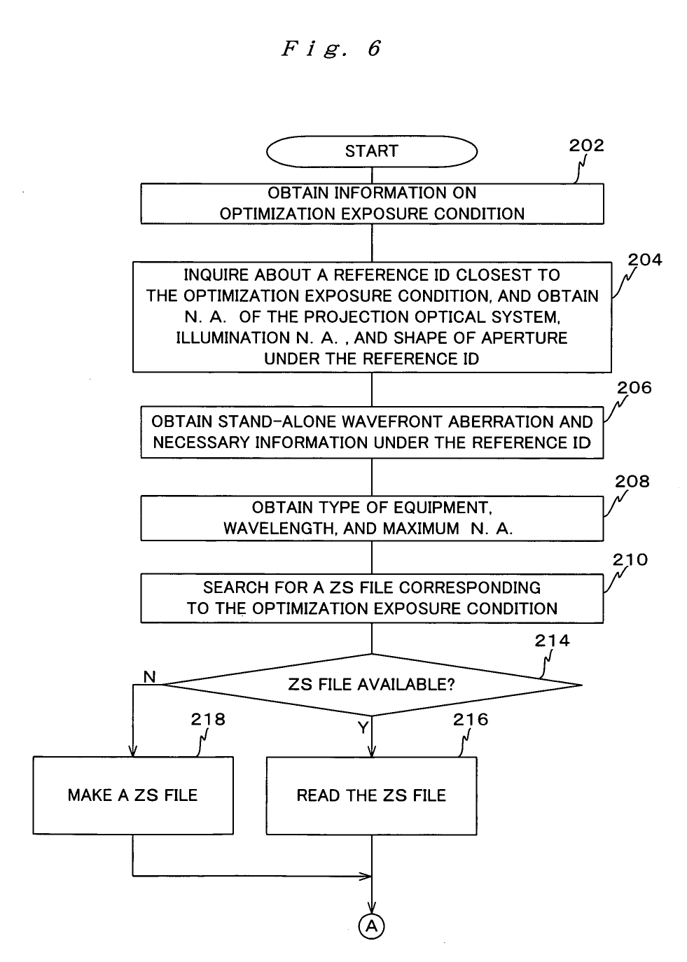

Next, the method or the like of designing a pattern to be formed on the reticle that can be shared in a plurality of exposure apparatus using the design program of the reticle pattern referred to earlier will be described, according to a flow chart in FIG. 5 (and FIGS. 6 to 10), which shows a processing algorithm of a processor installed in the second computer 930.

The flow chart shown in FIG. 5 starts, for example, when an operator of the first computer 920 in the clean room sends instructions for optimization that include specifying the exposure apparatus subject to optimizing and other necessary information (information on specifying the permissible values of the image-forming performance, which will be described later, information on input of restraint conditions, information on setting weight value, information on specifying the target value (target) of the image-forming performance, and the like, are also included when necessary) by e-mail or the like, and an operator on the second computer 930 side inputs instructions to start the processing into the second computer 930. In this case, the term ‘exposure apparatus subject to optimization’ is used in the embodiment, since in the process of designing the above pattern to be formed on the reticle, adjustment of the image-forming performance (optimization of the image-forming performance of the projection optical system) is performed so as to optimize the forming state of the projected image of the pattern on the image plane by projection optical system PL equipped in each exposure apparatus 922 selected, as it will be described later in the description.

First of all, in step 102, the specifying screen for specifying the equipment subject to optimization is shown on the display.

In the next step, step 104, the procedure is on standby until the operator specifies the equipment specified in the previous e-mail, such as exposure apparatus 922₁, 922₂, or the like, via a pointing device such as a mouse. Then, when the equipment is specified, the procedure proceeds to step 106, where data on the specified equipment is stored, such as, by storing the unit number.

In the next step, step 108, pattern correction value serving as correction information are cleared (set to zero), and in step 110, a counter m is initialized (m←1), which indicates the number of executions of operations such as optimization of the image-forming performance of the projection optical system of each equipment, evaluation (judgment) of the results of optimization, and the like, which will be described later.

In the next step, step 112, a counter k is initialized (k←1), which shows the number of equipment subject to optimization of the image-forming performance of the projection optical system.

In the next step, step 114, the procedure moves to a subroutine for optimization processing where k^{th} equipment (in this case, the first) is optimized.

In subroutine 114 of the optimization processing, first of all, in step 202 in FIG. 6, information on exposure conditions (hereinafter also referred to as ‘optimization exposure conditions’) subject to optimization is obtained. More specifically, an inquiry is sent to the first computer 920 for information on the type of the subject pattern, and for information on N.A. and illumination conditions (illumination N.A, illumination σ, the type of aperture stop, and the like) of the projection optical system that can be set in the subject equipment for an optimal pattern transfer, and the information is obtained. In the case of the embodiment, because the purpose is to design a pattern formed on a reticle that can be shared in a plurality of equipment, the response from the first computer 920 to the second computer on the subject pattern information should be pattern information of the same target for all the subject equipment.

In the next step, step 204, an inquiry is made to the first computer 920 on the reference ID of the subject equipment closest to the above optimization exposure conditions, and setting information on N.A. and illumination conditions (e.g., illumination N.A, illumination a, and the type of aperture stop) of the projection optical system under the reference ID is obtained.

In the next step, step 206, information on stand-alone wavefront aberration and necessary information under the above reference ID, or to be more specific, information on adjustment amount (adjustment parameter) values under the reference ID, wavefront aberration correction amount (or information on the image-forming performance) with respect to the stand-alone wavefront aberration under the reference ID, and the like is obtained.

The reason for using the term wavefront aberration correction amount (or information on the image-forming performance) in this case is because when the wavefront aberration correction amount under the reference ID is unknown, the wavefront aberration correction amount (or the wavefront aberration) can be assumed from the image-forming performance. How to assume the wavefront aberration correction amount from the image-forming performance will be described later in the description.

Normally, the stand-alone wavefront aberration of the projection optical system and the wavefront aberration (hereinafter referred to as on-body wavefront aberration) of projection optical system PL after being incorporated in the exposure apparatus do not coincide for some reason, however, in this case, for the sake of simplicity, the correction is to be performed for each reference ID (reference exposure condition) on the start-up of the exposure apparatus or on adjustment performed in the manufacturing stage of the exposure apparatus.

In the next step, step 208, apparatus information such as the model name, the exposure wavelength, and the maximum N.A. of the projection optical system is obtained from the first computer 920.

In the next step, step 210, the ZS file corresponding to the optimization exposure conditions previously described, is searched for in the second database.

In the next step, step 214, the judgment is made whether or not the ZS file corresponding to the optimization exposure conditions is found, and when the ZS file is found the file is loaded into the memory, such as the RAM. On the other hand, when the decision in step 214 is denied, that is, when the ZS file corresponding to the optimization exposure conditions does not exist within the second database, the procedure then proceeds to step 218 and instructions are given to computer 938 used for optical simulation to make the ZS file corresponding to the optimization exposure conditions, along with necessary information. And, by this operation, computer 938 makes the ZS file corresponding to the optimization exposure conditions, and the ZS file that has been made is added to the second database.

The ZS file corresponding to the optimization exposure conditions can also be made by the interpolation method, using the ZS database under a plurality of exposure conditions close to the optimization exposure conditions.

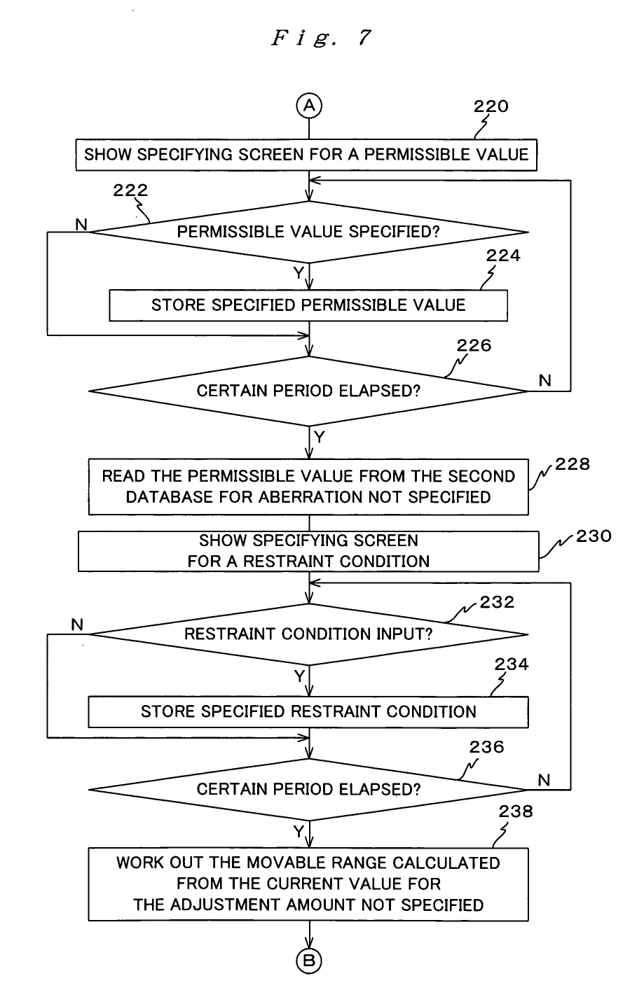

Next, in step 220 in FIG. 7, the display shows the specifying screen for specifying the permissible value of the image-forming performance (the twelve aberrations referred to earlier). Then, in step 222, the judgment is made whether or not the permissible values are input, and when the judgment is negative, the procedure then proceeds to step 226 where it is judged whether a certain period of time has elapsed or not after the input screen for the above permissible values has been displayed. And, when the judgment is denied, the procedure returns to step 222. Meanwhile, when the operator has specified the permissible values via the keyboard or the like in step 222, then the specified permissible values for aberration are stored in the memory such as the RAM, and the procedure moves to step 226. That is, the procedure waits for the permissible values to be specified for a certain period of time, while the loop of steps 222→226 or steps 222→224→226 is repeated.

The permissible values do not necessarily have to be used in the optimization calculation itself (in the embodiment, the adjustment amount calculation of the adjustment parameters using a merit function φ, which will be described later in the description), however, the permissible values will be required when evaluating the calculation results, such as in step 120 described later. Furthermore, in the embodiment, these permissible values will also be required when the weight of the image-forming performance described later is set. In the embodiment, as the permissible values, in the case the image-forming performance (including the index values) could be positive and negative values by its nature, the upper and lower limit values of the permissible range of the image-forming performance are set, whereas, in the case the image-forming performance could only be a positive value by its nature, the upper limit value of the permissible range of the image-forming performance is set (in this case, the lower limit value is zero).

Then, when a certain period of time has elapsed, the procedure then proceeds to step 228 where permissible values of aberration that were not specified are read from the ZS database within the second database, according to the default setting. As a consequence, in the memory such as the RAM, permissible values of aberration that have been specified and the remaining permissible values of aberration read from the ZS database are stored corresponding to the identification information of the equipment, such as the equipment number. In the description below, the area in which such permissible values are stored will be referred to as a ‘temporary storage area’.

In the next step, step 230, the specifying screen for restraint conditions of the adjustment parameters are shown on the display, and then in step 232, the judgment is made whether or not the restraint conditions have been input in step 232. When the judgment is negative, the procedure then moves to step 236 where the judgment is made to see if a certain period of time has passed or not since the above specifying screen has been displayed. When this judgment is negative, the procedure then returns to step 232. On the other hand, when the operator specifies the restraint conditions via the keyboard or the like in step 232, the procedure then moves to step 234 where the restraint conditions of the specified adjustment parameters are stored in the memory such as the RAM, and then proceeds to step 236. That is, the procedure waits for the permissible values to be specified for a certain period of time, while the loop of steps 232→236 or steps 232→234→236 is repeated.

Restraint conditions, in this case, means the permissible variation range of each adjustment amount (adjustment parameter) previously described, such as the permissible variation range of movable lenses 13₁ to 13₅ in directions of each degree of freedom, the permissible variation range of Z-tilt stage 58 in directions of three degrees of freedom, and the permissible range of wavelength shift.

Then, when a certain period of time has elapsed, the procedure proceeds to step 238 where according to a default setting, as the restraint conditions of the adjustment parameters that were not specified, the variable range is calculated for each adjustment parameter based on the values under the above reference ID (or current values), which is stored in the memory such as the RAM. As a consequence, in the memory, both the restraint conditions of the adjustment parameters that are specified and the restriction conditions of the remaining adjustment parameters that have been calculated are stored.

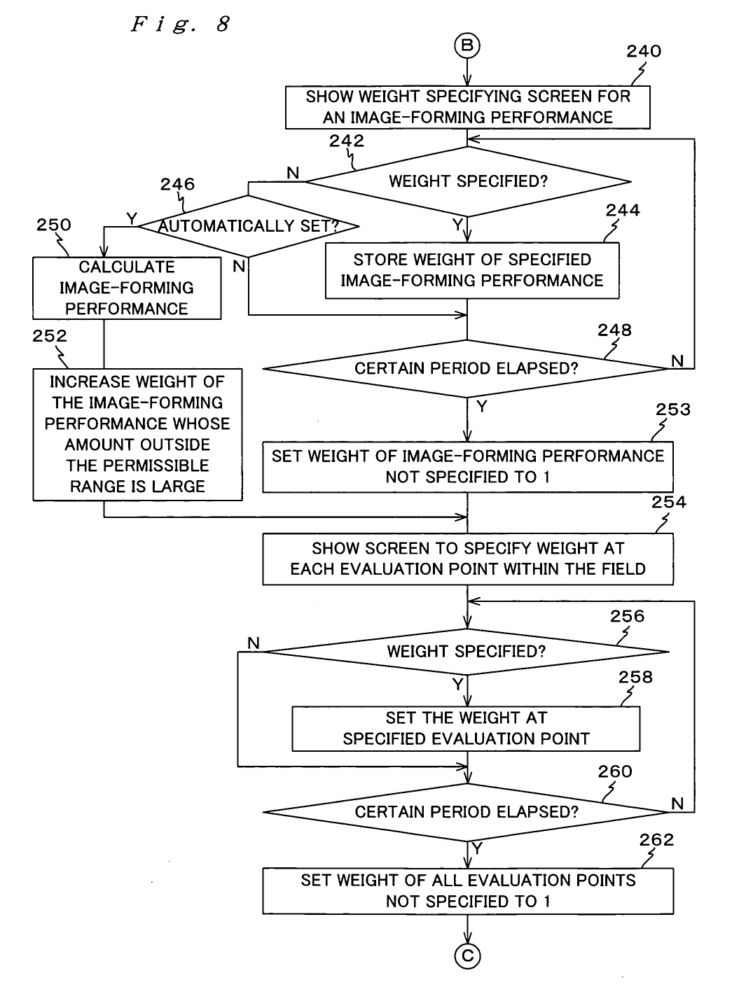

Next, in step 240 in FIG. 8, the weight specifying screen for specifying the weight of the image-forming performance is shown on the display. In the case of the embodiment, specifying the weight of the image-forming performance has to be performed at 33 evaluation points (measurement points) within the field of the projection optical system, on the 12 aberrations previously described. Therefore, 33×12=396 weights need to be specified. Accordingly, on the weight specifying screen, in order to make weight specifying possible by two steps, firstly, a specifying screen is shown for the weight of the 12 types of image-forming performance, and then, after this screen, the specifying screen for the weight at each evaluation point within the field is shown. In addition, on the specifying screen for the weight of the image-forming performance, an automatic specify button is also shown together.

Then, in step 242, it is judged whether or not the weight of any of the image-forming performance is specified. When the weight is specified by the operator via the keyboard or the like, the procedure then moves to step 244 where the weight of the specified image-forming performance (aberration) is stored in the memory such as the RAM, and then the procedure proceeds to step 248. In step 248, the judgment is made whether or not a certain period of time has elapsed since the display of the weight specifying screen previously described, and when the judgment is negative, then the procedure returns to step 242.

Meanwhile, when the judgment is denied in the above step 242, the procedure then moves to step 246 to see whether or not the automatic specify button has been selected. And, when the judgment is negative, the procedure then moves to step 248. On the other hand, when the operator has selected the automatic specify button via the mouse or the like, the procedure then moves to step 250 where the current image-forming performance is calculated based on equation (10) below.
f=Wa·ZS+C (10)

In this case, f is the image-forming performance that can be expressed as in equation (11) below, and Wa is the wavefront aberration data that can be expressed as in equation (12) below, which is calculated from the stand-alone wavefront aberration and the wavefront aberration correction amount under the reference ID obtained in step 206. In addition, ZS is data of a ZS file obtained in step 216 or 218 that can be expressed as in equation (13) below. Furthermore, C is data of a pattern correction value that can be expressed as in equation (14) below.

$$\begin{matrix}f = [ \begin{matrix}{f}_{1 , 1} & {f}_{1 , 2} & ⋯ & {f}_{1 , 11} & {f}_{1 , 12} \\ {f}_{2 , 1} & & & & {f}_{2 , 12} \\ ⋮ & & ⋰ & & ⋮ \\ {f}_{32 , 1} & & & & {f}_{32 , 12} \\ {f}_{33 , 1} & {f}_{33 , 2} & ⋯ & {f}_{33 , 11} & {f}_{33 , 12}\end{matrix} ] & ( 11 ) \\ Wa = [ \begin{matrix}{Z}_{1 , 1} & {Z}_{1 , 2} & ⋯ & {Z}_{1 , 36} & {Z}_{1 , 37} \\ {Z}_{2 , 1} & & & & {Z}_{2 , 37} \\ ⋮ & & ⋰ & & ⋮ \\ {Z}_{32 , 1} & & & & {Z}_{32 , 37} \\ {Z}_{33 , 1} & {Z}_{33 , 2} & ⋯ & {Z}_{33 , 36} & {Z}_{33 , 37}\end{matrix} ] & ( 12 ) \\ ZS = [ \begin{matrix}{b}_{1 , 1} & {b}_{1 , 2} & ⋯ & {b}_{1 , 11} & {b}_{1 , 12} \\ {b}_{2 , 1} & & & & {b}_{2 , 12} \\ ⋮ & & ⋰ & & ⋮ \\ {b}_{36 , 1} & & & & {b}_{36 , 12} \\ {b}_{37 , 1} & {b}_{37 , 2} & ⋯ & {b}_{37 , 11} & {b}_{37 , 12}\end{matrix} ] & ( 13 ) \\ C = [ \begin{matrix}0 & 0 & {C}_{1 , 3} & {C}_{1 , 4} & {C}_{1 , 5} & {C}_{1 , 6} & 0 & 0 & 0 & 0 & 0 & 0 \\ 0 & 0 & {C}_{2 , 3} & {C}_{2 , 4} & {C}_{2 , 5} & {C}_{2 , 6} & 0 & 0 & 0 & 0 & 0 & 0 \\ 0 & 0 & {C}_{3 , 3} & {C}_{3 , 4} & {C}_{3 , 5} & {C}_{3 , 6} & 0 & 0 & 0 & 0 & 0 & 0 \\ & & & & & & & & & & & \\ ⋮ & ⋮ & ⋮ & ⋮ & ⋮ & ⋮ & ⋮ & ⋮ & ⋮ & ⋮ & ⋮ & ⋮ \\ & & & & & & & & & & & \\ 0 & 0 & {C}_{33 , 3} & {C}_{33 , 4} & {C}_{33 , 5} & {C}_{33 , 6} & 0 & 0 & 0 & 0 & 0 & 0\end{matrix} ] & ( 14 )\end{matrix}$$

In equation (11), f_{i,1} (i=1 to 33) shows Disₓ at the i^{th} f_{i,3} shows CM_{V} at the i^{th} measurement point, f_{i,4} shows CM_{H} at the i^{th} measurement point, f_{i,5} shows CM_{R} at the iₜₕ measurement point, f_{i,6} shows CM_{L} at the i^{th} measurement point, f_{i,7} shows CF_{V} at the i^{th} measurement point, f_{i,8} shows CF_{H} at the i^{th} measurement point, f_{i,9} shows CF_{R} at the i^{th} measurement point, f_{i,10} shows CF_{L} at the i^{th} measurement point, f_{i,11} shows SA_{V} at the i^{th} measurement point, and f_{i,12} shows SA_{H} at the i^{th} measurement point.

In addition, in equation (12), Z_{i,j} shows the coefficient of the j^{th} term (j=1 to 37) in the Zernike polynomial, which is an expansion of the wavefront aberration at the i^{th} measurement point.

In addition, in equation (13), b_{p,q} (p=1 to 37, q=1 to 12) shows each element of the ZS file, and of the elements b_{p,1} shows the variation per 1λ for Disₓ in the p^{th} term of the Zernike polynomial, which is an expansion of the wavefront aberration, b_{p,2} shows the variation per 1λ for Dis_{y} in the p^{th} term, b_{p,3} shows the variation per 1λ for CM_{V} in the p^{th} term, b_{p,4} shows the variation per 1λ for CM_{H} in the p^{th} term, b_{p,5} shows the variation per 1λ for CM_{R} in the p^{th} term, b_{p,6} shows the variation per 1λ for CM_{L} in the p^{th} term, b_{p,7} shows the variation per 1λ for CF_{V} in the p^{th} term, b_{p,8} shows the variation per 1λ for CF_{H} in the p^{th} term, b_{p,9} shows the variation per 1λ for CF_{R} in the p^{th} term, b_{p,10} shows the variation per 1λ for CF_{L} in the p^{th} term, b_{p,11} shows the variation per 1λ for SA_{V} in the p^{th} term, and b_{p,12} shows the variation per 1λ for SA_{H} in the p^{th} term.

In addition, as the matrix of 33 rows and 12 columns on the right-hand side of equation (14), as an example, elements which are zero except for the elements of the 3^{rd}, 4^{th}, 5^{th}, and 6^{th} column in each row, that is, C_{i,3}, C_{i,4}, C_{i,5}, and C_{i,6} (i=1 to 33), are used. This is because the object in the embodiment is to correct the line width abnormal values serving as index values for coma, by correcting the pattern to be formed on the reticle.

In the above equation (14), C_{i,3} shows the correction value of line width abnormal value CM_{V} for vertical lines (that is, the correction value of the line width difference in vertical line patterns), C_{i,4} shows the correction value of line width abnormal value CM_{H} for horizontal lines (that is, correction value of the line width difference in horizontal line patterns), C_{i,5} shows the correction value of line width abnormal value CM_{R} for diagonal lines (angle of inclination, 45°) slanting upward to the right (that is, the correction value of the line width difference in diagonal line patterns slanting upward to the right), and C_{i,6} shows the correction value of line width abnormal value CM_{L} for diagonal lines (angle of inclination, 45°) slanting upward to the left (that is, the correction value of the line width difference in diagonal line patterns slanting upward to the left), each measured at the i^{th} measurement point. Because these pattern correction value are cleared in step 108, the initial values are all zero. That is, all elements of matrix C are initially zero.

In the next step, step 252, of the calculated 12 types of image-forming performance (aberrations), the weight is increased (greater than 1) for the image-forming performance greatly exceeding the permissible range (divergence from the permissible range) set based on the permissible values specified in advance, and then the procedure proceeds to step 254. This operation is not mandatory, and the image-forming performance greatly exceeding the permissible values may be shown on the screen in different colors instead. This enables the operator to assist the weight specification of the image-forming performance.

In the embodiment, the procedure waits for the weight of the image-forming performance to be specified for a certain period of time, while the loop of steps 242→246→248 or steps 242→244→248 is repeated. And, in the case the automatic specify button is selected during the period, automatic specifying is performed. On the other hand, when the automatic specify button is not selected, in the case at least one or more weight of the image-forming performance is specified, then the weight of the specified image-forming performance is stored in memory. And, when a certain period of time has elapsed, the procedure moves to step 253 where the weight of each image-forming performance that has not been specified is set to 1 according to the default setting, and then the procedure proceeds to step 254.

As a consequence, both the weight of the specified image-forming performance and the weight of the remaining image-forming performance (=1) are stored in memory.

In the next step, step 254, the screen for specifying the weight at the evaluation points (measurement points) within the field is shown on the display. Then, in step 256, the judgment is made whether or not the weight is specified for the evaluation points. When the judgment is negative, the procedure then moves to step 260 where the judgment is made whether or not a certain period of time has elapsed since the above screen for specifying the weight for the evaluation points (measurement points) is shown. When the judgment is negative, the procedure returns to step 256.

Meanwhile, in step 256, when the operator specifies the weight of any of the evaluation points (normally, the evaluation point is selected that especially needs to be improved) via the keyboard or the like, the procedure then moves to step 258 where the weight at the evaluation point is set and stored in the memory such as the RAM. Then the procedure moves on to step 260.

That is, the procedure waits for the weight of the evaluation point to be specified for a certain period of time after the weight specifying screen for the evaluation point described above is shown, while the loop composed of steps 256→260 or steps 256→258→260 is repeated.

Then, after a certain period of time has elapsed, the procedure moves on to step 262 where the weight is set to 1 according to a default setting for all the evaluation points that were not specified, and then the procedure proceeds to step 264 in FIG. 264.

As a consequence, the specified values of the weight at the specified evaluation point and the weight for the remaining evaluation points (=1) are all stored in memory.

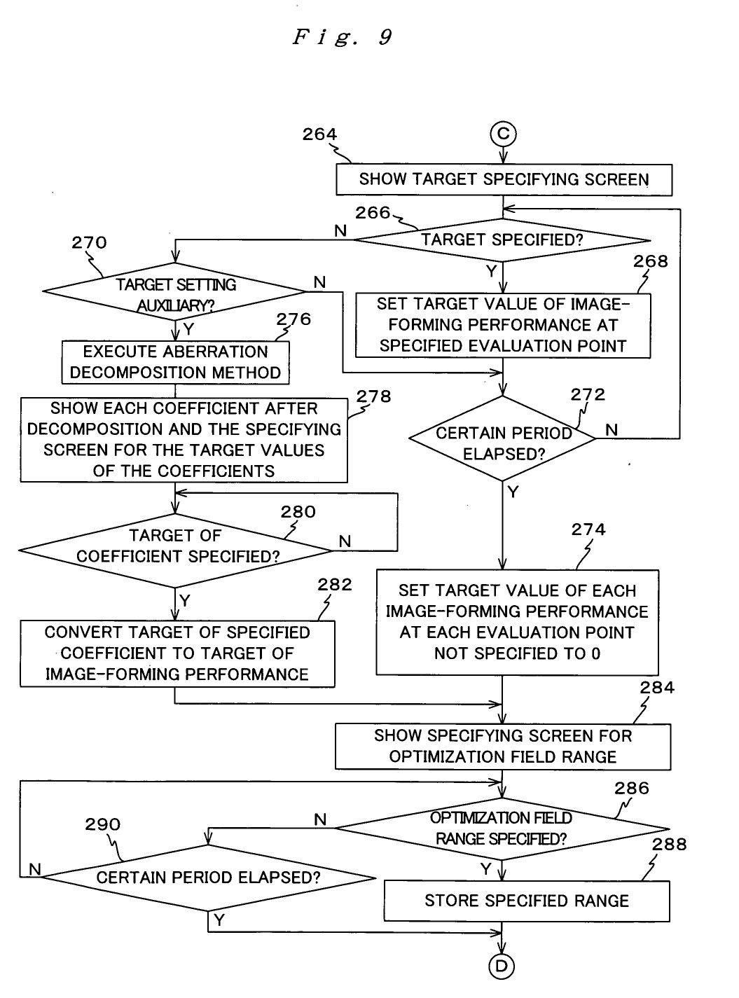

In step 264 in FIG. 9, the specifying screen for the target values (target) of the image-forming performance (the 12 types of aberrations referred to earlier) at each evaluation point within the field is shown on the display. In the case of the embodiment, the target of the image-forming performance needs to be specified at 33 evaluation points (measurement points) within the field of the projection optical system for the 12 aberrations described earlier, therefore, 33×12=396 targets need to be specified. Accordingly, the specifying screen for the target shows a setting auxiliary button, along with the section for manual specification.

Then, in the next step, step 266, the procedure is suspended to wait for the targets to be specified (that is, the judgment is made whether or not the targets are specified) for a predetermined period of time, and when the targets are not specified (when the judgment is negative), the procedure moves to step 270 where the judgment is made whether or not the setting auxiliary button has been selected. When this judgment is negative, the procedure then proceeds to step 272 where the decision is made whether or not a certain period of time has elapsed since the above specifying screen for the targets has been displayed. And, when the judgment is denied, then the procedure returns to step 266.

Meanwhile, in step 270, when the operator selects the setting auxiliary button with the mouse or the like, the procedure then proceeds to step 276 where an aberration decomposition method is performed.

The aberration decomposition method will now be described.

First of all, each image-forming performance (aberration), which is an element of image-forming performance f described earlier, power expanded as in equation (15) below for x and y.
f=G·A (15)

In equation (15) above, G is a matrix of 33 rows and 17 columns, as is shown in equation (16) below.

$$G = [ \begin{matrix}{g}_{1} ( {x}_{1} , {y}_{1} ) & {g}_{2} ( {x}_{1} , {y}_{1} ) & ⋯ & {g}_{16} ( {x}_{1} , {y}_{1} ) & {g}_{17} ( {x}_{1} , {y}_{1} ) \\ {g}_{1} ( {x}_{2} , {y}_{2} ) & & & & {g}_{17} ( {x}_{2} , {y}_{2} ) \\ ⋮ & & ⋰ & & ⋮ \\ {g}_{1} ( {x}_{32} , {y}_{32} ) & & & & {g}_{17} ( {x}_{32} , {y}_{32} ) \\ {g}_{1} ( {x}_{33} , {y}_{33} ) & {g}_{2} ( {x}_{33} , {y}_{33} ) & ⋯ & {g}_{16} ( {x}_{33} , {y}_{33} ) & {g}_{17} ( {x}_{33} , {y}_{33} )\end{matrix} ] \qquad ( 16 )$$

In this case, g₁=1, g₂=x, g₃=y, g₄=x², g₅=xy, g₆=y², g₇=x³, g₈=x²y, g₉=xy², g₁₀=y³, g₁₁=x⁴, g₁₂=x³y, g₁₃=x²y², g₁₄=xy³, g₁₅=y⁴, g₁₆=x(x²+y²), and g₁₇=y(x²+y²).In addition, (xᵢ, yᵢ) is the xy coordinate of the i^{th} evaluation point.

In addition, in the above equation (15), A is a matrix whose elements are decomposition coefficients of 17 rows and 12 columns as is shown in equation (17) below.

$$A = [ \begin{matrix}{a}_{1 , 1} & {a}_{1 , 2} & ⋯ & {a}_{1 , 11} & {a}_{1 , 12} \\ {a}_{2 , 1} & & & & {a}_{2 , 12} \\ ⋮ & & ⋰ & & ⋮ \\ {a}_{16 , 1} & & & & {a}_{16 , 12} \\ {a}_{17 , 1} & {a}_{17 , 2} & ⋯ & {a}_{17 , 11} & {a}_{17 , 12}\end{matrix} ] \qquad ( 17 )$$

Equation (15) above is then transformed into equation (17) below, so that the least squares method can be performed.
G^{T}·f=G^{T}·G·A (18)

In this case, G^{T} is a transposed matrix of matrix G.

Next, matrix A is obtained using the least squares method, based on equation (18) above.
A=(G^{T}·G)⁻¹·G^{T}·f (19)

The aberration decomposition method is performed in the manner described above, and each decomposition item coefficient is obtained, after the decomposition.

Referring back to FIG. 9, in the next step, step 278, the specifying screen of the target values of the coefficients is shown on the display, along with each decomposition item coefficient after decomposition obtained in the manner described above.

Then, in the next step, step 280, the procedure is suspended to wait for all the target values (targets) of the decomposition item coefficients to be specified. And, when the operator specifies all the targets of the decomposition coefficients via the keyboard or the like, the step then proceeds to step 282 where the targets of the decomposition item coefficients are converted into targets of the image-forming performance. In this case, as a matter of course, the operator can perform the target specifying only by revising the targets for the coefficients that need to be improved, and for the remaining targets, the coefficients shown can be used as the targets.
fₜ=G·A′ (20)

In equation (20) above, fₜ is the target of a specified image-forming performance, and A′ is a matrix whose element is the specified decomposition item coefficient (revised).

Incidentally, each decomposition item coefficient that is calculated does not necessarily have to be shown on the screen, and the target that needs to be revised can be automatically set based on each decomposition item coefficient that has been calculated.

Meanwhile, in step 266 referred to above, when the operator specifies any of the targets for an image-forming performance at an evaluation point via the keyboard or the like, the judgment made in step 266 is positive, and the procedure moves to step 268 where the specified target is set and stored in the memory such as the RAM. The procedure then moves to step 272.

That is, in the embodiment, the procedure waits for the targets to be specified for a certain period of time from when the target specifying screen referred to earlier has been shown, while the loop composed of steps 266→270→272 or steps 266→268→272 is repeated. In the case the setting auxiliary is specified during this period, the targets are specified by calculating the decomposition item coefficients, showing the results, and specifying the targets of the decomposition item coefficients, as is previously described. And, in the case the setting auxiliary button is not selected, when the target for one or more image-forming performance is specified at one or more evaluation points, the target of the specified image-forming performance at the specified evaluation point is stored in memory. And then, when a certain period of time elapses, the procedure moves to step 274 where the targets for each image-forming performance at the measurement points that were not specified are all set to 0 according to a default setting, then the procedure proceeds to step 284.

As a result, the targets of the specified image-forming performance at the specified evaluation points and the targets (=0) of the remaining image-forming performance are stored in memory, for example, in the form of a matrix fₜ consisting of 33 rows and 12 columns, as is shown in equation (21) below.

$${f}_{t} = [ \begin{matrix}{f}_{1 , 1}^{′} & {f}_{1 , 2}^{′} & ⋯ & {f}_{1 , 11}^{′} & {f}_{1 , 12}^{′} \\ {f}_{2 , 1}^{′} & & & & {f}_{2 , 12}^{′} \\ ⋮ & & ⋰ & & ⋮ \\ {f}_{32 , 1}^{′} & & & & {f}_{32 , 12}^{′} \\ {f}_{33 , 1}^{′} & {f}_{33 , 2}^{′} & ⋯ & {f}_{33 , 11}^{′} & {f}_{33 , 12}^{′}\end{matrix} ] \qquad ( 21 )$$

In the embodiment, the image-forming performance at the evaluation points where the targets were not specified is not taken into consideration in the optimization calculation. Accordingly, the image-forming performance has to be evaluated again, after obtaining the solutions.

In the next step, step 284, the screen for specifying the optimization field range is shown on the display, and then the loop composed of steps 286→290 is repeated while the procedure waits for the field range to be specified for a certain period of time, after the specifying screen of the optimization field range has been displayed. The reason for making it possible to specify the optimization range is because the following points were considered: in the scanning exposure apparatus such as the so-called scanning stepper as in the embodiment, the image-forming performance or the transfer state of the pattern on the wafer does not necessarily have to be optimized for the entire field of the projection optical system; or, for example, in the case of the stepper, depending on the reticle that is to be used or the size of the pattern area (that is, the entire or a partial section of the pattern area used when exposing a wafer), the image-forming performance or the transfer state of the pattern on the wafer does not necessarily have to be optimized for the entire field of the projection optical system.

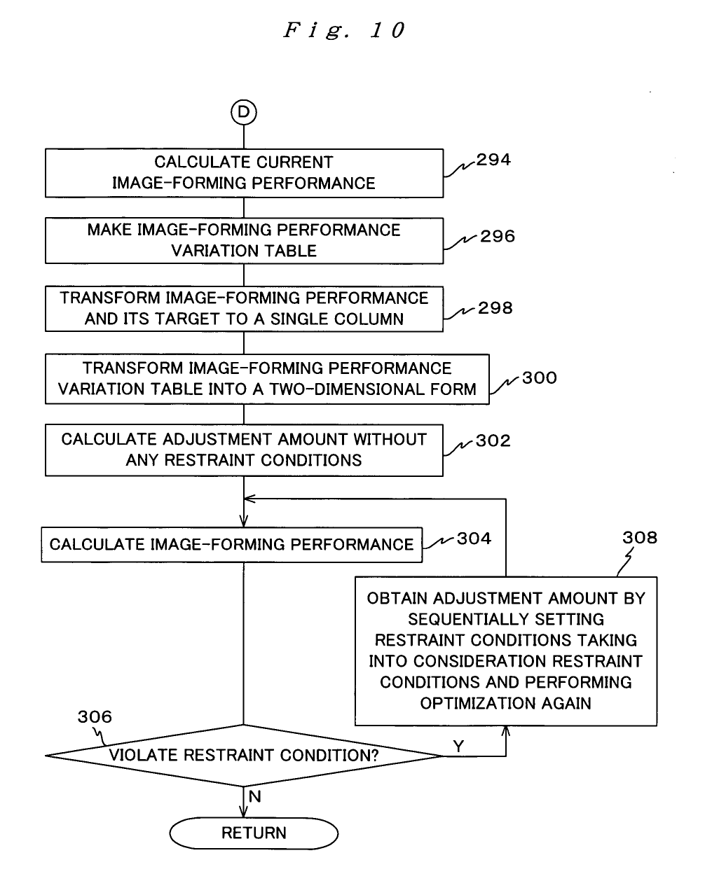

Then, when the optimization field is specified within a certain period of time, the procedure then moves to step 288 where the specified range is stored in the memory such as the RAM. Then, the procedure proceeds to step 294 in FIG. 10. On the other hand, when the optimization field range is not specified, the procedure then simply proceeds to step 294, without performing any operation in particular.

In step 294, the current image-forming performance is calculated, based on equation (10) referred to earlier.

Then, in the next step, step 296, an image-forming performance variation table is made for each adjustment parameter, using the wavefront aberration variation table (refer to equation (9) previously described) for each adjustment parameter and the ZS (Zernike sensitivity) file for each adjustment parameter, or in other words, the Zernike Sensitivity chart. This can be expressed as in equation (22) below.
image-forming performance variation table=wavefront aberration variation table·ZS file (22)

The calculation in equation (22) is a multiplication of the wavefront aberration variation table (a matrix of 33 rows and 37 columns) and the ZS file (a matrix of 37 rows and 12 columns), therefore, an image-forming performance variation table B1, which is obtained, is a matrix of, for example, 33 rows and 12 columns as is expressed below in equation (23).

$$B 1 = [ \begin{matrix}{h}_{1 , 1} & {h}_{1 , 2} & ⋯ & {h}_{1 , 11} & {h}_{1 , 12} \\ {h}_{2 , 1} & & & & {h}_{2 , 12} \\ ⋮ & & ⋰ & & ⋮ \\ {h}_{32 , 1} & & & & {h}_{32 , 12} \\ {h}_{33 , 1} & {h}_{33 , 2} & ⋯ & {h}_{33 , 11} & {h}_{33 , 12}\end{matrix} ] \qquad ( 23 )$$

The image-forming performance variation table is calculated for each of the 19 adjustment parameters. As a result, 19 image-forming performance variation tables B1 to B19 are obtained, each composed of a matrix having 33 rows and 12 columns.

In the next step, step 298, image-forming performance f and its target fₜ are made into a single column (one-dimensional column). In this case, being made into a single column means to transform the matrices f and fₜ of 33 rows and 12 columns into matrices of 396 rows and a single column. Equations (24) and (25) below show f and fₜ, respectively, after the transformation.

$$\begin{matrix}f = [ \begin{matrix}{f}_{1 , 1} \\ {f}_{2 , 1} \\ ⋮ \\ {f}_{33 , 1} \\ {f}_{1 , 2} \\ {f}_{2 , 2} \\ ⋮ \\ {f}_{33 , 2} \\ ⋮ \\ ⋮ \\ {f}_{1 , 12} \\ {f}_{2 , 12} \\ ⋮ \\ {f}_{33 , 12}\end{matrix} ] & ( 24 ) \\ {f}_{t} = [ \begin{matrix}{f}_{1 , 1}^{′} \\ {f}_{2 , 1}^{′} \\ ⋮ \\ {f}_{33 , 1}^{′} \\ {f}_{1 , 2}^{′} \\ {f}_{2 , 2}^{′} \\ ⋮ \\ {f}_{33 , 2}^{′} \\ ⋮ \\ ⋮ \\ {f}_{1 , 12}^{′} \\ {f}_{2 , 12}^{′} \\ ⋮ \\ {f}_{33 , 12}^{′}\end{matrix} ] & ( 25 )\end{matrix}$$

In the next step, step 300, the image-forming performance variation table for each of the 19 adjustment parameters made in step 296 above is transformed into a two-dimensional form. The transformation into a two-dimensional form, in this case, means to convert the form of the 19 types of the image-forming performance variation tables that are each made up of a 33 row 12 column matrix into a matrix having 396 rows and 19 columns, so that each column shows the image-forming performance variation at each evaluation point with respect to an adjustment parameter. The image-forming performance variation table after such a two-dimensional transformation can be expressed, for example, as B shown in equation (26) below.

$$B = [ \begin{matrix}{h}_{1 , 1} & {h}_{1 , 1}^{2} & ⋯ & ⋯ & {h}_{1 , 1}^{19} \\ {h}_{2 , 1} & & & & ⋮ \\ ⋮ & & & & \\ {h}_{33 , 1} & & & & \\ {h}_{1 , 2} & & & & ⋮ \\ {h}_{2 , 2} & & & & \\ ⋮ & & & & \\ {h}_{33 , 2} & & & & \\ ⋮ & & & & ⋮ \\ ⋮ & & & & \\ ⋮ & & & & \\ {h}_{1 , 12} & & & & \\ ⋮ & & & & ⋮ \\ {h}_{33 , 12} & {h}_{33 , 12}^{2} & ⋯ & ⋯ & {h}_{33 , 12}^{19}\end{matrix} ] \qquad ( 26 )$$

When the image-forming performance variation table has undergone such two-dimensional transformation, the procedure then moves to step 302 where the variation amount (adjustment amount) of the adjustment parameters is calculated without any consideration of the restraint conditions previously described.

Hereinafter, the processing in step 302 will be described in detail. In the case the weight is not taken into consideration, a relation that can be expressed as in equation (27) below exists between target fₜ of the image-forming performance made into a single column, image-forming performance f made into a single column, image-forming performance variation table B after two-dimensional transformation, and an adjustment amount dx of the adjustment parameter.
(fₜ−f)=B·dx (27)

In this case, dx is a matrix of 19 rows and one column as is shown in equation (28) whose elements is the adjustment amount of each adjustment parameter. In addition, (fₜ−f) is a matrix of 396 rows and one column, as is shown in equation (29) below.

$$\begin{matrix} dx = [ \begin{matrix}{dx}_{1} \\ {dx}_{2} \\ {dx}_{3} \\ {dx}_{4} \\ ⋮ \\ ⋮ \\ ⋮ \\ {dx}_{19}\end{matrix} ] & ( 28 ) \\ ( {f}_{t} - f ) = [ \begin{matrix}{f}_{1 , 1}^{′} - {f}_{1 , 1} \\ {f}_{2 , 1}^{′} - {f}_{2 , 1} \\ ⋮ \\ {f}_{33 , 1}^{′} - {f}_{33 , 1} \\ {f}_{1 , 2}^{′} - {f}_{1 , 2} \\ {f}_{2 , 2}^{′} - {f}_{2 , 2} \\ ⋮ \\ {f}_{33 , 2}^{′} - {f}_{33 , 2} \\ ⋮ \\ ⋮ \\ {f}_{1 , 12}^{′} - {f}_{1 , 12} \\ {f}_{2 , 12}^{′} - {f}_{2 , 12} \\ ⋮ \\ {f}_{33 , 12}^{′} - {f}_{33 , 12}\end{matrix} ] & ( 29 )\end{matrix}$$

When equation (27) above is solved by the least squares method, it can be expressed as in the following equation.
dx=(B^{T}·B)⁻¹·B^{T}·(fₜ−f) (30)

In this case, B^{T} is a transposed matrix of image-forming performance variation table B referred to earlier, and (B^{T}·B)⁻¹ is an inverse matrix of (B^{T}·B).

However, the case when the weight is not specified (all the weightings=1) is rare, and the weight is usually specified. Therefore, a merit function φ as is shown in equation (31) below, which serves as a weighting function, is to be solved using the least squares method.
Φ=Σwᵢ·(fₜᵢ−fᵢ)² (31)

In this case, fₜᵢ is an element of fₜ, and fᵢ is an element of f. When the above equation is transformed, it can be expressed as follows.
Φ=Σ(wᵢ^{1/2}·fₜᵢ−wᵢ^{1/2}·fᵢ)² (32)

Accordingly, when wᵢ^{1/2}·fᵢ is a new image-forming performance (aberration) fᵢ′ and wᵢ^{1/2}·fₜᵢ a new target fₜᵢ′, then merit function φ will be expressed as follows.
Φ=Σ(fₜᵢ′−fᵢ′)² (33)

Accordingly, equation (33) above maybe solved using the least squares method. However, in this case, the image-forming performance variation table expressed as in the following equation has to be used.
∂ fᵢ′/∂ xⱼ=wᵢ^{1/2}·∂ fᵢ/∂xⱼ (34)

As is described, in step 302, the 19 elements of dx, that is, the adjustment amount of the 19 adjustment parameters is obtained by the least squares method, without taking into consideration the restraint conditions.

In the next step, step 304, the adjustment amount of the 19 adjustment parameters that is obtained are substituted into, for example, equation (27) above, and each element of matrix fₜ−f, that is, the difference between the 12 types of aberration (image-forming performance) at all the evaluation points and the targets (target values), or each element of matrix f, that is, the 12 types of aberration (image-forming performance) at all the evaluation points, are calculated. The results of such calculation are stored corresponding to the permissible values (and targets (target values)) of aberration, in the temporary storage area referred to earlier in the memory such as the RAM, and then the procedure proceeds to step 306.

In step 306, the judgment is made whether or not the adjustment amount of the 19 adjustment parameters calculated in step 302 above break the restraint conditions that have been previously set (the judgment method will be described further later in the description). And, when the judgment is positive, the procedure then moves to step 308.

Hereinafter, the processing that is performed when the restraint conditions are violated will be described, including the case in step 308.

The merit function on such violation of the restraint conditions can be expressed, as in equation (35) below.
φ=φ₁+φ₂ (35)

In the equation above, φ₁ is an ordinary merit function as is shown in equation (30), and φ₂ is a penalty function (restraint conditions violation amount). When the restraint conditions are expressed as gⱼ and the boundary values bⱼ, φ₂ is to be a weighted squared sum of the boundary value violation amount (gⱼ−bⱼ), as in equation (36) below.
Φ₂=Σwⱼ′·(gⱼ−bⱼ)² (36)

The reason for φ₂ being a squared sum of the boundary value violation amount is because when φ₂ takes the form of a squared sum of the violation amount, equation (37) below can be solved for dx by the least squares method.
∂ Φ/∂ X=∂ Φ₁/∂ X+∂ Φ₂/∂ X=0 (37)

That is, dx can be obtained, in the same manner as the normal least squares method.

Next, concrete processing performed when the restraint conditions are violated will be described.

Restraint conditions are physically determined by the movable range of each of the three drive shafts (piezoelectric elements) of the movable lenses 13₁ to 13₅ and the tilt (θx and θy) limit of the shafts.

The movable range of each shaft can be expressed as in equations (38a) to (38c) below, with z1, z2, and z3 indicating the position of each shaft.
z1a≦z1≦z1b (38a)
z2a≦z2≦z2b (38b)
z3a≦z3≦z3b (38c)

In addition, the limit unique to tilt can be exemplified as in equation (38d) below.
(θx²+θy²)^{1/2}≦+40″ (38d)

The reason for choosing 40″ is for the following reason. When 40″ is transformed into radian,

$$\begin{matrix}{40}^{′′} = 40 / 3600 degrees \\ = π / ( 90 ⨯ 180 ) radian \\ = 1.93925 ⨯ {10}^{- 4} radian .\end{matrix}$$

Accordingly, for example, when a radius r of movable lenses 13₁ to 13₅ is approximately 200 mm, the movement amount of each shaft is as follows.

$$\begin{matrix}shaft movement amount = 1.93925 ⨯ {10}^{- 4} ⨯ 200 mm \\ = 0.03878 mm \\ = 38.78 μm \approx 40 μm\end{matrix}$$

That is, when the tilt is 40″, the perimeter moves around 40 μm from the horizontal position. Because the average stroke of the movement amount of each shaft is around 200 μm, 40 μm is an amount that cannot be ignored when compared with the strokes of the shafts around 200 μm. The tilt, however, is not limited to 40″, and can be set at any value, such as values according to the strokes of the drive shaft. In addition, other than the movable range previously described and the tilt limit, the restraint conditions may also take into consideration the shift range of the wavelength of illumination light EL, as well as the movable range of the wafer (Z-tilt stage 58) in the Z direction and the tilt of the wafer.

The equations (38a) to (38d) above have to be satisfied at the same time in order to prevent violation of the restraint conditions.

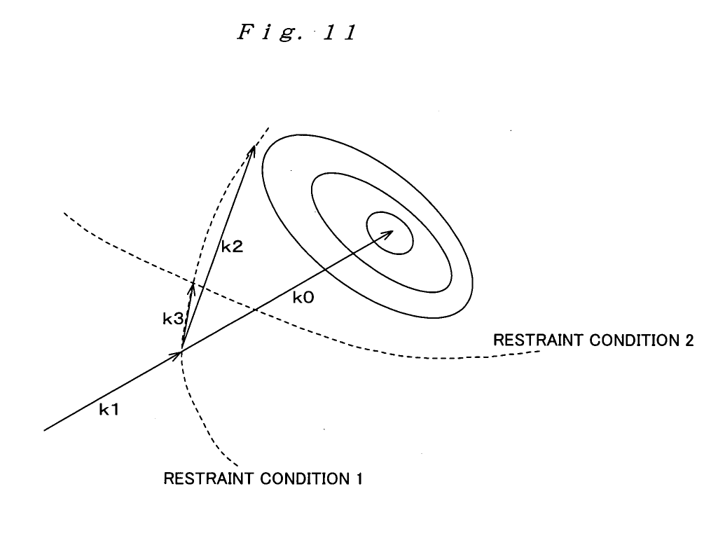

Therefore, firstly, as is described in step 302 above, optimization is performed without taking the restraint conditions into consideration, so as to obtain the adjustment amount dx of the adjustment parameters. This dx can be expressed as a movement vector k0 (Zi, θxᵢ, θyᵢ, i=1 to 7) shown in the diagram in FIG. 11. In this case, i=1 to 5 corresponds to movable lenses 13₁ to 13₅, respectively, i=6 corresponds to the wafer (Z-tilt stage), and i=7 corresponds to the wavelength shift of the illumination light. The wavelength of the illumination light does not actually have three degrees of freedom, however, in this case, the wavelength is to have three degrees of freedom for the sake of convenience.

Next, the judgment is made whether or not at least one of the conditions (38a) to (38d) above is not satisfied (step 306), and when the judgment is negative, that is, the equations (38a) to (38d) above are all satisfied at the same time, the processing when the restraint conditions are violated will not be required, therefore, the processing performed when the restraint conditions are violated comes to an end. On the other hand, when at least one of the conditions in the equations (38a) to (38d) above is not satisfied, the procedure then moves to step 308.

In step 308, as is shown in FIG. 11, the movement vector k0 that has been obtained is scaled down to obtain the condition and the point that firstly violate the restraint conditions. The vector is expressed as k1.

Next, the restraint condition violation amount regarded as an aberration is added to the data with the condition serving as a restraint condition, and then the optimization calculation is re-performed. In this case, the image-forming performance variation table related to the restraint condition violation amount is calculated at point k1. And, in this manner, movement vector k2 in FIG. 11 is obtained.

In this case, the term ‘the restraint condition violation amount regarded as an aberration,’ means that the restraint condition violation amount, which can be expressed as, for example, z1-z1b, z2-z2b, z3-z3b, (θx²+θy²)^{1/2}−40, could be a restraint condition aberration.

For example, when z2 violates the restraint condition z2-z2b, the restraint condition violation amount (z2-z2b) can be regarded as an aberration and the normal optimizing processing can be performed. Accordingly, in this case, a row on the restraint condition section is added to the image-forming performance variation table. Such a restraint condition section is also added to the image-forming performance (aberration) and its target. In this case, when the weight is largely set, then z2 is consequently fixed to a boundary value z2b.

The restraint condition is a nonlinear function of z, θx, and θy, therefore, different derivatives can be obtained depending on the place picked in the image-forming performance variation table. Accordingly, the adjustment amount (movement amount) and the image-forming performance variation table have to be sequentially calculated.

Next, as is shown in FIG. 11, vector k2 is scaled, and the condition and the point that firstly violate the restraint conditions are obtained. Then, the vector up to the point is to be k3.

Hereinafter, the setting of the restraint conditions described above is sequentially performed (adding the restraint conditions in the order of the movement vector violating the restraint conditions), and the processing for obtaining the movement amount (adjustment amount) by performing re-optimization is repeated until the restraint conditions are not violated.

According to the operation above, equation (39) can be obtained as a conclusive movement vector.
k=k1+k3+k5+ (39)

In this case, to simplify the process, k1 may be the solution (answer), that is, linear approximation may be performed. Or, when the optimal value is searched strictly within the range of the restraint conditions, k of the above equation (39) may be obtained by sequential calculation.

Next, optimization is further described, taking the restraint conditions into consideration.

As is described, normally, the following equation stands.
(fₜ−f)=B·dx (27)

By solving this equation using the least squares method, adjustment amount dx of the adjustment parameter can be obtained.

However, the image-forming performance variation table can be divided into a normal variation table and a restraint condition variation table, as is shown in equation (40) below.

$$B = [ \begin{matrix}{B}_{1} \\ {B}_{2}\end{matrix} ] \qquad ( 40 )$$

In this case, B₁ is a normal variation table without dependence on location. Meanwhile, B₂ is a restraint condition variation table, which is dependent on location.

In addition, the left side (fₜ−f) of equation (27) above can also be divided into two sections accordingly, as is shown in equation (41) below.

In this case, fₜ₁ is the normal aberration target and f₁ is the current aberration. In addition, fₜ₂ is the restraint condition and f₂ is the current restraint condition violation amount.

Because restraint condition variation table B₂, current aberration f₁, and current restraint condition violation amount f₂ are dependent on location, they need to be newly calculated per movement vector.

Then, when optimization calculations are performed in the usual manner using this variation table, optimization taking the restraint conditions into account is performed.

In step 308, the adjustment amount taking the restraint conditions into consideration is obtained in the manner described above, and then the procedure returns to step 304.

On the other hand, when the judgment in step 306 is negative, that is, when there is no restraint condition violation or when the restraint condition violation has been dissolved, the procedure then ends the subroutine processing for optimization of the equipment and returns to step 116 in the main routine in FIG. 5.

Referring back to FIG. 5, in step 116, the judgment is made whether or not the optimization has been completed for all the equipment specified in step 104 previously described. In the case the judgment is negative, the procedure then moves to step 118 where counter k is incremented by 1, and then the procedure moves to step 114 where the optimization processing of the k^{th} (in this case, the second) equipment is performed in the same manner as in the description above.

Hereinafter, the processing (including the decision making) of steps 118→114→116 are repeatedly performed until the judgment in step 116 turns positive.

In the description above, the case has been described where the processing of the subroutine or the like in step 114 is performed three or more times while counter m is at the same value (in this case, 1, which is the initial value). This is because the description was made on the assumption that three or more equipment were specified (selected) in step 104, therefore, it is a matter of course that in the case two equipment are specified (selected), the processing is performed two times, and when only one equipment is specified (selected), the processing is performed only once. That is, step 114 and step 116 are to be performed the same number of times as the number of the specified equipment, while counter m is at the same value.

Then, when the optimization described earlier has been completed for all the specified (selected) equipment, the judgment in step 116 turns positive, and the procedure moves to step 120 where the judgment is made whether or not the optimization for all the equipment is favorable. The judgment in step 120 is made by deciding whether or not the calculated values of the corresponding aberration are all within the permissible range, which is set by the permissible values for each aberration, for each of the equipment at each evaluation point. This judgment is made, based on the equipment number, the permissible values of the image-forming performance (the 12 types of aberration), and the calculated values of the image-forming performance (the 12 types of aberration) at each evaluation point and the corresponding targets (target values) (or the difference between the image-forming performance (the 12 types of aberration) at each evaluation point and the targets (target values)), which are stored in the temporary storage area in the memory such as the RAM referred to earlier.

And, in the case the judgment in step 120 is negative, that is, when at least one aberration among the 12 types of aberration is outside the permissible range in at least one equipment in at least one evaluation point, the procedure then moves to step 122 where the judgment is made whether or not the value of counter m exceeds M or not. When this decision is denied, the procedure then moves to step 124. In this case, since m is the, initial value 1, the judgment in this step is negative.

In step 124, based on the results of the decision made in step 120, the equipment whose calculated values of aberration were outside the permissible value (NG equipment), the evaluation point where the calculated values of aberration were outside the permissible value (NG position), and the type of aberration (NG item) are all specified.

In the next step, step 126, the average value of the equipment of residual errors on the NG item at the NG position is calculated as the pattern correction value previously described, and a pattern correction data C (corresponding elements of a matrix shown as equation (14) earlier in the description) is set (updated).

For example, in the case equipment A and equipment B are selected as the equipment subject to optimization in step 104, and for example, line width abnormal value CM_{V} for vertical lines turns out to be outside the permissible range in only equipment A at the i^{th} measurement point (evaluation point), the pattern correction value can be calculated as in the following example.
C_{i,3}=−{(CM_{V})_{A,i}+(CM_{V})_{B,I}}/(2*β) (42)

In this case, (CM_{V})_{A,i} is the line width abnormal value for the vertical lines at the i^{th} measurement point in equipment A, and (CM_{V})_{B,i} is the line width abnormal value for the vertical lines at the i^{th} measurement point in equipment B. In addition, β is the projection magnification of the exposure apparatus selected, which is subject to optimization. In the case the number of equipment subject to optimization is small, then, pattern correction value C_{i,3} can be calculated by equation (42) above, using (CM_{V})_{B,i}=0 for equipment B whose line width abnormal value (CM_{V})_{B,i} was within the permissible range at the i^{th} evaluation point.

In the next step, step 128, necessary information is given to computer 938 used for optical simulation, as well as instructions to make a ZS file corresponding to target exposure conditions (exposure conditions different only in pattern information from the optimization exposure conditions whose information is obtained in step 202 previously described) whose pattern information obtained in step 202 is corrected using the pattern correction value. Accordingly, computer 938 makes the ZS file corresponding to the target exposure conditions, and the ZS file that has been made is added to the second database.

Next, the procedure moves to step 132 where counter m is incremented by 1, and then the procedure returns to step 112 where the loop of steps 118→114→116 are repeatedly performed until the judgment in step 116 turns positive, and the optimization described earlier is performed again for all the equipment. However, in the processing of step 114 performed the second time (m=2), as pattern correction value data C, a matrix data is used whose values are set in step 126 described earlier but has at least a part of elements C_{i,3}, C_{i,4}, C_{i,5}, and C_{i,6} revised. In addition, as the ZS file, the ZS file made in step 128 previously described is to be read and used in step 216.

Then, when the optimization previously described is completed for all the equipment, the judgment in step 116 turns positive, and the procedure moves to step 120 where the judgment is made whether or not the optimization for all the equipment is favorable.

And, in the case the judgment in step 120 is negative, the procedure moves to step 122, and then after the processing in steps 122 to 132 is sequentially performed, the procedure then returns to step 112 where the loop processing of steps 112 previously described→(the loop of steps 114→116→118) 120→122→124→126→128→132 is repeated.

On the other hand, in the case the judgment in step 120 is positive, that is, when the results of the optimization previously described are favorable for all the equipment that are specified (selected) from the very start or when the results of the optimization previously described turns out favorable by the revision setting of the pattern correction value in step 126, the procedure then moves to step 138.

Apart from the processing described above, in the case the judgment made in step 120 continues to be negative while repeating the processing in the loop described above (steps 112 to 132) M times, on the M^{th} time of the loop, the decision in step 122 is affirmed and the procedure moves to step 134 where the processing is shut down after showing the content not optimizable on the screen of the display. The reason for employing such a structure is because when the results of the optimization do not turn out favorable for all the equipment after repeating the loop above for a certain number of times, it can be considered that the optimization substantially cannot be performed by setting the pattern correction value, therefore, the termination of the processing is executed. An example of M times is 10 times.

In step 138, the data of matrix C whose elements are all zero or the pattern correction value (pattern correction data) whose elements are partially revised in step 126 previously described are output (transmitted) to the first computer 920, and are also made to correspond with the pattern information while being stored in the memory such as the RAM.

In the next step, step 140, the correct adjustment amount (the adjustment amount per equipment calculated in step 114) for all the equipment that are specified are output (selected) to the first computer 920 from each equipment. The first computer 920 receives the information above, sets the exposure conditions whose pattern information under the optimization exposure conditions previously described is corrected using the pattern correction value as the new reference IDs for each equipment, makes the new IDs correspond with the information received on the correct adjustment amount for each equipment, and stores the data in the memory such as the RAM.

In the next step, step 142, the selection screen of whether to stop or to continue the processing is shown on the display. And, in step 144, when the continue button is chosen, the procedure then returns to step 102. Meanwhile, when the stop button is chosen, then the series of processing in this routine is completed.

Now, an example of an experiment result is described using a computer that has a reticle pattern design program similar to the one described above installed, or more specifically, the case where reticle pattern correction and optimization of the image-forming performance (aberration) are performed for equipment A and equipment B whose wavefront aberration within the field (static field) of the projection optical system has been measured.

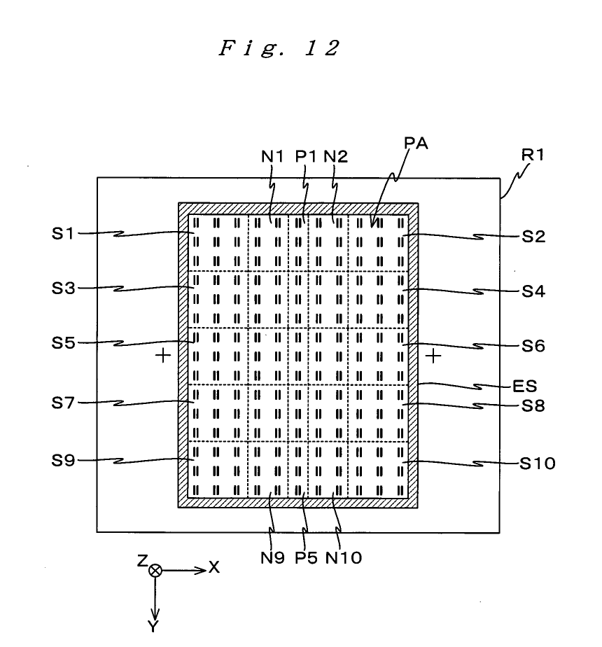

As the reticle, a working reticle R1 is to be used that has two fine line patterns in the vertical direction which are uniformly distributed within a pattern area PA, as is shown in FIG. 12A. In this case, within the field (static field) of the projection optical system, the measurement points (evaluation points) of wavefront aberrations previously described are arranged in a shape of a 3 row 11 column matrix, and on working reticle R1, a pair of line patterns is formed that make a set extending in the vertical direction (the Y-axis direction) in a correspondable state to each measurement point, arranged in the shape of a 3 row 11 column matrix. FIG. 12 shows working reticle R1 when viewed from the pattern surface side.

(Step 1)

In reticle R1, because the issues are the line width uniformity of the pattern and the position of the pattern, the Zernike Sensitivity chart (ZS file) for focus dependency, line width difference between the right and left lines, and the pattern center position are to be respectively obtained in advance as the evaluating image-forming performance under predetermined exposure conditions.

(Step 2)

Then, the ZS file above, the wavefront aberration data within the field of the projection optical system, the wavefront aberration variation table, and lens position variable range data for both equipment A and equipment B, and the permissible range for each image-forming performance referred to above (focus uniformity, right and left line width difference, and pattern shift) were set, and optimization of the image-forming performance of both equipment A and B was performed as in step 114 with all the pattern correction value set to zero, and in the process, each image-forming performance was calculated in a similar manner as in step 304 previously described.

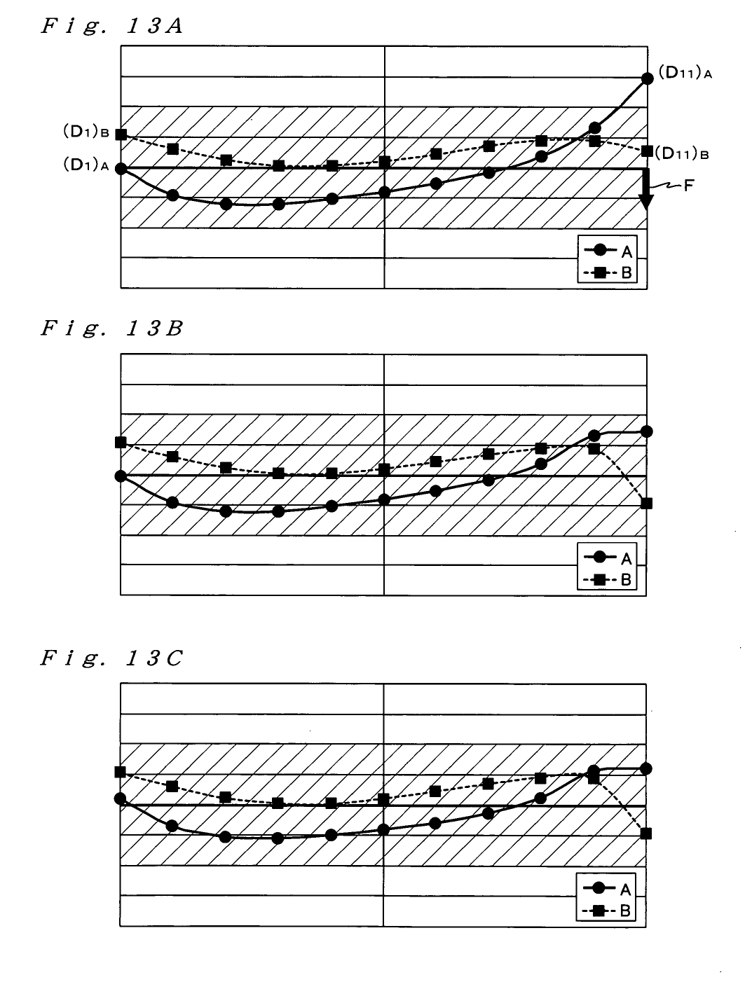

As a result, results shown in FIG. 13A were obtained as the right and left line width difference (line width abnormal values for vertical lines). FIG. 13A shows the average values of the right and left line width difference at each three measurement points (in this case, the projection position of the vertical line pattern pairs), which are located at substantially the same position in the non-scanning direction (the X-axis direction). The reason for obtaining such an average value is because the description presupposes scanning exposure.

In the case the description presupposes static exposure such as in the stepper, each image-forming performance is obtained per each measurement point.

In FIG. 13A, the black circle (●) shows the right and left line width difference for equipment A, whereas the black square (▪) shows the right and left line width difference for equipment B. Furthermore, the shaded section shows that the values are within the permissible range.

As is obvious from FIG. 13A, in equipment A, it can be seen that only the right and left line width difference value (D₁₁)_{A} on the right edge of the exposure area (the static field of the projection optical system) is outside the permissible range. In this case, when right and left line width differences (Dⱼ)_{A} and (Dⱼ)_{B} (j=1 to 11) are positive values, it indicates that the line width on the right side is larger than the line width on the left side. The focus uniformity and the pattern shift were within the permissible range at all the points for both equipment A and equipment B.

(Step 3)

Accordingly, by using −1/(2*β) of (D₁₁)_{A} above as the pattern correction value (the correction value corresponds to arrow F in FIG. 13A), the right and left line width difference at the position was corrected (by the correction, in each pair of the line patterns located at the edge on the left side within the pattern area (as a premise, the projection optical system is a dioptric system), the line pattern on the left side will have a narrower width than the line pattern on the right side) by the mask design tool. And, each image-forming performance was re-calculated in the same manner as in step 304, using the pattern data after correction, and using the appropriate adjustment amount (and the corresponding wavefront aberration) for both of the equipment calculated above (in Step 2). The calculation method of the referred to above is substantially the same as the method that uses the equation similar to equation (42) previously described, with the right and left line width difference value (D₁₁)_{B} on the right edge of the exposure area, which is within the permissible range, regarded as zero.

In this case, because FIG. 13A is based on scanning exposure, on calculating the image-forming performance, the wavefront was averaged in the scanning direction, and the wavefront data at each point was obtained, using the averaged wavefront.

As a consequence, the results shown in FIG. 13B were obtained. Similar to FIG. 13A described earlier, FIG. 13B shows the average values of the right and left line width difference at each three measurement points (in this case, the projection position of each pair of line patterns), which are located at substantially the same position in the non-scanning direction (the X-axis direction).

From FIG. 13B, it can be seen that the right and left line width difference values are within the permissible range in the entire exposure area for both equipment A and equipment B.

(Step 4)

For precaution, the above pattern correction value was substituted into the correction value corresponding to the line width abnormal value items at each measurement point on the right side edge within the exposure area, and with the remaining correction value all set to zero, optimization (such as, calculating the appropriate adjustment amount) of the image-forming performance of both equipment A and B was performed as in step 114, and in the process, each image-forming performance was calculated in a similar manner as in step 304 previously described.

As a consequence, the results shown in FIG. 13C were obtained. Similar to FIG. 13A described earlier, FIG. 13C shows the average values of the right and left line width difference at each three measurement points (in this case, the projection position of each pair of line patterns), which are located at substantially the same position in the non-scanning direction (the X-axis direction).

From FIG. 13C, it can be seen that the right and left line width difference values are within the permissible range in the entire exposure area for both equipment A and equipment B. When comparing FIG. 13C with FIG. 13B, it can be confirmed that a more favorable result can be obtained when performing aberration optimization again after pattern correction has been performed. Also in this case, issues other than the right and left line width difference, that is, the focus uniformity and the pattern shift were favorable for both equipment A and equipment B.

As is mentioned earlier in the description, in the processing in step 114, there may be a case where the wavefront aberration correction amount under the reference ID is unknown, and in this case, the wavefront aberration correction amount can be assumed from the image-forming performance under the reference ID. Hereinafter, such a case will be described.

In this case, the wavefront aberration correction amount will be assumed, presupposing that the deviation between the stand-alone wavefront aberration and the on-body wavefront aberration corresponds to deviation Δx′ in the adjustment amount of the adjustment parameters such as movable lenses 13₁ to 13₅ previously described.

When the adjustment amount supposing that the stand-alone wavefront aberration and the on-body wavefront aberration coincides with each other is expressed as Δx, and the correction amount of the adjustment amount expressed as Δx′, the ZS file expressed as ZS, the theoretical image-forming performance (the theoretical image-forming performance in the case there is no on-body wavefront aberration) under the reference ID expressed as K₀, the actual image-forming performance under the reference ID (the same adjustment parameter values) expressed as K₁, the wavefront aberration variation table expressed as H, the image-forming performance variation table expressed as H′, the stand-alone wavefront aberration expressed as Wp, and the wavefront aberration correction amount expressed as ΔWp, then, the following two equations (43) and (44) stand.
K₀=ZS*(Wp+H*Δx) (43)
K₁=ZS*(Wp+H*(Δx+Δx′)) (44)
Accordingly,
K₁−K₀=ZS*H*Δx′=H′*Δx′ (45).

Accordingly, when equation (45) above is solved by the least squares method, correction amount Δx′ of the adjustment amount can be expressed as in equation (46) below.
Δx′=(H′^{T}* H′)⁻¹*H′^{T}*(K₁−K₀) (46)

In addition, wavefront aberration correction amount ΔWp can be expressed as in equation (47) below.
ΔWP=H*Δx′ (47)

Each reference ID will have this wavefront aberration correction amount ΔWp.

In addition, the actual on-body wavefront aberration will result as in equation (48) below.
actual on-body wavefront aberration=Wp+H*Δx+ΔWp (48)

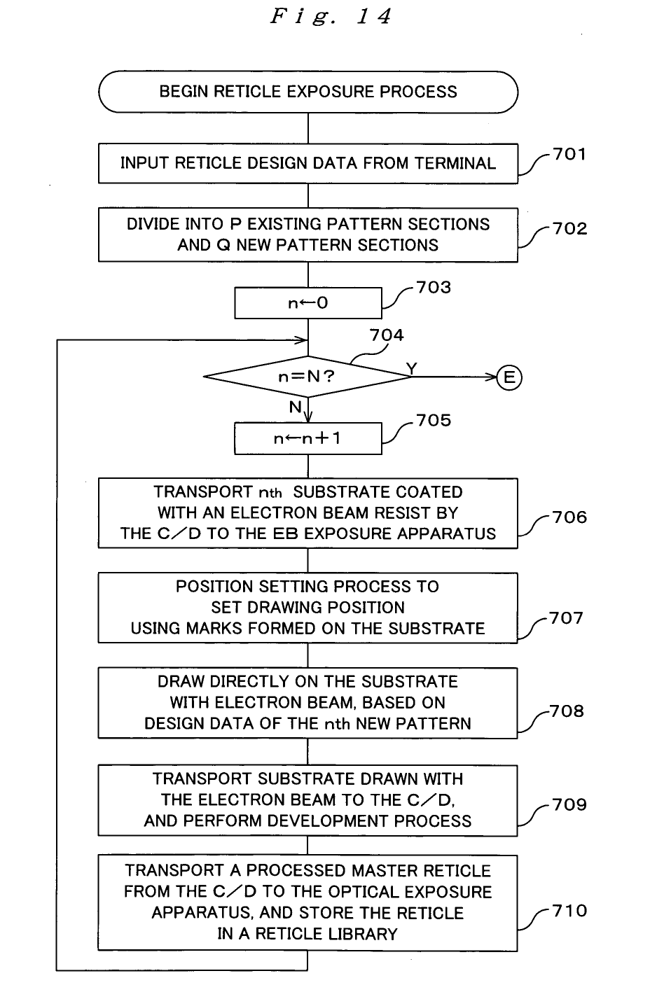

Next, an example of the operations performed when manufacturing a working reticle using reticle design system 932 and reticle manufacturing system 942 in FIG. 1 will be described, based on the flow chart in FIGS. 14 to 16. The description hereinafter exemplifies the case where working reticle R1 shown in FIG. 12 is manufactured.

First of all, in step 701 in FIG. 14, identification information that shows the partial design data of the working reticle to be manufactured and the position (e.g., a section requiring relatively loose line width accuracy) where the circuit can be divided is input to the second computer 930 from terminals 936A to 936D, via LAN 934. And, in response to the information that has been input, the second computer 930 transmits design data for a whole reticle pattern, which is all the partial design data put together, as well as its corresponding identification information to computer 940 in reticle manufacturing system 942, via LAN 936.

In the next step, step 702, computer 940 divides the reticle pattern into P existing pattern sections and Q new pattern sections (P and Q are integers that equal 1 or over), based on the design data and the identification information on the reticle pattern that has been received.

In this case, the existing pattern section is a pattern identical to the pattern of the device master reticle that has already been manufactured but reduced by a projection magnification γ (=1/α) of optical exposure apparatus 945, and the master reticle on which the existing pattern section is formed magnified by α times is stored in a reticle housing section (not shown).

On the other hand, the new pattern section refers to a device pattern that has not been made yet, or to a device pattern that has not yet been formed on the master reticle stored within the reticle housing section.

FIG. 12 shows an example of a dividing method (each dividing line is indicated by a dotted line) of the pattern on working reticle R subject to manufacturing in this case. In FIG. 12, a pattern area PA enclosed in a frame-shaped light shielding area ES on working reticle R1 is divided into 25 partial patterns, consisting of existing pattern sections S1 to S10, new pattern sections N1 to N10, and new pattern sections P1 to P5. In the case of the embodiment, existing pattern sections S1 to S10 are patterns identical to one another, new pattern sections N1 to N10 are also patterns identical to one another, and new pattern sections P1 to P5 are also patterns identical to one another.

In this case, computer 940 takes out a predetermined number of master reticles MR, one in this case, on which an enlarged pattern of existing pattern sections S1 to S10 is formed from an existing reticle housing section (not shown) using a reticle transport mechanism (not shown), and places this master reticle in a reticle library in optical exposure apparatus 945.

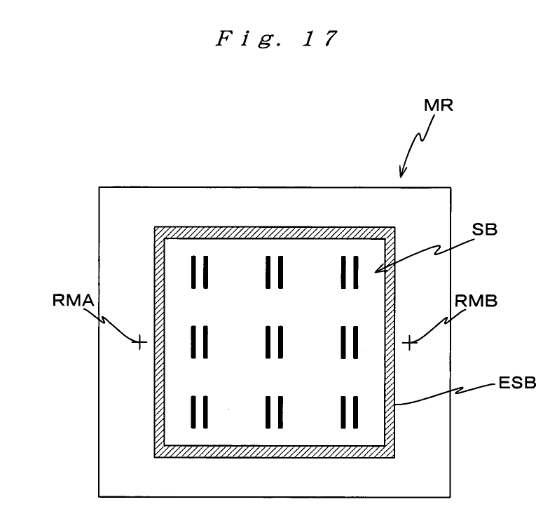

FIG. 17 shows master reticle MR described above. In FIG. 17, on master reticle MR, an original plate pattern SB, which is a pattern of existing pattern sections S1 to S10 enlarged by a times, is formed. Original plate pattern SB is made, by etching a light shielding membrane such as chrome (Cr) or the like. In addition, a light shielding area ESB consisting of chrome membrane surrounds original plate pattern SB of master reticle MR, and on the outer side of light shielding area ESB, alignment marks RMA and RMB are formed.

As the substrate (reticle blank) for master reticle MR, in the case the exposure light of optical exposure apparatus 945 is a KrF excimer laser beam, an ArF excimer laser beam, or the like, quartz (e.g., synthetic quartz) can be used. In addition, when the exposure light is an F₂ laser beam or the like, fluorite, fluorine-doped quartz or the like can be used.

Next, computer 940 makes the data for new original plate patterns of the new pattern sections N1 to N10 and new pattern sections P1 to P5 in FIG. 12 enlarged α times (e.g., 4 times, 5 times, or the like), by the reciprocal number of projection magnification γ.

Then, in steps 703 to 710 in FIG. 14, the master reticles are manufactured on which the new original plate patterns are formed.

More specifically, firstly, in step 703, computer 940 resets the value of a counter n (n←0), which shows the order of the new pattern section.

In the next step, step 704, computer 940 sees whether or not the value of counter n has reached N (in this case, since only two (types of) new master reticles have to be manufactured, N equals 2). And, when n has not yet reached N, the procedure moves to step 705 where counter n is incremented by one (n←n+1) by computer 940.

In the next step, step 706, the substrate transport system takes out an n^{th} substrate (a reticle blank) made of fluorite, fluorine-doped quartz, or the like from the blank housing section, and the substrate is coated with an electron beam resist in C/D 946, and then the substrate transport system transports the substrate from C/D 946 to EB exposure apparatus 944, via interface section 947.

On the substrate described above, predetermined alignment marks are formed. In addition, at this point, design data of the original plate patterns on which N new patterns are enlarged is sent to EB exposure apparatus 944 from computer 940.

Accordingly, in step 707, EB exposure apparatus 944 sets the drawing position of the substrate using the alignment marks of the substrate, and then after the position setting, the procedure proceeds to step 708 where the n^{th} original plate pattern is drawn directly onto the substrate.

Then, in step 709, the substrate on which the original plate pattern has been drawn is transported to C/D 946 by the substrate transport system via interface section 947, and the development processing is performed. In the case of the embodiment, since the electron beam resist has the properties of absorbing the exposure light (excimer laser beam) used in optical exposure apparatus 945 the resist pattern left by the development can be used without any change as the original plate pattern.

In the next step, step 710, the n^{th} (in this case, the first) substrate after development is transported to the reticle library in optical exposure apparatus 945 by the substrate transport system via interface section 949 as the n^{th} master reticle for the new pattern section.

Then the processing returns to step 704 where computer 940 judges whether or not the value of counter n has reached N (=2). The judgment here, however, is negative, and thereinafter, by repeating the processing in steps 705 to 710, the n^{th} (the second) master reticle corresponding to the new pattern section is manufactured. That is, the necessary number of master reticles corresponding to the new pattern section is manufactured in the manner described above.

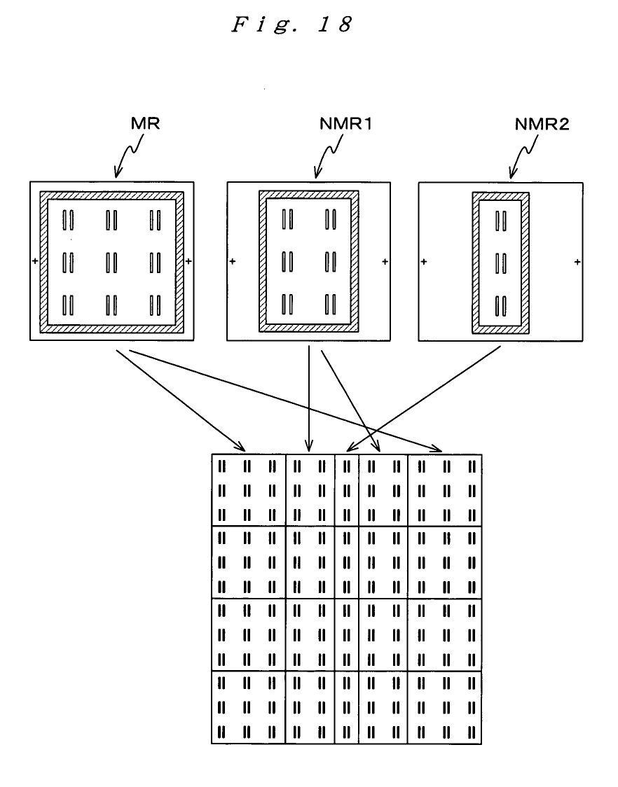

FIG. 18 shows new master reticles NMR1 and NMR2 manufactured in the manner described above, along with master reticle MR. A light shielding area is formed around the original plate pattern, also in master reticles NMR1 and NMR2.

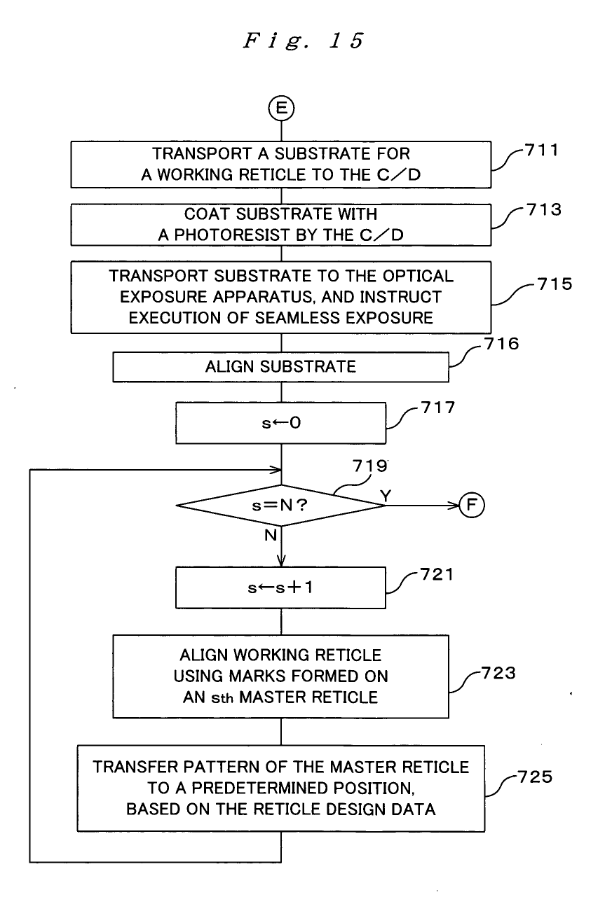

Next, in step 711 in FIG. 15, the substrate transport system takes out a substrate for a working reticle (R1), that is, a reticle blank (consisting of quartz, fluorite, fluorine-doped quartz, or the like), from the blank housing section (not shown) based on the instructions from computer 940, and transports the substrate to C/D 946. On this substrate (reticle blank), deposition of a metal film such as chromium film has been performed in advance, and marks for rough alignment is also formed. However, the marks for alignment do not necessarily have to be formed.

In the next step, step 713, C/D 946 coats a photoresist sensitive to the exposure light of optical exposure apparatus 945 on the substrate, based on the instructions from computer 940.

Next, in step 715, computer 940 transports the substrate to optical exposure apparatus 945 via interface section 949, using the substrate transport system, and gives instructions to the main controller of optical exposure apparatus 945 to perform seamless exposure (stitching exposure) using the plurality of master reticles. In this case, information on the positional relation between the new pattern sections and existing pattern sections within pattern area PA in FIG. 12 is also supplied to the main controller.

In the next step, step 716, in response to the instructions above, the main controller of optical exposure apparatus 945 loads the substrate onto the substrate holder after the substrate is aligned (pre-aligned) by the outer-shape reference, using a substrate loader system (not shown). Then, if necessary, further position alignment with respect to the stage coordinate system is performed, using the marks formed on the substrate for alignment and the alignment detection system.

In the next step, step 717, the main controller of optical exposure apparatus 945 resets a counter s, which shows the exposure sequence of the new N (in this case, two) master reticles, to zero, and then the procedure moves to step 719 where the main controller confirms whether or not the value of counter n has reached N. And, in the case the judgment is negative, the procedure then moves to step 721 where counter s is incremented by 1 (s←s+1), and the procedure moves to step 723.

In step 723, the main controller takes out the s^{th} (in this case, the first) master reticle from the reticle library and mounts the master reticle on the reticle stage. Then, using the alignment marks of the master reticle and the reticle alignment system, the main controller performs alignment of the master reticle to the stage coordinate system, and also to the substrate of working reticle (R1).

In the next step, step 725, the main controller controls the position of the wafer stage so that the exposure area of the substrate of working reticle (R1) matches the designed exposure position of the s^{th} new master reticle, and then gives instructions for scanning exposure so that the original plate pattern of the master reticle is transferred onto a predetermined area of the substrate. In this case, when the new master reticle is master reticle NMR1, which contains the original plate pattern of the new pattern sections N1 to N10 in FIG. 12, the reduced image of the patterns of the master reticle reduced by y times is sequentially transferred by seamless exposure (refer to FIG. 18), on the area corresponding to the above new pattern sections N1 to N10 on the substrate of working reticle (R1).

Then, the processing returns to step 719 where the main controller sees if the value of counter n has reached N or not again, and in the case the judgment is negative, the processing in steps 721 to 725 is repeated. In this case, in step 725, the reduced image of the patterns of a different master reticle, master reticle NMR2, which contains the original plate patterns of the new pattern sections, is sequentially transferred by seamless exposure (refer to FIG. 18) reduced by y times, on the area corresponding to the new pattern sections P1 to P5 on the substrate of working reticle (R1).

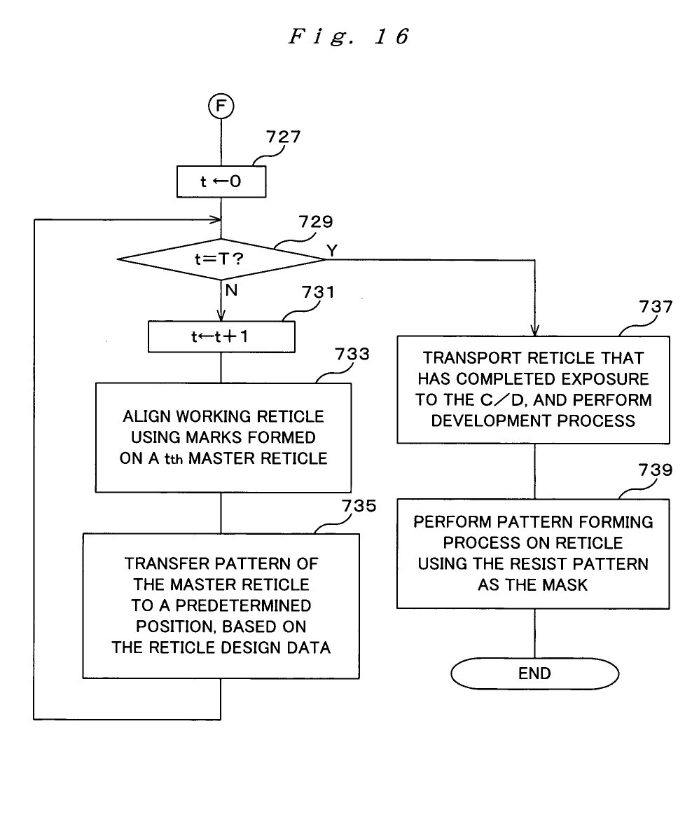

When seamless exposure using the N (in this case, two) new master reticles is completed in the manner described above, the processing then moves from step 719 to step 727 in FIG. 16.

In step 727, the main controller resets a counter t, which shows the exposure sequence of the existing master reticles of a predetermined number T (in this case, only one (type of) existing master reticle is required, therefore, T=1), to zero (t←0), and then in the next step, step 729, the main controller confirms whether or not the value of counter t has reached T. And, in the case the judgment is negative, counter t is incremented by 1 (t←t+1) in step 731, and then the procedure moves to step 733 where the t^{th} (in this case, the first) existing master reticle MR is mounted on the reticle stage and position alignment is preformed. Then, in step 735, the reduced image of the patterns of master reticle MR is transferred, each by seamless exposure based on the scanning exposure method (refer to FIG. 18), on the area corresponding to the existing pattern sections S1 to S10 on the substrate of working reticle (R1).

When seamless exposure of all the master reticles is completed in the manner described above, the processing then moves from step 729 to step 737.

In step 737, the substrate of working reticle (R1) is transported to C/D 946 shown in FIG. 1, and then the development processing is performed.

Then, the substrate after development is transported to an etching section (not shown) where etching is performed (step 739) on the remaining resist pattern, which serves as a mask. Furthermore, by performing the treatment such as resist separation, manufacturing a working reticle, such as working reticle R1 shown in FIG. 12, is completed.

Furthermore, by repeating the steps 711 to 739, working reticles that have the same pattern as working reticle R1 can be manufactured in required numbers within a short period of time.

In the embodiment, the original plate pattern drawn by EB exposure apparatus 944 is rough compared with the pattern of working reticle R1, and the pattern that is to be drawn is around half the entire pattern of working reticle R1 or less. Accordingly, the drawing time of EB exposure apparatus 944 is greatly reduced when compared with the case of directly drawing the entire pattern of working reticle R1.

Furthermore, as optical exposure apparatus 945 (projection exposure apparatus), a typical projection exposure apparatus by the step-and-scan method that can cope with the minimum line width of around 150 to 180 nm using the KrF excimer laser or the ArF excimer laser as its light source can be used, without any modification.

According to reticle design system 932 and reticle manufacturing system 942 in the embodiment, working reticle R1 and other working reticles can be manufactured in the manner described above.

As it can be easily imagined from the description so far, in the embodiment, in the case equipment A in the experiment previously referred in the description is exposure apparatus 922₁ and equipment B is exposure apparatus 922₂, when a pattern of a reticle is designed using the reticle pattern design program described earlier that can be commonly used among a plurality of exposure apparatus, pattern correction value similar to the experiment results previously described can be obtained in step 138, and in step 140, the adjustment amount can be obtained for each adjustment parameter of exposure apparatus 922₁ and 922₂ that are suitable for transferring the patterns that have been corrected, by setting the pattern of working reticle R1 as the subject pattern, and by specifying (selecting) exposure apparatus 922₁ and 922₂ as the equipment subject to optimization according to step 104 previously described.

Now, in the case the processing to obtain the above pattern correction value is performed after manufacturing the actual working retile R1, the case will be considered of manufacturing a working reticle commonly used in exposure apparatus 922₁ and 922₂ that contains a pattern similar to working reticle R1.

In this case, prior to the processing in step 702 described above, among the design data of working reticle R1, pattern data whose design data of the patterns of pattern sections S2, S4, S6, S8, and S10 located within pattern area PA on the right edge in FIG. 12 have been corrected based on the pattern correction value referred to above (data whose line width difference has been corrected for each pair of the line patterns located at the edge on the left side within pattern area PA) is transmitted as the design data of the reticle pattern to computer 940 in reticle manufacturing system 942 from the second computer 930.

Then, in reticle manufacturing system 942, a master reticle that has an original plate pattern, which contains an enlarged pattern of the pattern sections S2, S4, S6, S8, and S10, is manufactured as the new master reticle described earlier in the description.

Then, by performing seamless exposure previously described using this new master reticle and the master reticles that are already manufactured corresponding to the remaining pattern sections S1, S3, S5, S7, S9, N1 to N10, and P1 to P5, a working reticle containing the pattern of working reticle R1 that has been corrected based on the pattern correction value is manufactured within a short period of time without fail, in numbers when necessary.

Details on the reticle manufacturing method using a system similar to the reticle design system and reticle manufacturing system in the embodiment are disclosed in, for example, WO99/34255 (corresponding U.S. Pat. No. 6,677,088), WO99/66370 (corresponding U.S. Pat. No. 6,653,025), U.S. Pat. No. 6,607,863, and the like, and the various methods disclosed in the above WO Publication and the U.S. Patents can be used with or without any modification in this embodiment. As long as the national laws in designated states (or elected states), to which this international application is applied, permit, the above disclosures of each publication and the U.S. Patents are incorporated herein by reference. In addition, optical exposure apparatus 945 was described as a scanning stepper, however, it can also be a static type exposures apparatus (such as a stepper), and the seamless exposure previously described can be performed similarly with the stepper by the step-and-stitch method.

In exposure apparatus 922₁ to 922_{N} related to the embodiment, when manufacturing semiconductor devices, the working reticle for device manufacturing is loaded on reticle stage RST, and then, preparatory operations such as reticle alignment, the so-called baseline measurement of the wafer alignment system, EGA (Enhanced Global Alignment), and the like are performed.

Details on the preparatory operations such as the above reticle alignment and baseline measurement are disclosed in, for example, Kokai (Japanese Unexamined Patent Application Publication) No. 7-176468 and the corresponding U.S. Pat. No. 5,646,413, referred to earlier, whereas details on the following operation, EGA, are disclosed in, for example, Kokai (Japanese Unexamined Patent Application Publication) No. 61-44429 and the corresponding U.S. Pat. No. 4,780,617. As long as the national laws in designated states (or elected states), to which this international application is applied, permit, the above disclosures of each publication and the U.S. Patents are incorporated herein by reference.

Then, based on the wafer alignment results, exposure by the step-and-scan method is performed. Since the operations or the like on exposure are the same as a typical scanning stepper, the details here will be omitted.

In the case the working reticle manufactured in the manner described above, which is made as a common reticle to be used among a plurality of exposure apparatus, is to be used among a plurality of exposure apparatus subject to optimization, the first computer 920 provides the new reference IDs of each equipment (exposure apparatus 922) and information on the corresponding appropriate adjustment amount stored in the memory such as the RAM instep 140 previously described to main controller 50 of each exposure apparatus 922. Then, based on the information, main controller 50 of each exposure apparatus 922 sets the exposure conditions according to the new reference IDs, and also executes optimization of the transferred image of the pattern of the working reticle in the following manner.

More specifically, based on instruction values of the drive amount of movable lenses 13₁, 13₂, 13₃, 13₄, and 13₅ in directions of each degree of freedom (drivable direction), z₁, θx₁, θy₁, z₂, θx₂, θy₂, z₃, θx₃, θy₃, z₄, θx₄, θy₄, z₅, θx₅, and θy₅, provided as the information on the appropriate adjustment amount, a predetermined calculation is performed to calculate the respective drive instruction values for each of the three drive elements that drive each movable lens, and the results are sent to image-forming characteristics correction controller 48. Accordingly, image-forming characteristics correction controller 48 controls the applied voltage to each drive element that drives movable lenses 13₁ to 13₅ in directions of the respective degrees of freedom. In addition, control information TS is provided to light source 16 based on the wavelength shift amount Δλ of illumination light EL, so as to adjust the center wavelength.

And, in a state where the adjustment of each section has been performed as is described above, exposure by the step-and-scan method is performed. While the exposure (scanning exposure) is being performed, focus leveling control of wafer W is executed using the focal point position detection system (60a, 60b) described earlier, based on drive amounts Wz, Wθx, and Wθy of the surface of wafer W (Z-tilt stage 58) in three degrees of freedom, which are provided as the appropriate adjustment amount.

Accordingly, the pattern of the working reticle can be transferred onto wafer W with good precision in any of the equipment (exposure apparatus 922). In addition, adjustment or the like of the image-forming performance of projection optical system PL for optimizing the transferred state of the pattern can also be performed within a very short time.

However, in the case above, the first computer 920 does not necessarily have to provide the information on the adjustment amount. In such a case, main controller 50 of each exposure apparatus 922 will perform the setting of optimization exposure conditions with the pattern of the working reticle as a reference as well as the adjustment of the image-forming performance of projection optical system PL, in a state where the working reticle is loaded on reticle stage RST, and also in this case, the exposure conditions setting and the adjustment of the image-forming performance of projection optical system PL in order to transfer the pattern of the working reticle with good precision can be performed without fail in any of the exposure apparatus. This is because the reticle design system has confirmed that the optimization is favorable, as is previously described.

As is obvious from the description so far, in the embodiment, movable lens 13₁ to 13₅, Z-tilt stage 58, and light source 16 constitute an adjustment section, while the position (or the variation amount) of movable lens 13₁ to 13₅ and Z-tilt stage 58 in the Z, θx, and θy directions and the wavelength shift amount of the illumination light from light source 16 serve as the adjustment amount. And, each above adjustment section, drive elements driving the movable lenses, image-forming characteristics correction controller 48, and wafer stage drive section 56 driving Z-tilt stage 58 constitute an adjustment unit. However, the configuration of the adjustment unit is not limited to this, and for example, only movable lens 13₁ to 13₅ may be included as the adjustment section. This is because even in such a case, it is possible to adjust the image-forming performance (aberrations) of the projection optical system.

As is described in detail above, according to device manufacturing system 10, when deciding the information of the pattern that is to be formed on the reticle (working reticle) which will be used among a plurality of exposure apparatus, the second computer 930 performs the following optimization processing in the optimization processing step (steps 110 to 132 in FIG. 5) for the exposure apparatus subject to optimization selected from among the plurality of exposure apparatus 922₁ to 922_{N} connecting via LAN 926 and LAN 918.

More specifically, in the processing, a first step (steps 114 to 118) and a second step (steps 120, 124, and 126) are repeatedly performed until as a result of the judgment in step 2, the image-forming performance of the projection optical system in all the exposure apparatus falls within the permissible range and the judgment made in step 120 turns positive. In the first step, the appropriate adjustment amount of the adjustment unit so as to adjust the forming state of the projected image of the pattern on the object is calculated for each exposure apparatus under target exposure conditions, which take into consideration correction information on the pattern, based on a plurality of types of information that includes the adjustment information of the adjustment unit including the pattern information and information related to the image-forming performance of the projection optical system corresponding to the adjustment information under predetermined exposure conditions, correction information on the pattern, and information on the permissible range of the image-forming performance. And in the second step, the judgment is made whether or not the predetermined image-forming performance of the projection optical system in at least one exposure apparatus is outside the permissible range under the target exposure conditions after the adjustment unit has been adjusted according to the appropriate adjustment amount for each exposure apparatus calculated in the first step, and by the judgment, based on the image-forming performance resulting to be outside the permissible range, the correction information is set according to a predetermined criterion.

More specifically, a. first of all, the pattern correction value is set to a predetermined initial value, e.g., zero, and with a known pattern serving as a pattern subject to projection, the adjustment amount of the adjustment unit when projecting the pattern is calculated for each of a plurality of exposure apparatus, and b. and then, in the case the adjustment unit of each exposure apparatus has been adjusted based on-their appropriate adjustment values, the judgment is made whether or not the image-forming performance of the projection optical system in at least one exposure apparatus is outside the permissible range. c. As a consequence, in the case the image-forming performance of the projection optical system is judged to be outside the permissible range in one or a plurality of exposure apparatus, the pattern correction value is set according to a predetermined criterion corresponding to the image-forming performance outside the permissible range. d. And then, by correcting the above known pattern with the pattern correction value that has been set and using the pattern as the pattern subject to projection, the adjustment amount of the adjustment unit when projecting the pattern is calculated for each of the plurality of exposure apparatus, and hereinafter, the steps b., c., and d. above are repeated.

Then, in the optimization processing step above, when the image-forming performance of projection exposure apparatus PL falls within the permissible range for all the exposure apparatus, that is, in the case there is no more image-forming performance outside the permissible range by setting the correction value, or in the case the image-forming performance of the projection exposure apparatus in all the exposure apparatus is within the permissible range from the very start, then, in the decision making step (step-138), the second computer 930 decides the correction value set in the above optimization processing step as the pattern correction information, and outputs (transmits) the information to the first computer 920, as well as store the information in the memory such as the RAM while making the information correspond to the pattern information.

Accordingly, by using the pattern correction information decided in the manner described above or the pattern information of the pattern that has been corrected with the pattern correction information when manufacturing a working reticle, it become possible to easily achieve manufacturing a working reticle that can be commonly used among a plurality of exposure apparatus. Incidentally, the calculation criterion (setting criterion) of the pattern correction value described in step 126 in the embodiment is a mere example, therefore, for example, the pattern correction value may be a value half of the image-forming performance resulting to be outside the permissible range. What matters is that the image-forming performance resulting to be outside the permissible range can be set within the permissible range with the criterion.

In addition, according to device manufacturing system 10 in the embodiment, the second computer 930 judges (step 122) whether or not the above first step and the above second step has been repeated M times (a predetermined number of times), and in the case the judgment of repeating the processing M times before the image-forming performance of the projection optical system in all the exposure apparatus falls within the permissible range turns positive in step 2, the second computer 920 shows that it is beyond optimization (step 134) on the screen, and ends the processing.

This operation takes into consideration, for example, the case when the permissible range of the image-forming performance is extremely small or the case when the pattern correction value should not be largely increased, where the situation may occur when the appropriate adjustment amount for all the exposure apparatus cannot be calculated in a state satisfying the required conditions no matter how many times the pattern correction value setting is performed. That is, in such a case, by ending the processing (forced termination) at the point where the first and second steps are repeatedly performed a predetermined number of times, it can prevent time from being wasted. However, there are cases when the permissible range of the image-forming performance is not so small or when the pattern correction value may be largely increased, and in such cases, step 122 where the M times of repetition is checked may not necessarily be required.

The measures taken after the above forced termination will now be briefly described. For example, in the case the above forced termination is executed when designing a reticle that can be commonly used in equipment A and equipment B, reticles optimized for each equipment, equipment A and equipment B, can be designed (and manufactured), respectively. Or, an equipment C, can be newly added to the choice of optimization, then equipment A and equipment C, as well as equipment B and equipment C can be specified as the equipment subject to optimization, and the processing shown in the flow chart in FIG. 5 previously described can be performed. In this case, a reticle that can be commonly used in equipment A and equipment C and a reticle that can be commonly used in equipment B and equipment C can be designed (and manufactured).

In addition, in device manufacturing system 10 in the embodiment, as is described above, information on the pattern correction value is decided by the second computer 930 constituting the reticle design system according to the processing in the flow chart in FIG. 5, and by correcting an original pattern based on the decided information on the correction value, the information on a pattern that makes the image-forming performance in any of the exposure apparatus fall within the permissible range when forming a projected image by projection optical system PL in a plurality of exposure apparatus is decided.

Then, the information on the pattern (or the information on the correction value described above) is provided to computer 940 used for production control in reticle manufacturing system 942, and reticle manufacturing system 942 uses the information to form a pattern on a reticle blank and easily manufactures a working reticle that can be used commonly in a plurality of exposure apparatus.

In addition, according to device manufacturing system 10 in the embodiment, the working reticle manufactured by reticle manufacturing system 942 in the manner described above is loaded into each specified exposure apparatus subject to optimization, and in a state where the image-forming performance of projection optical system PL equipped in each exposure apparatus is adjusted to match the pattern of the working reticle, wafer W is exposed via the working reticle and projection optical system PL. Because the pattern formed on the working reticle is decided so that the image-forming performance of projection optical system PL should be within the permissible range in any of the specified (selected) plurality of exposure apparatus subject to optimization at the pattern information deciding stage, the image-forming performance can be adjusted within the permissible range for certain by the above adjustment of the image-forming performance of projection optical system PL performed to match the pattern of the working reticle. In this case, as is previously described, the values of the adjustment amount of the adjustment unit that were obtained when optimizing the image-forming performance of each exposure apparatus to decide the pattern correction value may be stored, and the values can be used without any changes to adjust the image-forming performance of the projection optical system, or, the appropriate values of the adjustment parameters of the image-forming performance may be obtained again. In any case, according to the above exposure, the pattern is transferred onto the wafer with good precision.

As is obvious from the description so far, when a working reticle is manufactured in the embodiment, optimization of the image-forming performance in a plurality of exposure apparatus (the plurality of specified equipment subject to optimization previously described) that are supposed to use the working reticle is also performed, when the reticle pattern is designed. Therefore, the following merits can be obtained.

More specifically, when focusing on a certain pattern (a working reticle on which the pattern is formed), the range of the exposure apparatus in which the pattern can be used broadens. On the contrary, when focusing on a certain exposure apparatus, the range of the pattern that can be shared with other exposure apparatus can be broadened, which allows transfer in a state more favorable than when optimization of only the image-forming performance (aberrations) is performed for each exposure apparatus using the same reticle (mask).

In addition, because correction of line width difference or the like of the pattern image due to aberration or the like of the projection optical system was performed for each exposure apparatus in the pattern correction method described in Japanese Patent Publication No. 3343919 referred to earlier, there was consequently a high tendency of manufacturing a working reticle that had a different pattern for each exposure apparatus, whereas, in the embodiment, the working reticle can be commonly used among a plurality of equipment, which consequently leads to reducing the reticle cost and also allows flexible operation among the equipment.

In the embodiment above, main controller 50 of at least one exposure apparatus specified as the equipment subject to optimization among exposure apparatus 922₁ to 922_{N} may calculate the adjustment amount of the adjustment unit under target exposure conditions, which take into consideration the pattern correction information, under predetermined exposure conditions, using for example, adjustment information on the reference ID closest to the optimization exposure conditions previously described, information related to the image-forming performance of projection optical system PL, and the pattern correction information in the working reticle manufacturing stage by reticle design system 932 and reticle manufacturing system 942 (this information is available by sending an inquiry to the first computer), and the adjustment unit can be controlled according to the calculated adjustment amount. In this case, on calculating the appropriate adjustment amount, the same method as in the equipment optimization in step 114 in the embodiment above can be employed. In addition, in this case, main controller 50 constitutes a processing unit connecting to the adjustment unit via signal lines.

In the manner described above, the adjustment amount that make the image-forming performance of projection optical system PL more favorable than when the pattern correction value is not taken into consideration can be calculated. Furthermore, even in the case where it is difficult to calculate the adjustment amount that make the image-forming performance of the projection optical system fall within the permissible range decided in advance under the target exposure conditions when the pattern correction information is not taken into consideration, by calculating the adjustment amount of the adjustment unit under the target exposure conditions taking into consideration the pattern correction information, a case may occur when it becomes possible to calculate the adjustment amount that make the image-forming performance of the projection optical system fall within the permissible range decided in advance.

Then, when the adjustment unit is adjusted according to the calculated adjustment amount, the image-forming performance of the projection optical system is adjusted more favorably than when the pattern correction information is not taken into consideration. Accordingly, the adjustment capability of the image-forming performance of the projection optical system to the pattern on the working reticle can be substantially improved.

In the description so far, equipment A and equipment B were chosen as the equipment subject to optimization for the sake of convenience, however, it is obvious from the flow chart in FIG. 5 that device manufacturing system 10 in the embodiment is not a system for sharing a working reticle between only two exposure apparatus. That is, according to device manufacturing system 10 in the embodiment, a working reticle can be manufactured that can be commonly used among any plurality of exposure apparatus in the plurality of exposure apparatus 922₁ to 922_{N}, at a maximum of N exposure apparatus.

In the embodiment above, for calculating the image-forming performance, information on stand-alone wavefront aberration obtained instep 206 in FIG. 6, the values of the adjustment amount (adjustment parameters) under the reference ID closest to the optimization exposure conditions, and wavefront aberration data of projection optical system PL, which are calculated using the wavefront aberration correction amount to stand-alone wavefront aberration under the reference ID, were used (refer to step 250). However, the calculation method is not limited to this, and adjustment information of the adjustment unit in each equipment just before optimizing the image-forming performance previously described and the actual measurement data of the image-forming performance of the projection optical system, such as the actual measurement data of wavefront aberration measured using wavefront aberration measuring instrument 80 earlier described, can be used for calculating the image-forming performance. In such a case, because the appropriate adjustment amount of the adjustment unit under the optimization exposure conditions or the target exposure conditions is calculated based on the actual measurement data of wavefront aberration of the projection optical system which is actually measured just before optimization, it becomes possible to calculate the accurate adjustment amount. In this case, since the calculated adjustment amount is based on the actual measurement values, the precision of the adjustment amount is equal to or higher than the calculated amount previously described in the embodiment.

In this case, as the actual measurement data, any data can be used as long as it is a base for calculating the appropriate adjustment amount of the adjustment unit under the optimization exposure conditions (or the target exposure conditions), along with the adjustment information of the adjustment unit. For example, the actual measurement data may include the actual measurement data on wavefront aberration, however, the actual measurement data is not limited to this, and it may include the actual measurement data on an arbitrary image-forming performance under the optimization exposure conditions. In such a case, by using the actual measurement data on the image-forming performance and the Zernike Sensitivity chart (ZS file) previously described, wavefront aberration can be obtained by a simple calculation.

The processing algorithm of the second computer 930 described in the embodiment above is a mere example, and it is a matter of course that the present invention is not limited to this.

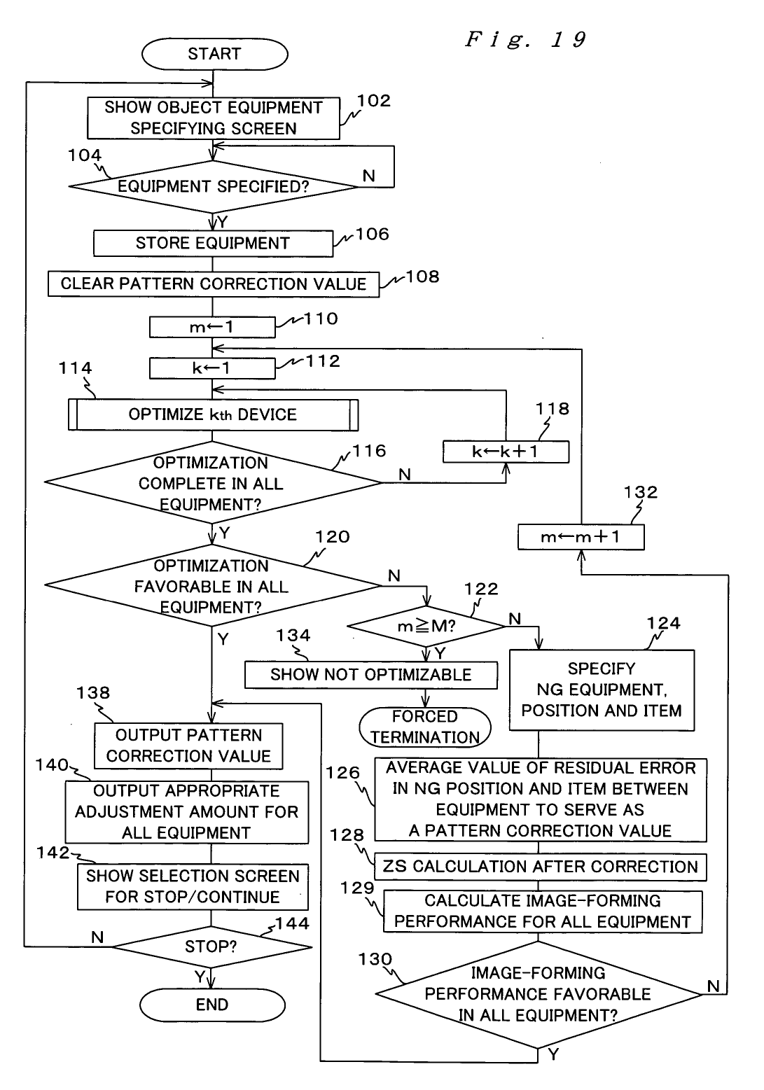

Next, a modified example of the embodiment above is described. The feature of the modified example is the point that it employs the program shown in the flow chart in FIG. 19 as the program corresponding to the processing algorithm of the second computer 930 in the embodiment previously described. The configuration of the total system is the same as the embodiment above.

As a whole, the flow chart in FIG. 19 is roughly the same as the flow chart in FIG. 5 described earlier, however, it differs on the point that a step 129 and a step 130 are added in between the step where the ZS after pattern correction is calculated (step 128) and the step where counter M is incremented (step 132). The difference will be described in the description below.

In step 129 in FIG. 19, the 12 types of aberration (the image-forming performance) for each equipment at all the evaluation points is calculated in the manner below, using the appropriate adjustment amount (the adjustment amount of the 19 adjustment parameters) of each equipment obtained prior to the revision with the pattern correction value in step 126, the pattern correction value (pattern correction data (matrix C described earlier)) whose elements are partially revised in step 126, and the ZS file revised in step 128.

More specifically, each element of matrix Wa in equation (12) described earlier is obtained based on the adjustment amount of the 19 adjustment parameters, the wavefront aberration variation table described earlier, and the stand-alone wavefront aberration, and then, using matrix Wa, the ZS file revised in step 128, and matrix C whose elements are partially revised, the calculation in equation (10) described earlier is performed. Then, the 12 types of aberration (the image-forming performance) for each equipment at all the evaluation points calculated in the manner described above is stored in the temporary storage area in the memory such as the RAM referred to earlier, while being made to correspond with their corresponding target (target value) and permissible value.

In the next step, step 130, the judgment is made for each equipment whether or not the difference between the 12 types of aberration (the image-forming performance) for each equipment at all the evaluation points calculated in step 129 above and their corresponding target is within the permissible range set by the permissible value, and by such a judgment, the judgment is made whether or not the image-forming performance is favorable in all the equipment. In this case, step 130 represents a second judgment step, and step 120 represents a first judgment step.

Then, in the case the judgment in step 130 above is negative, the procedure returns to step 132 where counter m is incremented by 1, and then the optimization processing for each equipment, which is previously described in step 112 and thereinafter, is repeatedly performed. On the other hand, in the case the judgment in step 130 is positive, the procedure then jumps to step 138 where the pattern correction value (pattern correction data) whose elements are partly revised in step 126 is output (transmitted) to the first computer 920 and stored in the temporary storage area in the memory such as the RAM, while being made to correspond with the pattern information.

The processing in the other steps are the same as the flow chart in FIG. 5 previously described.

In the case the program corresponding to the flow chart in FIG. 19 is employed as the program corresponding to the processing algorithm of the second computer 930, when the image-forming performance of projection optical system PL in all the exposure apparatus is within the permissible range in step 130, the procedure moves to step 138 (corresponds to the decision making step) without returning to the first step where the correction value set at this point is decided and output as the pattern correction information. Accordingly, the pattern correction value (pattern correction information) can be decided and output within a short period of time when compared with the embodiment previously described where the pattern correction value is decided confirming that the image-forming performance of the projection optical system in all the exposure apparatus is within the permissible range, after the appropriate adjustment amount is calculated again by returning to the first step.

In the embodiment above and the modified example above, the case has been described where a ZS file was newly made corresponding to the target exposure conditions whose pattern information is corrected using the pattern correction value, after the revision of the pattern correction value. However, in the case the pattern correction value is small, because it can be presumed that the ZS hardly changes before and after the pattern correction, step 128 previously described does not necessarily have to be arranged. Or, whether recalculation of the ZS is necessary or not can be judged according to the amount of the pattern correction value.

In addition, in the embodiment above and the modified example above, weight (weight of the image-forming performance, and weight at each evaluation point within the field) specifying, target (target values of the image-forming performance at each evaluation point within the field) specifying, optimization field range specifying, and the like described earlier do not necessarily have to be performed. This is because these can be specified in advance by the default setting, as is previously described.

For similar reasons, permissible values and restraint conditions do not necessarily have to be specified.

On the contrary, other functions that were not described above may be added. For example, the evaluation mode may be specified. More specifically, the ways of evaluation can be specified such as in, for example, absolute value mode, maximum minimum width mode (per axis, total), and the like. In this case, the optimization calculation itself is always performed with the absolute values of the image-forming performance as the target, therefore, the absolute value mode should be set as the default setting, and the maximum minimum width mode should be an optional mode.

To be more specific, for the image-forming performance such as distortion whose average value in each axis direction for the X-axis and Y-axis can be subtracted as the offset, the maximum minimum width mode (range/offset per axis) should be able to be specified. In addition, for the image-forming performance such as TFD (total focus difference depending on the uniformity within the plane in astigmatism and curvature of field) whose average value of the entire XY plane can be subtracted as the offset, the maximum minimum width mode (range/total offset) should be able to be specified.

The maximum minimum width mode will be necessary when the calculation results are evaluated. More specifically, by deciding whether or not the width is within the permissible range or not, in the case the width is not within the permissible value, it becomes possible to perform the optimization calculation again with the calculation conditions (such as weight) changed.

In addition, in the embodiment above, the case has been described where a plurality of sets of a pattern consisting of two line patterns were assumed as the subject patterns, and in at least one set of the patterns, a pattern correction value in order to correct the line width difference (that is, it corresponds to the line width abnormal value which is the index value for coma) of the two line patterns is calculated, however, the present invention is not limited to this. More specifically, for example, in the case the object is to perform positional deviation (positional deviation within the XY plane) correction of the two line patterns each of the patterns above, along with the correction of the line width difference previously described, instead of matrix C expressed earlier in equation (14), matrix C′ expressed in equation (49) below may be used to perform the calculation in equation (10) previously described.

$${C}^{′} = [ \begin{matrix}{C}_{1 , 1} & {C}_{1 , 2} & {C}_{1 , 3} & {C}_{1 , 4} & {C}_{1 , 5} & {C}_{1 , 6} & 0 & 0 & 0 & 0 & 0 & 0 \\ {C}_{2 , 1} & {C}_{2 , 2} & {C}_{2 , 3} & {C}_{2 , 4} & {C}_{2 , 5} & {C}_{2 , 6} & 0 & 0 & 0 & 0 & 0 & 0 \\ {C}_{3 , 1} & {C}_{3 , 2} & {C}_{3 , 3} & {C}_{3 , 4} & {C}_{3 , 5} & {C}_{3 , 6} & 0 & 0 & 0 & 0 & 0 & 0 \\ & & & & & & & & & & & \\ ⋮ & ⋮ & ⋮ & ⋮ & ⋮ & ⋮ & ⋮ & ⋮ & ⋮ & ⋮ & ⋮ & ⋮ \\ & & & & & & & & & & & \\ {C}_{33 , 1} & {C}_{33 , 2} & {C}_{33 , 3} & {C}_{33 , 4} & {C}_{33 , 5} & {C}_{33 , 6} & 0 & 0 & 0 & 0 & 0 & 0\end{matrix} ] \qquad ( 49 )$$

In equation (49) above, C_{i,1} is the correction value (that is, the correction value of the positional deviation amount of the pattern in the X-axis direction) of distortion Disₓ in the X-axis direction at the i^{th} measurement point, and C_{i,2} is the correction value (that is, the correction value of the positional deviation amount of the pattern in the Y-axis direction) of distortion Dis_{y} in the Y-axis direction at the i^{th} measurement point.

As a matter of course, in the case the object is to perform only positional deviation (positional deviation within the XY plane) correction of the two line patterns each of the patterns above, a matrix having the elements of matrix C′ with the elements in the 3^{rd}, 4^{th}, 5^{th} and 6^{th} column set to zero may be used, instead of matrix C.

The various changes described above in the processing algorithm of the second computer 930 can be achieved easily, by changing the software.

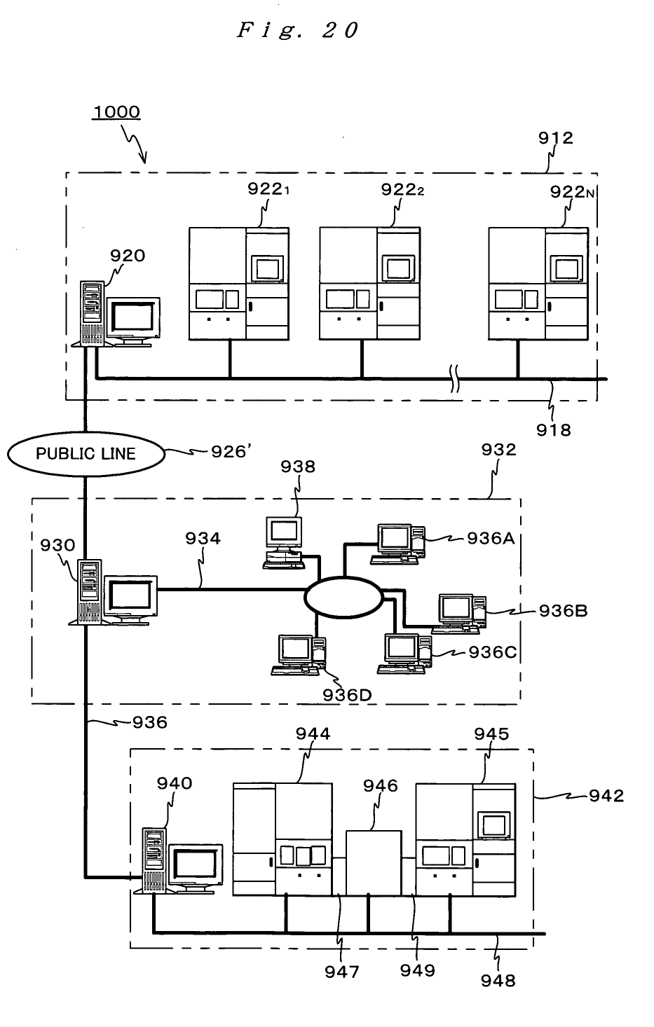

The system configuration described in the embodiment above is a mere example, and the pattern decision system related to the present invention is not limited to this. For example, as in the computer system shown in FIG. 20, a system configuration may be employed that has a communication channel containing a public line 926′ in a part of its channel.

FIG. 20 shows a system 1000 configured including lithography system 912 built in a semiconductor factory of a device manufacturer (hereinafter referred to as ‘manufacturer A’ as appropriate) that uses equipment such as exposure apparatus for manufacturing devices, and reticle design system 932 and reticle manufacturing system 942 on the mask manufacturer (hereinafter referred to as ‘manufacturer B’ as appropriate) side connecting to lithography system 912 via the communication channel containing public line 926′ in a part of its channel.

System 1000 in FIG. 20 is suitable, especially in the case when, for example, manufacturer B receives a request from manufacturer A to manufacture a working reticle that is planned to be commonly used in a plurality of exposure apparatus in exposure apparatus 922₁ to 922_{N}.

In addition, lithography system 912 and the reticle manufacturing system 942 may be arranged within the same clean room. In this case, C/D 946 and at least one exposure apparatus in exposure apparatus 922 may be inline connected, without arranging optical exposure apparatus 945 constituting reticle manufacturing system 942. In such a case, exposure apparatus 922 can be used instead of exposure apparatus 945, and in this case, as wafer stage WST of the exposure apparatus, a unit whose wafer holder and substrate holder have an exchangeable structure should be employed.

In addition, in the embodiment above and the modified example in FIG. 20, the case has been described where the reticle design system is stored within the second computer 930. However, the present invention is not limited to this, and for example, a CD-ROM storing the reticle design program and the database that goes with the program can be loaded into drive unit 46 equipped in at least one exposure apparatus in exposure apparatus 922, and the reticle design program and the database that goes with the program may be installed or copied into storage unit 42 such as a hard disc. Such an arrangement makes it possible for the operator of exposure apparatus 922 to obtain pattern correction value (pattern correction information) that can be used in both exposure apparatus 922 and other exposure apparatus that plan to share the reticle, by performing the operations described earlier similar to the operator of the second computer 930. And by sending the pattern correction information to their own mask manufacturing department, a mask manufacturer, or the like by phone, fax, or e-mail, or the like, the working reticle that is planned to be commonly used in a plurality of exposure apparatus can be manufactured for certain. In addition, a configuration where the programs corresponding to the various processing algorithms such as deciding the pattern correction value, manufacturing the reticle, optimizing the image-forming performance of the projection optical system in the exposure apparatus are executed by a single computer (for example, a computer that has an overall control of the lithography process) may be employed, or a configuration where a plurality of computers execute the programs corresponding to each processing algorithm or an arbitrary combination of the processing algorithms may be employed.

The decision method of the pattern correction value described in the embodiment above and the modified example is a mere example of the pattern decision method of the present invention, and it is a matter of course that the pattern decision method of the present invention is not limited to this. More specifically, the pattern decision method of the present invention is a pattern decision method where the information is decided on the pattern to be formed on the mask used in a plurality of exposure apparatus. Therefore, any method may be employed, as long as the pattern information can be decided so that a predetermined image-forming performance falls within a permissible range when a projected image of the pattern is formed by the projection optical system in a plurality of exposure apparatus. In such a case, by using the pattern information decided when manufacturing a mask, it becomes possible to achieve manufacturing a mask that can be used commonly in a plurality of exposure apparatus easily.

As a consequence, the above two merits, that is; the merit of being able to perform transfer in a more favorable state than when performing only optimization of the image-forming performance (aberration) for each exposure apparatus using the same mask, and to broaden the range of the pattern that can be shared with another exposure apparatus, and the merit of being able to reduce the mask cost and being able to increase the operational flexibility of the exposure apparatus, since it will become possible to commonly use the mask in a plurality of exposure apparatus, can be obtained.

In reticle manufacturing system 942 in the embodiment above and the modified example, EB exposure apparatus 944 manufactures the master reticle, and optical exposure apparatus 945 manufactures the working reticle using the master reticle. However, the configuration of reticle manufacturing system 942 is not limited to this, and for example, a system may be employed where the working reticle is manufactured using only EB exposure apparatus 944, without arranging optical exposure apparatus 945.

In addition, in the embodiment above and the modified example, the operator is to perform input of various conditions or the like, however, for example, setting information of various exposure conditions that are necessary may be set as default setting values, and according to the setting values, the second computer 930 may perform the various types of processing previously described. When such an arrangement is employed, the various types of processing can be performed, without the operator intervening in the processing. In this case, the display on the screen may be shown in the same manner as is previously described. Or, the operator may make a file in advance for various condition settings different from the above default setting, and the CPU of the second computer 930 can read the setting data in the file when necessary and the various types of processing can be performed according to the data that has been read. When such and arrangement is employed, the operator does not have to intervene as in the case above, and in addition, it also becomes possible to make the second computer 930 execute the various types of processing, according to the condition settings requested by the operator different from the default setting.

In the embodiment above, in the case the actual measurement data of wavefront aberration is used as the actual measurement data of the image-forming performance of the projection optical system, a wavefront aberration measuring instrument can be used, for example, for measuring the wavefront aberration, and as the wavefront aberration measuring instrument a wavefront aberration measuring instrument whose total shape is made exchangeable with the wafer holder may be used. In such a case, the wavefront aberration measuring instrument can be automatically transported using the transport system (such as the wafer loader), which loads the wafer and the wafer holder onto, as well as unload the wafer and the wafer holder from wafer stage WST (Z-tilt stage 58). In addition, the configuration of the wavefront aberration measuring instrument is not limited to the ones shown in FIGS. 3, 4A, and 4B, and any configuration may be employed. The wavefront aberration measuring instrument loaded on the wafer stage does not have to have wavefront aberration measuring instrument 80 described earlier entirely incorporated, and wavefront aberration measuring instrument 80 may be only partially incorporated, with the remaining section arranged external to the wafer stage. Furthermore, in the embodiment above, wavefront aberration measuring instrument 80 is described freely detachable to the wafer stage, however, it may be permanently installed in the wafer stage. In this case, wavefront aberration measuring instrument 80 may be arranged only partially in the wafer stage, and the remaining section arranged external to the wafer stage. Furthermore, in the embodiment above, the aberration of light-receiving optical system of wavefront aberration measuring instrument 80 was ignored; however, the wavefront aberration of the projection optical system may be decided taking into consideration the wavefront aberration. In addition, in the case the measurement reticle disclosed in, for example, U.S. Pat. No. 5,978,085, is used for measuring the wavefront aberration, the positional deviation of the latent image of the measurement pattern transferred and formed on the resist layer of the wafer from the latent image of the reference pattern may be detected, for example, by alignment system ALG equipped in the exposure apparatus. In the case of detecting the latent image of the measurement pattern, a photoresist may be used as the sensitive layer of the object such as a wafer, or a magnetooptical material may be used. Furthermore, the exposure apparatus and the coater developer may be inline connected, and the resist image that can be obtained when developing the wafer on which the measurement pattern has been transferred may be detected by alignment system ALG in the exposure apparatus, further with the etched image that can be obtained by the etching process. In addition, a measurement unit used only for measurement may be disposed separately to the exposure apparatus to detect the transferred image (such as the latent image and the resist image) of the measurement pattern, and the results may be sent to the exposure apparatus via LAN, the Internet, or by wireless communication.

In the embodiment above and the modified example, the case has been described where a LAN, a LAN and a public line, and other signal lines are used as the communication channel. However, the present invention is not limited to this, and the signal lines and the communication channel may either be fixed-line or wireless.

In the embodiment above and the modified example, the 12 types of image-forming performance have been optimized, however, the types (numbers) of the image-forming performance is not limited to this, and by changing the types of exposure conditions subject to optimization, the types (numbers) of the image-forming performance that are optimized can be increased or decreased. For example, the type of the image-forming performance included in the Zernike Sensitivity chart described earlier as the evaluation amount can be changed.

In addition, in the embodiment above and the modified example, coefficients of each of the 1^{st} to n^{th} terms in the Zernike polynomial are all used, however, at least one coefficient of one term of the 1^{st} to n^{th} terms does not have to be used. For example, without using the coefficients of each of the 2 to 4^{th} terms, the corresponding image-forming performance may be adjusted in a conventional manner. In this case, when the coefficients of each of the 2^{nd} to 4^{th} terms are not used, the corresponding image-forming performance may be adjusted by adjusting the position of at least one movable lens 13₁ to 13₅ in directions of three degrees of freedom, or it may be adjusted by adjusting the Z position and inclination of wafer W (Z-tilt stage 58).

In addition, in the embodiment above and the modified example, the case has been described where coefficients of the terms of the Zernike polynomials are calculated up to the 81^{st} term using the wavefront aberration measuring unit, while in the case of the wavefront aberration measuring instrument, coefficients of the terms of the Zernike polynomials are calculated up to the 37^{th} term, however, the present invention is not limited, and the terms may be any other numbers. For example, the terms up to the 82^{nd} term or more may be calculated in both cases. Similarly, the wavefront aberration variation table previously described is not limited to the ones related from the 1^{st} term to the 37^{th} term.

Furthermore, in the above embodiment and the modified example, the case has been described where optimization is performed using the Least Squares Method or Damped Least Squares Method, however, the following methods can also be used: (1) gradient methods such as the Steepest Decent Method or the Conjugate Gradient Method, (2) Flexible Method, (3) Variable by Variable Method, (4) Orthonomalization Method, (5) Adaptive Method, (6) Quadratic Differentiation, (7) Global Optimization by Simulated Annealing, (8) Global Optimization by Biological Evolution, and (9) Genetic Algorithm (refer to U.S. patent application No. 2001/0053962A).

In addition, in the above embodiment and the modified example, as the information on illumination conditions, σ values (coherence factor) are used in normal illumination and annular ratio is used in annular illumination. However, in annular illumination, in addition to, or instead of using the annular ratio, the inside diameter or the outside diameter may also be used. Or, in modified illumination such as in quadrupole illumination (also called SHRINC or multipole illumination), because the light quantity distribution of the illumination light on the pupil plane of the illumination optical system is increased partially, more specifically, in a plurality of partial areas whose light quantity centroid are set at positions where the distance from the optical axis of the illumination optical system is substantially equal, the positional information of the plurality of partial areas (light quantity centroid) on the pupil surface of the illumination optical system (for example, the coordinate values in a coordinate system whose origin is the optical axis on the pupil surface of the illumination optical system), the distance between the plurality of partial areas (light quantity centroid) and the optical axis of the illumination optical system, and the size of the partial area (corresponding to the σ value) may also be used as the information.

Furthermore, in the above embodiment and the modified example, the case has been described where the image-forming performance is adjusted by moving the optical elements of projection optical system PL, however, the image-forming performance adjustment mechanism is not limited to the drive mechanism of the optical elements, and in addition to, or instead of the drive mechanism, mechanisms may be used that changes the pressure of gas in between the optical elements of projection optical system PL, moves or inclines reticle R in the optical axis direction of the projection optical system, or changes the optical thickness of the plane-parallel plate disposed in between the reticle and the wafer. However, in such a case, the number of degrees of freedom may be changed in the above embodiment and the modified example.

In the embodiment above, the case has been described where a scanner is used as the exposure apparatus, however, the present invention is not limited to this, and an exposure apparatus by the static exposure method (such as a stepper) that transfers a pattern of a mask onto an object while the mask and the object are in a static state whose details are disclosed in, for example, U.S. Pat. No. 5,243,195, and the like may be used.

Furthermore, in the above embodiment and the modified example, the configuration of the plurality of exposure apparatus was identical. However, an exposure apparatus whose wavelength of illumination light EL is different may also be used together, or exposure apparatus having different configurations, for example, an exposure apparatus by the static exposure method (such as the stepper) and an exposure apparatus by the scanning exposure method (such as a scanner) may be used together. In addition, a part of the plurality of exposure apparatus may be at least either an exposure apparatus that uses charged particle beams such as an electron beam or an ion beam, or an exposure apparatus that uses an X-ray or an EUV beam. In addition, for example, an immersion exposure apparatus that has liquid filled in between projection optical system PL and the wafer whose details are disclosed in, for example, the International Publication WO99/49504, maybe used. The immersion exposure apparatus may be an apparatus by the scanning exposure method that uses a catadioptric type projection optical system, or an apparatus by the static exposure method that uses a projection optical system having the projection magnification of ⅛. In the case of the latter immersion exposure apparatus, in order to form a large pattern on the substrate, it is desirable to employ the step-and-stitch method. Furthermore, as is disclosed in, for example, Kokai (Japanese Unexamined Patent Application Publication) No. 10-214783 and the corresponding U.S. Pat. No. 6,341,007, and in the International Publication No. WO98/40791 pamphlet and the corresponding U.S. Pat. No. 6,262,796, an exposure apparatus that has two independently movable wafer stages may also be used.

The usage of the exposure apparatus 922_{N} shown in FIG. 1 is not limited to the exposure apparatus used for manufacturing semiconductors, and for example, it can also be applied to an exposure apparatus used for transferring a liquid crystal display device pattern onto a square glass plate when manufacturing liquid crystal displays, or to an exposure apparatus used for manufacturing display devices such as a plasma display or an organic EL, pick-up devices (such as a CCD), thin film magnetic heads, micromachines, and DNA chips. In addition, exposure apparatus 922_{N} can also be used not only as the exposure apparatus used for manufacturing microdevices such as a semiconductor, but also as an exposure apparatus that transfers a circuit pattern onto a glass substrate or a silicon wafer in order to manufacture a reticle or a mask used in an optical exposure apparatus, an EUV exposure apparatus, and X-ray exposure apparatus, and an electron beam exposure apparatus.

In addition, the light source of the exposure apparatus in the embodiment above is not limited to a pulsed ultraviolet light source such as the F₂ laser, the ArF excimer laser, and the KrF excimer laser, and a continuous light source as in, for example, an extra-high pressure mercury lamp that emits an emission line such as a g-line (wavelength, 436 nm) or an i-line (wavelength, 365 nm) can also be used. Furthermore, as illumination light EL, X-ray may also be used, especially EUV light.

In addition, a harmonic wave may be used that is obtained by amplifying a single-wavelength laser beam in the infrared or visible range emitted by a DFB semiconductor laser or fiber laser, with a fiber amplifier doped with, for example, erbium (or both erbium and ytteribium), and by converting the wavelength into ultraviolet light using a nonlinear optical crystal. Also, the magnification of the projection optical system is not limited to a reduction system, and an equal magnification or a magnifying system may be used. Furthermore, the projection optical system is not limited to a refraction system, and a catadioptric system that has reflection optical elements and refraction optical elements may be used as well as a reflection system that uses only reflection optical elements. When the catadioptric system or the reflection system is used as projection optical system PL, the image-forming performance of the projection optical system is adjusted by changing the position or the like of the reflection optical elements (such as a concave mirror or a reflection mirror) that serve as the movable optical elements previously described. In addition, when especially the Ar₂ laser beam or the EUV light or the like is used as illumination light EL, projection optical system PL can be a total reflection system that is made up only of reflection optical elements. However, when the Ar₂ laser beam, the EUV light, or the like is used, reticle R also needs to be a reflective type reticle.

Incidentally, semiconductor devices are made undergoing the following steps: a manufacturing step where a working reticle is manufactured in the manner previously described, a wafer manufacturing step where a wafer is made from silicon material, a transferring step where the pattern of the reticle is transferred onto the wafer by the exposure apparatus in the embodiment, a device assembly step (including the dicing process, bonding process, and packaging process), and an inspection step. According to the device manufacturing method, because exposure is performed in a lithographic process using the exposure apparatus in the above embodiment, the pattern of the working reticle is transferred onto the wafer via projection optical system PL whose image-forming performance is adjusted according to the subject pattern, and accordingly, it becomes possible to transfer fine patterns onto the wafer (photosensitive object) with high overlay accuracy. Accordingly, the yield of the devices as final products is improved, which makes it possible to improve its productivity.

While the above-described embodiment of the present invention is the presently preferred embodiment thereof, those skilled in the art of lithography systems will readily recognize that numerous additions, modifications, and substitutions may be made to the above-described embodiment without departing from the spirit and scope thereof. It is intended that all such modifications, additions, and substitutions fall within the scope of the present invention, which is best defined by the claims appended below.

What is claimed is:

1. A pattern decision method in which information on a pattern that is to be formed on a mask is decided, said mask being a mask used in a plurality of exposure apparatus that form a projected image of said pattern formed on said mask onto an object via a projection optical system, said method comprising:
an optimization processing step in which a first step and a second step are repeatedly performed until an image-forming performance of said projection optical system in all the exposure apparatus is judged to be within a permissible range, according to a judgment made in said second step, wherein
in said first step, an appropriate adjustment amount of an adjustment unit so as to adjust a forming state of said projected image of said pattern on said object is calculated for each exposure apparatus under target exposure conditions, which take into consideration correction information on said pattern, based on a plurality of types of information that includes said adjustment information of said adjustment unit including said pattern information and information related to said image-forming performance of said projection optical system corresponding to said adjustment information under predetermined exposure conditions, correction information on said pattern, and information on said permissible range of said image-forming performance, and
in said second step, said judgment is made whether or not said predetermined image-forming performance of said projection optical system in at least one exposure apparatus is outside said permissible range under said target exposure conditions after said adjustment unit has been adjusted according to said appropriate adjustment amount for each exposure apparatus calculated in said first step, and by said judgment, based on said image-forming performance resulting to be outside said permissible range, said correction information is set according to a predetermined criterion; and
a decision making step in which when said image-forming performance of said projection optical system in all the exposure apparatus falls within said permissible range, said correction information set in said optimization processing step is decided as correction information on said pattern.

2. The pattern decision method according to claim 1 wherein
said second step comprises
a first judgment step in which a predetermined image-forming performance of a projection optical system in at least one exposure apparatus is judged whether it is outside said permissible range under said target exposure conditions or not after said adjustment unit has been adjusted according to said appropriate adjustment amount, based on said appropriate adjustment amount for each exposure apparatus calculated in said first step, and said adjustment information of said adjustment unit under said predetermined exposure conditions and information related to an image-forming performance of said projection optical system corresponding to said adjustment information, and
a setting step in which said correction information is set according to a predetermined criterion based on a predetermined image-forming performance resulting to be outside said permissible range, in the case said predetermined image-forming performance of a projection optical system in at least one exposure apparatus is outside said permissible range according to the results of said judgment in said first judgment step.

3. The pattern decision method according to claim 2 wherein
said second step further comprises
a second judgment step in which a predetermined image-forming performance of a projection optical system in at least one exposure apparatus is judged whether it is outside said permissible range or not under said target exposure conditions after said adjustment unit has been adjusted according to said appropriate adjustment amount, based on said appropriate adjustment amount for each exposure apparatus calculated in said first step, said correction information set in said setting step, said adjustment information of said adjustment unit under said predetermined exposure conditions and information related to said image-forming performance of said projection optical system corresponding to said adjustment information, and information on said permissible range of said image-forming performance.

4. The pattern decision method according to claim 1 wherein
said predetermined criterion is a criterion based on an image-forming performance resulting outside said permissible range, and is also a criterion when performing pattern correction to make said image-forming performance fall within said permissible range.

5. The pattern decision method according to claim 1 wherein
said correction information is set based on an average value of residual errors of a predetermined image-forming performance in said plurality of exposure apparatus.

6. The pattern decision method according to claim 1 wherein
said information related to said image-forming performance includes information on wavefront aberration of said projection optical system after adjustment under said predetermined exposure conditions.

7. The pattern decision method according to claim 1 wherein
said information related to said image-forming performance includes information on wavefront aberration only of said projection optical system and information on an image forming performance of said projection optical system under said predetermined exposure conditions.

8. The pattern decision method according to claim 1 wherein
said information related to said image-forming performance is information on a difference between an image-forming performance of said projection optical system under said predetermined exposure conditions and a predetermined target value of said image-forming performance,
said adjustment information of said adjustment unit is information on adjustment amounts of said adjustment unit, whereby
in said first step, said appropriate adjustment amount is calculated for each exposure apparatus, using a relational expression between said difference, a Zernike Sensitivity chart under said target exposure conditions, which denotes a relation between an image-forming performance of said projection optical system and the coefficient of each term in the Zernike polynomial under said target exposure conditions, a wavefront aberration variation table consisting of a group of parameters, which denotes a relation between adjustment of said adjustment unit and wavefront aberration change of said projection optical system, and said adjustment amounts.

9. The pattern decision method according to claim 8 wherein
said relational expression is an expression that includes a weighting function for performing weighting on any of the terms of each term of said Zernike polynomial.

10. The pattern decision method according to claim 9 wherein
said weight is set so that among said image-forming performance of said projection optical system under said target exposure conditions, weight in sections outside said permissible range is high.

11. The pattern decision method according to claim 8 wherein
in said second step, said judgment of whether or not said predetermined image-forming performance of said projection optical system in at least one exposure apparatus is outside said permissible range is made, based on a difference between:
an image-forming performance of said projection optical system under said target exposure conditions calculated for each exposure apparatus, based on information on wavefront aberration after adjustment and said Zernike Sensitivity chart under said target exposure conditions, said information on wavefront aberration after adjustment being obtained based on adjustment information of said adjustment unit under said predetermined exposure conditions and information on wavefront aberration of said projection optical system corresponding to said adjustment information, and an appropriate adjustment amount calculated in said first step; and
said target value of said image-forming performance.

12. The pattern decision method according to claim 8 wherein
as said Zernike Sensitivity chart under said target exposure conditions, a Zernike Sensitivity chart under said target exposure conditions that takes into consideration said correction information made by calculation after setting said correction information in said second step is used.

13. The pattern decision method according to claim 8 wherein
said predetermined target value is a target value of said image-forming performance in a least one evaluation point of said projection optical system.

14. The pattern decision method according to claim 13 wherein
said target value of said image-forming performance is a target value of an image-forming performance at a representative point that is selected.

15. The pattern decision method according to claim 1 wherein
in said optimization processing step, said appropriate adjustment amount is calculated, further taking into consideration restraint conditions, which are decided by adjustment amount limits due to said adjustment unit.

16. The pattern decision method according to claim 1 wherein
in said optimization processing step, said appropriate adjustment amount is calculated with at least a part of the field of said projection optical system serving as an optimization field range.

17. The pattern decision method according to claim 1, said method further comprising:
a repetition number limitation step in which a judgment is made whether or not said first step and said second step have been repeated a predetermined number of times, and when a judgment is made that said first step and said second step have been repeated a predetermined number of times before said image-forming performance of said projection optical system in all the exposure apparatus falls within said permissible range, processing is terminated.

18. A mask manufacturing method, said method comprising:
a pattern decision step in which information on a pattern that is to be formed on a mask is decided according to a pattern decision method in claim 1; and
a pattern forming step in which a pattern is formed on a mask blank using said information on said pattern that has been decided.

19. An exposure method, said method comprising:
a loading step in which a mask manufactured by a manufacturing method according to claim 18 is loaded into an exposure apparatus among said plurality of exposure apparatus; and
an exposure step in which an object is exposed via said mask and a projection optical system, in a state where an image-forming performance of said projection optical system equipped in said exposure apparatus is adjusted according to a pattern of said mask.

20. A device manufacturing method, said method comprising a transferring step in which a device pattern is transferred onto a photosensitive object using an exposure method according to claim 19.

21. A pattern decision method in which information on a pattern that is to be formed on a mask is decided, said mask being a mask used in a plurality of exposure apparatus that form a projected image of said pattern formed on said mask onto an object via a projection optical system wherein
said information on said pattern is decided so as to make a predetermined image-forming performance when said projected image of said pattern is formed by said projection optical system in said plurality of exposure apparatus fall within a permissible range.

22. A mask manufacturing method, said method comprising:
a pattern decision step in which information on a pattern that is to be formed on a mask is decided by a pattern decision method according to claim 21; and
a pattern forming step in which a pattern is formed on a mask blank using said information on said pattern that has been decided.

23. An exposure method, said method comprising:
a loading step in which a mask manufactured by a manufacturing method according to claim 22 is loaded into an exposure apparatus of said plurality of exposure apparatus; and
an exposure step in which an object is exposed via said mask and said projection optical system, in a state where an image-forming performance of a projection optical system equipped in said exposure apparatus is adjusted according to a pattern of said mask.

24. A device manufacturing method, said method comprising a transferring step in which a device pattern is transferred onto a photosensitive object using an exposure method according to claim 23.

25. An image-forming performance adjusting method of a projection optical system in which an image-forming performance of said projection optical system projecting a pattern formed on a mask onto an object is adjusted, said method comprising:
a calculating step in which an appropriate adjustment amount of an adjustment unit so as to adjust a forming state of said projected image of said pattern on said object is calculated for each exposure apparatus under target exposure conditions, which take into consideration correction information on said pattern, using adjustment information of said adjustment unit and information related to said image-forming performance of said projection optical system under predetermined exposure conditions, and correction information on said pattern in a mask manufacturing stage; and
an adjusting step in which said adjustment unit is adjusted according to said appropriate adjustment amount.

26. The image-forming performance adjusting method according to claim 25 wherein
said information related to said image-forming performance includes information on wavefront aberration of said projection optical system after adjustment under said predetermined exposure conditions.

27. The image-forming performance adjusting method according to claim 25 wherein
said information related to said image-forming performance includes information on wavefront aberration only of said projection optical system and information on an image forming performance of said projection optical system under said predetermined exposure conditions.

28. The image-forming performance adjusting method according to claim 25 wherein
said information related to said image-forming performance is information on a difference between an image-forming performance of said projection optical system under said predetermined exposure conditions and a predetermined target value of said image-forming performance,
said adjustment information of said adjustment unit is information on adjustment amounts of said adjustment unit, whereby
in said calculating step, said appropriate adjustment amount is calculated, using a relational expression between said difference, a Zernike Sensitivity chart under said target exposure conditions, which denotes a relation between an image-forming performance of said projection optical system and the coefficient of each term in the Zernike polynomial under said target exposure conditions, a wavefront aberration variation table consisting of a group of parameters, which denotes a relation between adjustment of said adjustment unit and wavefront aberration change of said projection optical system, and said adjustment amounts.

29. The image-forming performance adjusting method according to claim 28 wherein
said relational expression is an expression that includes a weighting function for performing weighting on any of the terms of each term of said Zernike polynomial.

30. An exposure method in which a pattern formed on a mask is transferred onto an object using a projection optical system, said method comprising:
an adjusting step in which an image-forming performance of said projection optical system under said target exposure conditions is adjusted by an image-forming performance adjusting method according to claim 25; and
a transferring step in which said pattern is transferred onto said object, using a projection optical system whose image-forming performance has been adjusted.

31. A device manufacturing method, said method comprising a transferring step in which a device pattern is transferred onto a photosensitive object using an exposure method according to claim 30.

32. A pattern decision system in which information on a pattern that is to be formed on a mask is decided, said mask being a mask used in a plurality of exposure apparatus that form a projected image of said pattern formed on said mask onto an object via a projection optical system, said system comprising:
a plurality of exposure apparatus that each have a projection optical system and an adjustment unit used to adjust an image-forming state of a projected image of said pattern on said object; and
a computer connecting to said plurality of exposure apparatus via a communication channel, wherein
for exposure apparatus subject to optimization selected from said plurality of exposure apparatus, said computer executes
an optimization processing step in which a first step and a second step are repeatedly performed until an image-forming performance of said projection optical system in all the exposure apparatus subject to optimization is judged to be within a permissible range, according to a judgment made in said second step, wherein
in said first step, an appropriate adjustment amount of an adjustment unit so as to adjust a forming state of said projected image of said pattern on said object is calculated for each exposure apparatus under target exposure conditions, which take into consideration correction information on said pattern, based on a plurality of types of information that includes said adjustment information of said adjustment unit including said pattern information and information related to said image-forming performance of said projection optical system corresponding to said adjustment information under predetermined exposure conditions, correction information on said pattern, and information on said permissible range of said image-forming performance, and
in said second step, said judgment is made whether or not said predetermined image-forming performance of said projection optical system in at least one exposure apparatus subject to optimization is outside said permissible range under said target exposure conditions after said adjustment unit has been adjusted according to said appropriate adjustment amount for each exposure apparatus calculated in said first step, and by said judgment, based on said image-forming performance resulting to be outside said permissible range, said correction information is set according to a predetermined criterion; and
a decision making step in which when said image-forming performance of said projection optical system in all the exposure apparatus subject to optimization falls within said permissible range, said correction information set in said optimization processing step is decided as correction information on said pattern.

33. The pattern decision system according to claim 32 wherein
said computer executes in said second step
a first judgment step in which a judgment of whether or not said predetermined image-forming performance of said projection optical system in at least one exposure apparatus subject to optimization is outside said permissible range under said target exposure conditions after said adjustment unit has been adjusted according to said appropriate adjustment amount is made, based on said appropriate adjustment amount for each exposure apparatus calculated in said first step, and said adjustment information of said adjustment unit under predetermined exposure conditions and information related to an image-forming performance of said projection optical system corresponding to said adjustment information, and
a setting step in which said correction information is set according to a predetermined criterion based on a predetermined image-forming performance resulting to be outside said permissible range, in the case said predetermined image-forming performance of said projection optical system in at least one exposure apparatus subject to optimization is outside said permissible range according to the results of said judgment in said first judgment step.

34. The pattern decision system according to claim 33 wherein
said computer further executes in said second step
a second judgment step in which a judgment of whether or not a predetermined image-forming performance of a projection optical system in at least one exposure apparatus subject to optimization is outside said permissible range under said target exposure conditions after said adjustment unit has been adjusted according to said appropriate adjustment amount is made, based on said appropriate adjustment amount for each exposure apparatus calculated in said first step, said correction information set in said setting step, said adjustment information of said adjustment unit under said predetermined exposure conditions and information related to said image-forming performance of said projection optical system corresponding to said adjustment information, and information on said permissible range of said image-forming performance.

35. The pattern decision system according to claim 32 wherein
said predetermined criterion is a criterion based on an image-forming performance resulting outside said permissible range, and is also a criterion when performing pattern correction to make said image-forming performance fall within said permissible range.

36. The pattern decision system according to claim 32 wherein
said computer sets said correction information in said optimization processing step, based on an average value of residual errors of an image-forming performance in said plurality of exposure apparatus subject to optimization.

37. The pattern decision system according to claim 32 wherein
said information related to said image-forming performance is information on a difference between an image-forming performance of said projection optical system under said predetermined exposure conditions and a predetermined target value of said image-forming performance,
said adjustment information of said adjustment unit is information on adjustment amounts of said adjustment unit, whereby
in said first step, said computer calculates said appropriate adjustment amount for each exposure apparatus, using a relational expression between said difference, a Zernike Sensitivity chart under said target exposure conditions, which denotes a relation between an image-forming performance of said projection optical system and the coefficient of each term in the Zernike polynomial under said target exposure conditions, a wavefront aberration variation table consisting of a group of parameters, which denotes a relation between adjustment of said adjustment unit and wavefront aberration change of said projection optical system, and said adjustment amounts.

38. The pattern decision system according to claim 37 wherein
said predetermined target value is a target value of an image-forming performance in a least one evaluation point of said projection optical system, which is externally input.

39. The pattern decision system according to claim 38 wherein
said target value of said image forming performance is a target value of an image-forming performance at a representative point that is selected.

40. The pattern decision system according to claim 38 wherein
said target value of said image forming performance is a target value of an image-forming performance converted from a target value of a coefficient set based on a decomposition coefficient to improve faulty elements, after said image-forming performance of said projection optical system has been decomposed into elements by an aberration decomposition method.

41. The pattern decision system according to claim 37 wherein
said relational expression is an expression that includes a weighting function for performing weighting on any of the terms of each term of said Zernike polynomial.

42. The pattern decision system according to claim 41 wherein
said computer further executes a procedure of
displaying said image-forming performance of said projection optical system within and outside a permissible range under said predetermined exposure conditions using different colors, and also displaying a weight setting screen.

43. The pattern decision system according to claim 41 wherein
said weight is set so that among said image-forming performance of said projection optical system under said target exposure conditions, weight in sections outside said permissible range is high.

44. The pattern decision system according to claim 37 wherein
in said second step, said computer executes
a judgment operation of whether or not said predetermined image-forming performance of said projection optical system in said at least one exposure apparatus is outside said permissible range, based on a difference between:
an image-forming performance of said projection optical system under said target exposure conditions calculated for each exposure apparatus, based on information on wavefront aberration after adjustment and said Zernike Sensitivity chart under said target exposure conditions denoting a relation between an image-forming performance of said projection optical system under said target exposure conditions and coefficients of each term of the Zernike polynomial, said information on wavefront aberration after adjustment being obtained based on adjustment information of said adjustment unit under said predetermined exposure conditions and information on wavefront aberration of said projection optical system corresponding to said adjustment information, and an appropriate adjustment amount calculated in said first step; and
said target value of said image-forming performance.

45. The pattern decision system according to claim 37 wherein
in said second step, said computer executes
making of a Zernike Sensitivity chart by calculation under target exposure conditions, which take into consideration said correction information, after setting said correction information, and then uses said Zernike Sensitivity chart as the Zernike Sensitivity chart under said target exposure conditions.

46. The pattern decision system according to claim 37 wherein
said predetermined target value is a target value of an image-forming performance in a least one evaluation point of said projection optical system, which is externally input.

47. The pattern decision system according to claim 46 wherein
said target value of said image forming performance is a target value of an image-forming performance at a representative point that is selected.

48. The pattern decision system according to claim 32 wherein
in said optimization processing step, said computer calculates said appropriate adjustment amount, further taking into consideration restraint conditions, which are decided by adjustment amount limits due to said adjustment unit.

49. The pattern decision system according to claim 32 wherein
said computer can externally set at least a part of the field of said projection optical system as an optimization field range.

50. The pattern decision system according to claim 32 wherein
said computer decides whether or not said first step and said second step have been repeated a predetermined number of times, and when said computer decides that said first step and said second step have been repeated a predetermined number of times before said image-forming performance of said projection optical system in all the exposure apparatus subject to optimization falls within said permissible range, terminates the processing.

51. The pattern decision system according to claim 32 wherein
said computer is a process computer that controls each section of any one of said plurality of exposure apparatus.

52. An exposure apparatus that transfers a pattern formed on a mask onto an object via a projection optical system, said apparatus comprising:
an adjustment unit that adjusts a forming state of a projected imaged of said pattern on an object by said projection optical system; and
a processing unit connecting to said adjustment unit via a communication channel, said processing unit controlling said adjustment unit based on an appropriate adjustment amount of said adjustment unit under target exposure conditions, which take into consideration correction information of said pattern, said appropriate adjustment amount calculated using adjustment information under predetermined exposure conditions, information related to an image-forming performance of said projection optical system, and correction information on said pattern in a mask manufacturing stage.

53. A program that makes a computer execute a predetermined processing in order to design a mask used in a plurality of exposure apparatus that form a projected image of said pattern formed on said mask onto an object via a projection optical system, said program making said computer execute:
an optimization processing procedure in which a first procedure and a second procedure are repeatedly performed until an image-forming performance of said projection optical system in all the exposure apparatus is judged to be within a permissible range, according to a judgment made in said second procedure, wherein
in said first procedure, an appropriate adjustment amount of an adjustment unit so as to adjust a forming state of said projected image of said pattern on said object is calculated for each exposure apparatus under target exposure conditions, which take into consideration correction information on said pattern, based on a plurality of types of information that include said adjustment information of said adjustment unit including said pattern information, and information related to said image-forming performance of said projection optical system corresponding to said adjustment information under predetermined exposure conditions, correction information on said pattern, and information on said permissible range of said image-forming performance, and
in said second procedure, said judgment is made whether or not said predetermined image-forming performance of said projection optical system in at least one exposure apparatus is outside said permissible range under said target exposure conditions after said adjustment unit has been adjusted according to said appropriate adjustment amount for each exposure apparatus calculated in said first procedure, and by said judgment, based on said image-forming performance resulting to be outside said permissible range, said correction information is set according to a predetermined criterion; and
a decision making procedure in which when said image-forming performance of said projection optical system in all the exposure apparatus falls within said permissible range, said correction information set in said optimization processing procedure is decided as correction information on said pattern.

54. The program according to claim 53 wherein
as said second procedure, said program makes said computer execute
a first judgment procedure in which a judgment of whether or not a predetermined image-forming performance of a projection optical system in at least one exposure apparatus is outside said permissible range under said target exposure conditions after said adjustment unit has been adjusted according to said appropriate adjustment amount is made, based on said appropriate adjustment amount for each exposure apparatus calculated in said first procedure, and said adjustment information of said adjustment unit under predetermined exposure conditions and information related to an image-forming performance of said projection optical system corresponding to said adjustment information, and
a setting procedure in which said correction information is set according to a predetermined criterion based on an image-forming performance resulting to be outside said permissible range, in the case a predetermined image-forming performance of a projection optical system in at least one exposure apparatus is outside said permissible range according to the results of said judgment in said first judgment procedure.

55. The program according to claim 54, said program further making said computer execute as said second procedure:
a second judgment procedure in which a judgment of whether or not said predetermined image-forming performance of said projection optical system in at least one exposure apparatus is outside said permissible range under said target exposure conditions after said adjustment unit has been adjusted according to said appropriate adjustment amount is made, based on said appropriate adjustment amount for each exposure apparatus calculated in said first procedure, said correction information set in said setting procedure, said adjustment information of said adjustment unit under said predetermined exposure conditions and information related to said image-forming performance of said projection optical system corresponding to said adjustment information, and information on said permissible range of said image-forming performance.

56. The program according to claim 53 wherein
said predetermined criterion is a criterion based on an image-forming performance resulting outside said permissible range, and is also a criterion when performing pattern correction to make said image-forming performance fall within said permissible range.

57. The program according to claim 53 wherein
said predetermined criterion is a criterion for setting said correction information based on an average value of residual errors of said image-forming performance of said plurality of exposure apparatus.

58. The program according to claim 53 wherein
said information related to said image-forming performance includes information on wavefront aberration of said projection optical system after adjustment under said predetermined exposure conditions.

59. The program according to claim 53 wherein
said information related to said image-forming performance includes information on wavefront aberration only of said projection optical system and information on an image forming performance of said projection optical system under said predetermined exposure conditions.

60. The program according to claim 53 wherein
said information related to said image-forming performance is information on a difference between an image-forming performance of said projection optical system under said predetermined exposure conditions and a predetermined target value of said image-forming performance,
said adjustment information of said adjustment unit is information on adjustment amounts of said adjustment unit, whereby said program makes said computer execute
a calculating procedure of said appropriate adjustment amount for each exposure apparatus, using a relational expression between said difference, a Zernike Sensitivity chart under said target exposure conditions, which denotes a relation between an image-forming performance of said projection optical system and the coefficient of each term in the Zernike polynomial under said target exposure conditions, a wavefront aberration variation table consisting of a group of parameters, which denotes a relation between adjustment of said adjustment unit and wavefront aberration change of said projection optical system, and said adjustment amounts as said first procedure.

61. The program according to claim 60, said program further making said computer execute:
a display procedure in which a setting screen of said target values at each evaluation point within the field of said projection optical system is shown.

62. The program according to claim 60, said program further making said computer execute:
a display procedure in which an image-forming performance of said projection optical system is decomposed into elements by an aberration decomposition method, and said setting screen of said target values is shown along with a decomposition coefficient obtained after decomposition; and
a conversion procedure in which a target value of a coefficient set according to said display of said setting screen is converted to a target value of said image-forming performance.

63. The program according to claim 60 wherein
said relational expression is an expression that includes a weighting function for performing weighting on any of the terms of each term of said Zernike polynomial.

64. The program according to claim 63, said program further making said computer execute:
a procedure of displaying said image-forming performance of said projection optical system within and outside a permissible range under said target exposure conditions using different colors, and also displaying a setting screen for said weighting.

65. The program according to claim 60 wherein
in said second procedure, said program makes said computer execute
a judgment operation of whether or not said predetermined image-forming performance of said projection optical system in said at least one exposure apparatus is outside said permissible range, based on a difference between:
an image-forming performance of said projection optical system under said target exposure conditions calculated for each exposure apparatus, based on information on wavefront aberration after adjustment and said Zernike Sensitivity chart under said target exposure conditions denoting a relation between an image-forming performance of said projection optical system under said target exposure conditions and coefficients of each term of the Zernike polynomial, said information on wavefront aberration after adjustment being obtained based on adjustment information of said adjustment unit under said predetermined exposure conditions and information on wavefront aberration of said projection optical system corresponding to said adjustment information, and an appropriate adjustment amount calculated in said first step; and
said target value of said image-forming performance.

66. The program according to claim 60 wherein
in said second procedure, said program makes said computer execute
a procedure of making a Zernike Sensitivity chart by calculation under target exposure conditions, which take into consideration said correction information, after setting said correction information, and then using said Zernike Sensitivity chart as the Zernike Sensitivity chart under said target exposure conditions.

67. The program according to claim 53 wherein
in said optimization processing procedure, said program makes said computer calculate said appropriate adjustment amount, further taking into consideration restraint conditions, which are decided by adjustment amount limits due to said adjustment unit.

68. The program according to claim 53 wherein
in said optimization processing procedure, said program makes said computer calculate said appropriate adjustment amount, with at least a part of the field of said projection optical system as an optimization field range, according to specification from the outside.

69. The program according to claim 53, said program further making said computer execute:
a procedure of deciding whether or not said first procedure and said second procedure have been repeated a predetermined number of times, and when said computer decides that said first procedure and said second procedure have been repeated a predetermined number of times before said image-forming performance of said projection optical system in all the exposure apparatus subject to optimization falls within said permissible range, said program makes said computer terminate the processing.

70. An information storage medium that can be read by a computer in which a program according to claim 53 is recorded.
